(19) United States
(12) Patent Application Publication
(10) Pub. No.: US 2025/0140175 A1
(43) Pub. Date: May 1, 2025

(54) Light Emitting Display Panel and Light Emitting Display Apparatus Using the Same

(71) Applicant: LG Display Co., Ltd., Seoul (KR)

(72) Inventors: GuenSik Lee, Paju-si (KR); SeungTae Jin, Paju-si (KR); Dongkyu Lee, Paju-si (KR)

(21) Appl. No.: 18/904,687

(22) Filed: Oct. 2, 2024

(30) Foreign Application Priority Data
Oct. 26, 2023 (KR) 10-2023-0144938

(51) Int. Cl. G09G 3/32

(52) U.S. Cl. CPC G09G 3/32; G09G 2310/08; G09G 2320/068; G09G 2330/023; G09G 2380/10

(57) ABSTRACT

A light emitting display panel is disclosed that comprises a display area including light emitting areas, each of the light emitting areas including subpixels in the light emitting area. Viewing angle switching units are in a non-display area and each viewing angle switching unit is connected to the subpixels included in a corresponding light emitting area. Each subpixel includes a first light emitting unit driven by a first viewing angle control transistor that is controlled by the viewing angle switching unit that is connected to the subpixel where the first light unit includes a first lens having a first shape, and a second light emitting unit driven by a second viewing angle control transistor that is controlled by the viewing angle switching unit that is connected to the subpixel where the second light emitting unit includes a second lens having a second shape.

### CROSS-REFERENCE TO RELATED APPLICATION

This application claims the benefit of the Republic of Korea Patent Application No. 10-2023-0144938 filed on Oct. 26, 2023, which is hereby incorporated by reference in its entirety.

### FIELD OF TECHNOLOGY

The present disclosure relates to a light emitting display panel and a light emitting display apparatus using the same.

### DISCUSSION OF THE RELATED ART

A plurality of light emitting display apparatuses for providing information or content to a driver and a passenger can be mounted on a vehicle.

Among light emitting display apparatuses mounted on a vehicle, light emitting display apparatus mounted on a dashboard is becoming increasingly larger.

However, because a viewing angle of a light emitting display apparatus mounted on a dashboard is fixed, drivers and passengers may feel uncomfortable watching videos.

### SUMMARY

Accordingly, the present disclosure is directed to providing a light emitting display apparatus that substantially obviates one or more problems due to limitations and disadvantages of the related art.

An embodiment of the present disclosure is directed to providing a light emitting display panel and a light emitting display apparatus in which viewing angle switching units corresponding to light emitting areas are provided in a non-display area.

Another embodiment of the present disclosure is directed to providing a light emitting display panel and a light emitting display apparatus using the same in which light having a first viewing angle but not a second viewing angle is output or light having a second viewing angle but not the first viewing angle is output in each subpixel of light emitting areas.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and the appended drawings.

In one embodiment, a light emitting display panel comprises: a display area that is divided into a plurality of light emitting areas along a first direction and along a second direction that is different from the first direction and a non-display area that is outside the display area, each of the plurality of light emitting areas including a plurality of subpixels in the light emitting area; and a plurality of viewing angle switching units in the non-display area, each viewing angle switching unit connected to the plurality of subpixels included in a corresponding light emitting area from the plurality of light emitting areas, wherein each of the plurality of subpixels includes: a first light emitting unit driven by a first viewing angle control transistor that is controlled by a viewing angle switching unit from the plurality of viewing angle switching units that is connected to the subpixel, the first light emitting unit including a first lens having a first shape; and a second light emitting unit driven by a second viewing angle control transistor that is controlled by the viewing angle switching unit that is connected to the subpixel, the second light emitting unit including a second lens having a second shape that is different from the first shape of the first lens.

In one embodiment, a light emitting display apparatus comprises: a display area that is divided into a plurality of light emitting areas along a first direction and along a second direction that is different from the first direction and a non-display area that is outside the display area, each of the plurality of light emitting areas including a plurality of subpixels in the light emitting area, wherein each of the plurality of subpixels includes: a first light emitting unit driven by a first viewing angle control transistor, the first light emitting unit emitting light at a first viewing angle; and a second light emitting unit driven by a second viewing angle control transistor, the second light emitting unit emitting light at a second viewing angle that is different from the first viewing angle, wherein in each of the plurality of subpixels of the plurality of light emitting areas, the first light emitting unit emits light having the first viewing angle without the second light emitting unit emitting the light having the second viewing angle, and the second light emitting unit emits light having the second viewing angle without the first light emitting unit emitting the light having the first viewing angle.

In one embodiment, a light emitting display device comprises: a display panel including a plurality of light emitting areas that each include a plurality of subpixels in the light emitting area and a non-display area around the plurality of light emitting areas, each of the plurality of subpixels including a first light emitting unit that emits light at a first viewing angle and a second light emitting unit that emits light at a second viewing angle that is different from the first viewing angle; and a plurality of viewing angle switching units in the non-display area, each viewing angle switching unit connected to the plurality of subpixels included in a corresponding light emitting area from the plurality of light emitting areas and is configured to control the plurality of subpixels in the corresponding light emitting area to emit light at the first viewing angle or the second viewing angle, wherein the plurality of subpixels of one light emitting area from the plurality of light emitting areas emit light at the first viewing angle that corresponds to a portion of a first image while the plurality of subpixels of another light emitting area from the plurality of light emitting areas emits light at the second viewing angle that corresponds to a portion of a second image that is different from the first image during a first mode of the light emitting display device.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exemplary diagram illustrating a configuration of a light emitting display apparatus according to an embodiment of the present disclosure;

FIG. 2 is an exemplary diagram illustrating a structure of a subpixel applied to a light emitting display apparatus according to an embodiment of the present disclosure;

FIG. 3 is an exemplary diagram illustrating a structure of a control driver applied to a light emitting display apparatus according to an embodiment of the present disclosure;

FIG. 4 is an exemplary diagram illustrating a structure of a gate driver applied to a light emitting display apparatus according to an embodiment of the present disclosure;

FIG. 5 is an exemplary diagram illustrating a structure of a data driver applied to a light emitting display apparatus according to an embodiment of the present disclosure;

FIG. 6 is an exemplary diagram illustrating an internal structure of a vehicle to which a light emitting display apparatus according to an embodiment of the present disclosure is applied;

FIGS. 7A to 7F are exemplary diagrams illustrating how viewing angles of light emitting areas change in a light emitting display panel according to an embodiment of the present disclosure;

FIG. 8 is an exemplary plan view schematically illustrating a structure of a subpixel of a light emitting display panel according to an embodiment of the present disclosure;

FIGS. 9A and 9B are exemplary perspective views illustrating structures of a first lens and a second lens of a subpixel applied to a light emitting display panel according to an embodiment of the present disclosure;

FIG. 10 is an exemplary plan view illustrating a structure of three subpixels applied to a light emitting display panel according to an embodiment of the present disclosure;

FIG. 11 is an exemplary cross-sectional view taken along line I-I′ illustrated in FIG. 10 according to an embodiment of the present disclosure;

FIG. 12 is an exemplary cross-sectional view taken along line II-II′ illustrate in FIG. 10 according to an embodiment of the present disclosure;

FIG. 13 is an exemplary timing diagram for explaining a basic driving method of a light emitting display apparatus according to an embodiment of the present disclosure;

FIG. 14 is an exemplary diagram illustrating a connection structure of viewing angle switching units and viewing angle control lines in a light emitting display apparatus according to an embodiment of the present disclosure;

FIG. 15 is an exemplary diagram illustrating a structure of a viewing angle switching unit illustrated in FIG. 14 according to an embodiment of the present disclosure;

FIG. 16 is another exemplary diagram illustrating a structure of a viewing angle switching unit illustrated in FIG. 14 according to an embodiment of the present disclosure;

FIG. 17 is an exemplary diagram illustrating a viewing angle control signal, a first control signal, and a second control signal applied to a light emitting display apparatus illustrated in FIG. 14 according to an embodiment of the present disclosure;

FIG. 18 is another exemplary diagram illustrating a connection structure of viewing angle switching units and viewing angle control lines in a light emitting display apparatus according to an embodiment of the present disclosure;

FIG. 19 is an exemplary diagram illustrating a structure of a viewing angle switching unit illustrated in FIG. 18 according to an embodiment of the present disclosure;

FIG. 20 is another exemplary diagram illustrating a structure of a viewing angle switching unit illustrated in FIG. 18;

FIG. 21 is another exemplary diagram illustrating a structure of a viewing angle switching unit illustrated in FIG. 18 according to an embodiment of the present disclosure;

FIG. 22 is an exemplary diagram illustrating a viewing angle control signal, a first control signal, and a second control signal applied to a light emitting display apparatus illustrated in FIG. 18 according to an embodiment of the present disclosure;

FIGS. 23 and 24 are other exemplary diagrams illustrating a structure of a viewing angle switching unit applied to a light emitting display apparatus according to the present disclosure; and

FIG. 25 is another exemplary diagram illustrating a structure of a viewing angle control unit applied to a light emitting display apparatus according to the present disclosure.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. may be used. These terms are intended to identify the corresponding elements from the other elements, and basis, order, or number of the corresponding elements should not be limited by these terms. The expression that an element or layer is “connected,” “coupled,” or “adhered” to another element or layer indicates that the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, embodiments of the present disclosure will be described in detail with reference to the accompanying drawings.

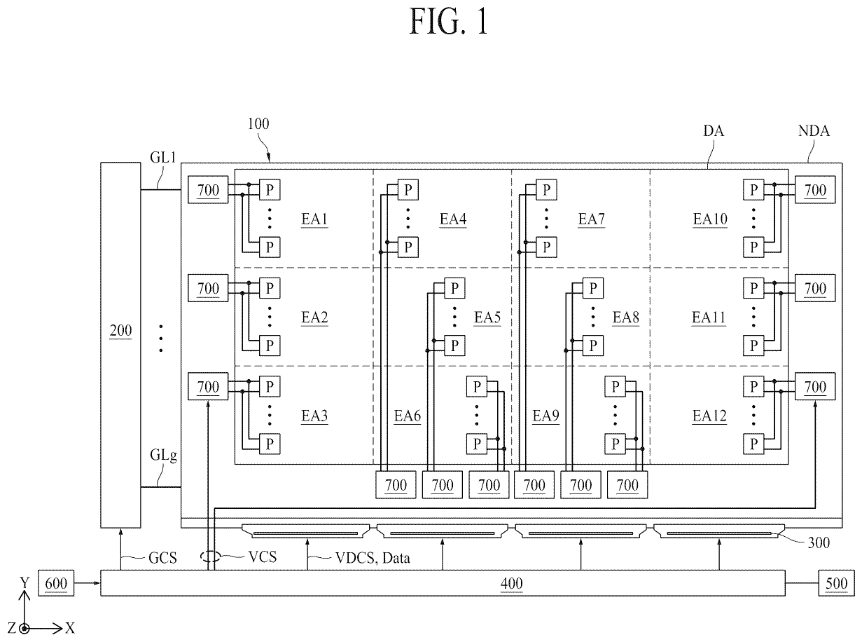

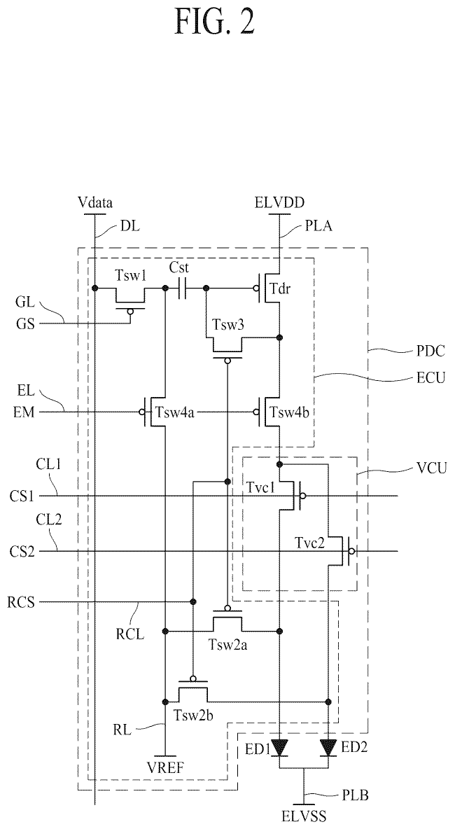

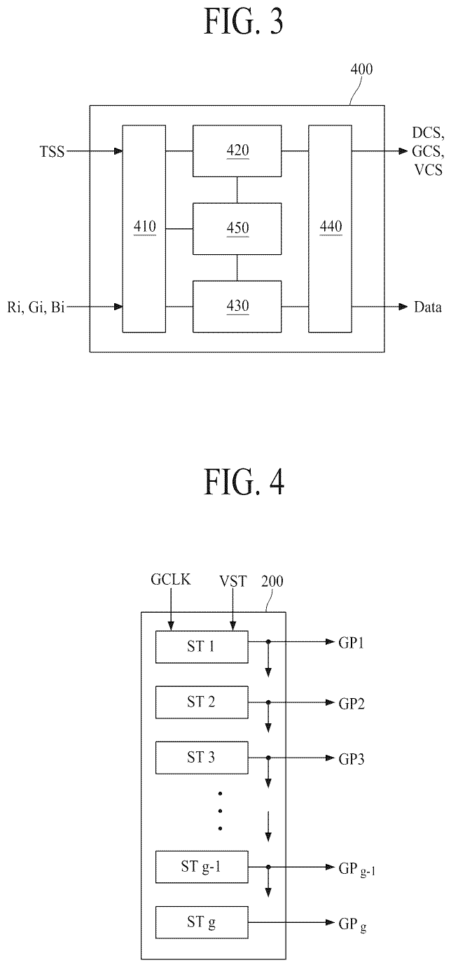

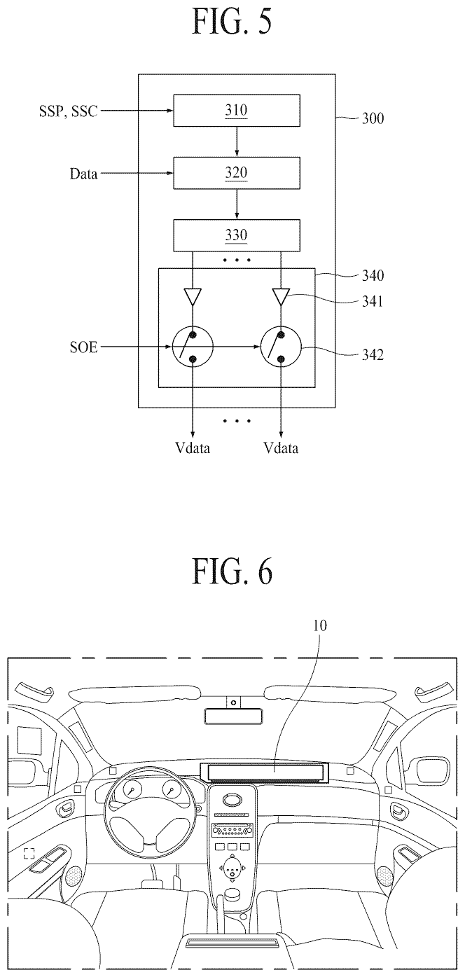

FIG. 1 is an exemplary diagram illustrating a configuration of a light emitting display apparatus according to an embodiment of the present disclosure, FIG. 2 is an exemplary diagram illustrating a structure of a subpixel applied to a light emitting display apparatus according to an embodiment of the present disclosure, FIG. 3 is an exemplary diagram illustrating a structure of a control driver applied to a light emitting display apparatus according to an embodiment of the present disclosure, FIG. 4 is an exemplary diagram illustrating a structure of a gate driver applied to a light emitting display apparatus according to an embodiment of the present disclosure, and FIG. 5 is an exemplary diagram illustrating a structure of a data driver applied to a light emitting display apparatus according to an embodiment of the present disclosure.

A light emitting display apparatus according to an embodiment of the present disclosure may be any one of an organic light emitting diode display apparatus, a quantum dot light emitting diode display apparatus, and an inorganic light emitting diode display apparatus. That is, a light emitting display apparatus according to an embodiment of the present disclosure may be an electroluminescent display apparatus. Moreover, a light emitting display apparatus according to an embodiment of the present disclosure may be a micro light emitting diode display apparatus.

A light emitting display apparatus according to an embodiment of the present disclosure can be used as various kinds of electronic devices. Electronic devices can be, for example, televisions, monitors, etc., and can be automotive electronic devices mounted and used in vehicle. Particularly, a light emitting display apparatus according to an embodiment of the present disclosure can be mounted on a dashboard of a vehicle to provide information and various images related to an operation of the vehicle to a driver and a passenger. Hereinafter, for convenience of description, a light emitting display apparatus mounted on a dashboard of a vehicle to be used will be described as an example of a light emitting display apparatus according to an embodiment of the present disclosure.

The light emitting display apparatus according to an embodiment of the present disclosure, as illustrated in FIGS. 1 and 2, can include a light emitting display panel 100 which includes a display area DA displaying an image and a non-display area NDA provided outside the display area DA, a gate driver 200 which supplies gate signals GS to a plurality of gate lines GL1 to GLg provided in the display area DA of the display panel 100, a data driver 300 which supplies data voltages Vdata to a plurality of data lines DL1 to DLd provided in the display area DA of the display panel 100, a control driver 400 which controls driving of the gate driver 200 and the data driver 300, and a power supply unit 500 which supplies power to the control driver 400, the gate driver 200, the data driver 300, and the light emitting display panel 100.

First, the light emitting display panel 100 can include a display area DA and a non-display area NDA. Gate lines GL1 to GLg, data lines DL, and subpixels P can be provided in the display area DA. Accordingly, an image can be displayed in the display area DA. Here, g and d are natural numbers. The non-display area NDA can surround the outer periphery of the display area DA.

The subpixel P included in the light emitting display panel 100, as illustrated in FIG. 2, can include a pixel driving circuit PDC which includes a switching transistor Tsw1, a storage capacitor Cst, a driving transistor Tdr, a first reference transistor Tsw2a, a second reference transistor Tsw2b, a first viewing angle control transistor Tvc1, and a second viewing angle control transistor Tvc2, and a first light emitting device ED1 and a second light emitting device ED2 which are connected to the pixel driving circuit PDC.

A first terminal of the driving transistor Tdr can be connected to a first voltage supply line PLA through which a first voltage ELVDD is supplied, and a second terminal of the driving transistor Tdr can be connected to the first light emitting device ED1 and the second light emitting device ED2.

A first terminal of the switching transistor Tsw1 can be connected to a data line DL, a second terminal of the switching transistor Tsw1 can be connected to a first terminal of the storage capacitor Cst, and a gate of the switching transistor Tsw1 can be connected to a gate line GL.

A data voltage Vdata can be supplied through the data line DL from the data driver 300. A gate signal GS can be supplied through the gate line GL from the gate driver 200. The gate signal GS can include a gate pulse GP for turning on the switching transistor Tsw1 and a gate-off signal for turning off the switching transistor Tsw1.

The first reference transistor Tsw2a and the second reference transistor Tsw2b can be provided for measuring a threshold voltage or mobility of the driving transistor Tdr, or supplying a reference voltage VREF to the pixel driving circuit PDC.

A first terminal of the first reference transistor Tsw2a can be connected to a reference line RL through which a reference voltage VREF is supplied, a second terminal of the first reference transistor Tsw2a can be connected to a second terminal of the first viewing angle control transistor Tvc1 and the first light emitting device ED1, and a gate of the first reference transistor Tsw2a can be connected to a reference control line RCL through which a reference control signal RCS is supplied.

A first terminal of the second reference transistor Tsw2b can be connected to a reference line RL through which the reference voltage VREF is supplied, a second terminal of the second reference transistor Tsw2b can be connected to a second terminal of the second viewing angle control transistor Tvc2 and the second light emitting device ED2, and a gate of the second reference transistor Tsw2b can be connected to the reference control line RCL through which the reference control signal RCS is supplied.

The reference line RL can be connected to the data driver 300 and can be connected to the power supply unit 500 through the data driver 300. For example, the reference voltage VREF supplied from the power supply unit 500 can be supplied to the subpixels SP through the reference line RL, sensing signals transmitted from the subpixels SP can be converted into digital sensing signals in the data driver 300, and the digital sensing signals can be transmitted to the control driver 400.

A first terminal of the storage capacitor Cst can be connected to a second terminal of the switching transistor Tsw1, and a second terminal of the storage capacitor Cst can be connected to a gate of the driving transistor Tdr.

A first terminal of the first viewing angle control transistor Tvc1 can be connected to the second terminal of the driving transistor Tdr, a second terminal of the first viewing angle control transistor Tvc1 can be connected to the first light emitting device ED1, and a gate of the first viewing angle control transistor Tvc1 can be connected to a first control signal line CL1.

A first terminal of the second viewing angle control transistor Tvc2 can be connected to the second terminal of the driving transistor Tdr, a second terminal of the second viewing angle control transistor Tvc2 can be connected to the second light emitting device ED2, and a gate of the second viewing angle control transistor Tvc2 can be connected to a second control signal line CL2.

That is, the gate of the first viewing angle control transistor Tvc1 can be connected to the first control signal line CL1 and the gate of the second viewing angle control transistor Tvc2 can be connected to the second control signal line CL2. The first control signal line CL1 and the second control signal line CL2 can be provided in each of m light emitting areas. Here, m is a natural number greater than 1.

For example, when the display area DA is divided into 12 light emitting areas EA1 to EA12, as illustrated in FIG. 1, m is 12. In this case, gates of first viewing angle control transistors Tvc1 provided in a first light emitting area EA1 can be connected to the first control signal line CL1 and gates of second viewing angle control transistors Tvc2 provided in the first light emitting area EA1 can be connected to the second control signal line CL2.

Further, gates of first viewing angle control transistors Tvc1 provided in a 12th light emitting area EA12 can be connected to a first control signal line CL1 and gates of second viewing angle control transistors Tvc2 provided in the 12th light emitting area EA12 can be connected to a second control signal line CL2.

The first control signal line CL1 and the second control signal line CL2 which are provided in the first light emitting area EA1 are different from the first control signal line CL1 and the second control signal line CL2 which are provided in the 12th light emitting area EA12. That is, the first control signal line CL1 and the second control signal line CL2 can be provided in each of the light emitting areas.

In this case, a polarity type of the first viewing angle control transistor Tvc1 can be the same as a polarity type of the second viewing angle control transistor Tvc2.

For example, when the first viewing angle control transistor Tvc1 is an N-type transistor, the second viewing angle control transistor Tvc2 can be an N-type transistor, and when the first viewing angle control transistor Tvc1 is a P-type transistor, the second viewing angle control transistor Tvc2 can be a P-type transistor.

In this case, when the first viewing angle control transistor Tvc1 is turned on, the second viewing angle control transistor Tvc2 can be turned off, and when the first viewing angle control transistor Tvc1 is turned off, the second viewing angle control transistor Tvc2 can be turned on.

For example, as illustrated in FIG. 2, the gate of the first viewing angle control transistor Tvc1 is connected to the first control signal line CL1 and the gate of the second viewing angle control transistor Tvc2 is connected to the second control signal line CL2. Therefore, when signals of different levels are input through the first control signal line CL1 and the second control signal line CL2, one of the first viewing angle control transistor Tvc1 and the second viewing angle control transistor Tvc2 can be turned on, and the other can be turned off.

More specifically, in FIG. 2, when a first control signal having a low level is input to the first control signal line CL1 and a second control signal having a high level is input to the second control signal line CL2, the first viewing angle control transistor Tvc1 formed of the P-type transistor can be turned on, and the second viewing angle control transistor Tvc2 formed of the P-type transistor can be turned off.

Further, in FIG. 2, when a first control signal having the high level is input to the first control signal line CL1 and a second control signal having the low level is input to the second control signal line CL2, the first viewing angle control transistor Tvc1 formed of the P-type transistor can be turned off, and the second viewing angle control transistor Tvc2 formed of the P-type transistor can be turned on.

As illustrated in FIG. 2, the pixel driving circuit PDC can further include a connection transistor Tsw3 and emission transistors Tsw4a and Tsw4b.

A first terminal of the connection transistor Tsw3 can be connected to the gate of the driving transistor Tdr and the second terminal of the storage capacitor Cst, a second terminal of the connection transistor Tsw3 can be connected to the second terminal of the driving transistor Tdr, and a gate of the connection transistor Tsw3 can be connected to the reference control line RCL.

A first terminal of a first emission transistor Tsw4a can be connected to the second terminal of the switching transistor Tsw1 and the first terminal of the storage capacitor Cst, a second terminal of the first emission transistor Tsw4a can be connected to the reference line RL, and a gate of the first emission transistor Tsw4a can be connected to an emission line EL.

A first terminal of the second emission transistor Tsw4b can be connected to the second terminal of the driving transistor Tdr and the second terminal of the connection transistor Tsw3, a second terminal of the second emission transistor Tsw4b can be connected to the first terminal of the first viewing angle control transistor Tvc1 and the first terminal of the second viewing angle control transistor Tvc2, and a gate of the second emission transistor Tsw4b can be connected to the emission line EL. An emission signal EM can be supplied to the emission line EL.

The first light emitting device ED1 connected to the pixel driving circuit PDC can include a first electrode which receives the first voltage EVDD through the driving transistor Tdr, the second emission transistor Tsw4b, and the first viewing angle control transistor Tvc1, a second electrode connected to a second voltage supply line PLB supplied with a second voltage EVSS, and a light emitting layer provided between the first electrode and the second electrode.

The second light emitting device ED2 connected to the pixel driving circuit PDC can include a first electrode which receives the first voltage EVDD through the driving transistor Tdr, the second emission transistor Tsw4b, and the second viewing angle control transistor Tvc2, a second electrode connected to the second voltage supply line PLB supplied with the second voltage EVSS, and a light emitting layer provided between the first electrode and the second electrode.

The structure of the subpixel P applied to a light emitting display apparatus according to an embodiment of the present disclosure is not limited to the structure illustrated in FIG. 2. Accordingly, the structure of the subpixel P can be changed to various shapes.

Particularly, the pixel driving circuit PDC applied to a light emitting display apparatus according to an embodiment of the present disclosure, as illustrated in FIG. 2, can include a light emitting control unit ECU (e.g., a light emitting control circuit) and a viewing angle control unit VCU (e.g., a viewing angle control circuit). The light emitting control unit ECU can control a level of current supplied to the light emitting device ED1 or ED2 and a timing at which the current is supplied to the light emitting device ED1 or ED2. The viewing angle control unit VCU can control a viewing angle of light to be output from the light emitting device ED1 or ED2. In this case, the structure and function of the light emitting control unit ECU can be changed in various shape.

The control driver 400 can realign input image data Ri, Gi, and Bi transmitted from an external system 600 by using a timing synchronization signal TSS transmitted from the external system and can generate a data control signal DCS which is to be supplied to the data driver 300 and a gate control signal GCS which is to be supplied to the gate driver 200.

To this end, as illustrated in FIG. 3, the control driver 400 can include a data aligner 430 (e.g., a circuit) which realigns input image data Ri, Gi, and Bi to generate image data Data and transmits the image data Data to the data driver 300, a control signal generator 420 (e.g., a circuit) which generates the gate control signal GCS and the data control signal DCS by using the timing synchronization signal TSS, an input unit 410 (e.g., a circuit) which transmits the timing synchronization signal TSS transmitted from the external system 600 to the control signal generator 420 and transmits the input image data Ri, Gi, and Bi transmitted from the external system 600 to the data aligner 430, and an output unit 440 (e.g., a circuit) which supplies the data driver 300 with the image data Data generated by the data aligner 430 and the data control signal DCS generated by the control signal generator 420 and supplies the gate driver 200 with the gate control signal GCS generated by the control signal generator 420.

The control signal generator 420 can generate a power control signal supplied to the power supply unit 500.

The control driver 400 can further include a storage unit (e.g., memory) for storing various information. The storage unit 450 can be included in the control driver 400 as illustrated in FIG. 3, but can be separated from the control driver 400 and provided independently.

The control signal generator 420 can generate viewing angle control signals VCS and supply them to viewing angle control lines.

The viewing angle control signals VCS can be supplied to viewing angle switching units 700 provided in the non-display area NDA.

The external system 600 can perform a function of driving the control driver 400 and an electronic device.

For example, when the electronic device is mounted on a vehicle, the external system 600 can receive various kinds of sound information, image information, and letter information over a communication network and can receive various image information related to an operation of the vehicle over other electronic devices mounted on the vehicle. The external system 600 can transmit the received image information to the control driver 400. The external system 600 can convert the image information into input image data Ri, Gi, and Bi and transmit the input image data Ri, Gi, and Bi to the control driver 400.

The power supply unit 500 can generate various powers and supply the generated powers to the control driver 400, the gate driver 200, the data driver 300, and the light emitting display panel 100.

The gate driver 200 can be directly embedded into the non-display area NDA by using a gate-in panel (GIP) type, or the gate driver 200 can be provided in the display area DA in which light emitting devices ED are provided, or the gate driver 200 can be provided on a chip on film mounted in the non-display area NDA.

The gate driver 200 can supply gate pulses GP1 to GPg to the gate lines GL1 to GLg.

When a gate pulse GP generated by the gate driver 200 is supplied to a gate of the switching transistor Tsw1 included in the subpixel P, the switching transistor Tsw1 can be turned on. When the switching transistor Tsw1 is turned on, data voltage Vdata supplied through a data line DL can be supplied to the subpixel P.

When a gate-off signal generated by the gate driver 200 is supplied to the switching transistor Tsw1, the switching transistor Tsw1 can be turned off. When the switching transistor Tsw1 is turned off, a data voltage may not be supplied to the subpixel P any longer.

The gate signal GS supplied to the gate line GL can include the gate pulse GP and the gate-off signal.

To supply gate pulses GP1 to GPg to gate lines GL1 to GLg, the gate driver 200, as illustrated in FIG. 4, can include stages ST1 to STg connected to gate lines GL1 to GLg.

Each of the stages ST1 to STg can be connected to one gate line GL, but can be connected to at least two gate lines GL.

In order to generate gate pulses GP1 to GPg, a gate start signal VST and at least one gate clock GCLK which are generated by the control signal generator 420 can be transferred to the gate driver 200. For example, the gate start signal VST and the at least one gate clock GCLK can be included in the gate control signal GCS.

One of the stages ST1 to STg can be driven by a gate start signal VST to output a gate pulse GP to a gate line GL. The gate pulse GP can be generated by a gate clock GCLK.

At least one of signals output from a stage ST where a gate pulse is output can be supplied to another stage ST to drive another stage ST. Accordingly, a gate pulse can be output in another stage ST.

For example, the stages ST can be driven sequentially to sequentially supply the gate pulses GP to the gate lines GL.

As described above, each of the stages ST1 to STg can be connected to one gate line GL, but can also be connected to at least two gate lines GL.

Also, when the subpixel P has the structure illustrated in FIG. 2, each of the stages ST1 to STg can be connected to at least one gate line GL and at least one reference control line RCL. The reference control signals RCS output through the reference control lines RCL can be generated by the same or similar method to a method by which gate pulses are generated, and then can be sequentially output to the reference control lines RCL.

In this case, a stage connected to the gate line GL illustrated in FIG. 2 and a stage connected to the reference control line RCL illustrated in FIG. 2 may be the same or different.

Moreover, stages for generating gate signals to be supplied to the gate lines GL and stages for generating reference control signals RCS to be supplied to the reference control lines RCL can be independently provided in the gate drivers 200.

That is, the number, type, and connection structure of lines connected to one stage can vary depending on a structure of the subpixels P and a driving method of the subpixels P.

Also, as illustrated in FIG. 2, when the emission line EL to which the emission signal EM is supplied is connected to the subpixel P, after the emission signals EM are generated in the gate driver 200 by the same method as the gate signals GS, the emission signals EM can be output to the emission lines EL.

For example, the gate driver 200 can generate gate signals GS and emission signals EM, and can also generate reference control signals RCS.

In this case, gate signals GS, emission signals EM, and reference control signals RCS can be generated through stages St1 to STg as illustrated in FIG. 4. Alternatively, stages for generating gate signals GS, stages for generating emission signals EM, and stages for generating reference control signals RCS can be independently provided in the gate driver 200. Alternatively, stages for generating gate signals GS and reference control signals RCS and stages for generating emission signals EM can be independently provided in the gate driver 200.

Therefore, the specific structure of the gate driver 200 can be changed in various shapes depending on a structure of the subpixels P, a driving method of the subpixels P, and the number and type of lines connected between the subpixels P and the gate driver 200.

The data driver 300 can supply data voltages Vdata to the data lines DL1 to DLd.

To this end, the data driver 300, as illustrated in FIG. 5, can include a shift register 310 which outputs a sampling signal, a latch 320 which latches image data Data received from the control driver 400, a digital-to-analog converter 330 which converts the image data Data, transmitted from the latch 320, into a data voltage Vdata and outputs the data voltage Vdata, and an output buffer 340 which outputs the data voltage, transmitted from the digital-to-analog converter 330, to the data line DL on the basis of a source output enable signal SOE.

The shift register 310 can output the sampling signal by using the data control signal DCS received from the control signal generator 420. For example, the data control signals DCS transmitted to the shift register 310 can include a source start pulse SSP and a source shift clock signal SSC.

The latch 320 can latch image data Data sequentially received from the control driver 400, and then output the image data Data to the digital-to-analog converter 330 at the same time on the basis of the sampling signal.

The digital-to-analog converter 330 can convert the image data Data transmitted from the latch 320 into data voltages Vdata and output the data voltages Vdata.

The output buffer 340 can simultaneously output the data voltages Vdata transmitted from the digital-to-analog converter 330 to data lines DL1 to DLd of the light emitting display panel 100 on the basis of the source output enable signal SOE transmitted from the control signal generator 420.

To this end, the output buffer 340 can include a buffer 341 which stores the data voltage Vdata transmitted from the digital-to-analog converter 330 and a switch 342 which outputs the data voltage Vdata stored in the buffer 341 to the data line DL on the basis of the source output enable signal SOE.

For example, when the switches 342 are turned on based on the source output enable signal SOE simultaneously supplied to the switches 342, the data voltages Vdata stored in the buffers 341 can be supplied to the data lines DL1 to DLd through the switches 342.

The data voltages Vdata supplied to the data lines DL1 to DLd can be supplied to subpixels P connected to a gate line GL supplied with a gate pulse GP.

Finally, the viewing angle switching units 700 can be provided in the non-display area NDA, and the viewing angle switching units 700 can be connected to the light emitting areas EA in one-to-one relationship.

For example, as illustrated in FIG. 1, when the display area DA is divided into 12 light emitting areas EA1 to EA12, 12 viewing angle switching units 700 can be provided in the non-display area NDA, and one viewing angle switching unit 700 can be connected to subpixels P provided in one light emitting area EA.

The first light emitting units can be driven without the second light emitting units being driven or the second light emitting units can be driven without the first light emitting units being driven in the light emitting area EA based on the first control signal and the second control signal transmitted from the viewing angle switching unit 700. Accordingly, in the light emitting area EA, light having the first viewing angle can be output or light having the second viewing angle can be output.

Hereinafter, additional features for the configurations described above will be described.

The display area DA can include pixel row lines and pixel column lines provided with subpixels P. For example, the pixel row lines can mean subpixels P provided along a first direction (X-axis direction) illustrated in FIG. 1, and the pixel column lines can mean subpixels P provided along a second direction (Y-axis direction) illustrated in FIG. 1.

A subpixel P may be any one of a red subpixel emitting red light, a green subpixel emitting green light, a blue subpixel emitting blue light, and a white subpixel emitting white light. A unit pixel can include at least two subpixels. For example, white light can be output by a unit pixel.

The subpixel P can include the first and second light emitting devices ED1 and ED2, the pixel driving circuit PDC including transistors which drive the first and second light emitting devices ED1 and ED2, a first lens disposed on the first light emitting device ED1, and a second lens disposed on the second light emitting device ED2.

A first light emitting unit can include the first light emitting device ED1 driven by the first viewing angle control transistor Tvc1 and the first lens disposed on the first light emitting device ED1. Also, a second light emitting unit can include the second light emitting device ED2 driven by the second viewing angle control transistor Tvc2 and the second lens disposed on the second light emitting device ED2.

The first light emitting unit can be driven by the first viewing angle control transistor Tvc1, and the second light emitting unit can be driven by the second viewing angle control transistor Tvc2.

The first viewing angle control transistor Tvc1 can be connected between the first light emitting unit and the driving transistor Tdr which controls a level of current supplied to the first or second light emitting unit. The second viewing angle control transistor Tvc2 can be connected between the driving transistor Tdr and the second light emitting unit. The second emission transistor Tsw4b can be connected between the first viewing angle control transistor Tvc1 and the driving transistor Tdr and between the second viewing angle control transistor Tvc2 and the driving transistor Tdr.

The first lens provided in the first light emitting unit and the second lens provided in the second light emitting unit can have different shapes.

Particularly, an exit angle, that is, a viewing angle, of a light output through the first lens can be different from a viewing angle of a light output through the second lens.

For example, the subpixel P can operate in a wide viewing angle mode a share mode, or a first mode (hereinafter, simply referred to as a share mode (SM)) by driving the first light emitting device ED1 to output a light through the first lens such that the light has a first viewing angle during the wide viewing angle mode. Moreover, the subpixel P can operate in a narrow viewing angle mode, privacy mode, or second mode (hereinafter, simply referred to as a privacy mode (PM)) which limits a viewing angle by driving the second light emitting device ED2 to output a light through the second lens having a second viewing angle during the narrow viewing angle mod that is less than the first viewing angle.

The narrow viewing angle mode can denote a mode having a narrower viewing angle (hereinafter, simply referred to as a narrow viewing angle or a second viewing angle) than a viewing angle (hereinafter, simply referred to as a wide viewing angle or a first viewing angle) in the wide viewing angle mode.

That is, the light emitting display apparatus according to an embodiment of the present disclosure can selectively drive the first light emitting device ED1 and the second light emitting device ED2 of the subpixel P, thereby controlling a viewing angle of the subpixel P. A detailed description thereof will be provided later.

The display area DA can be divided into at least two light emitting areas along the first direction, and the display area DA can be divided into at least two light emitting areas along the second direction different from the first direction. For example, as illustrated in FIG. 1, the display area DA can be divided into four light emitting areas along the first direction X and can be divided into three light emitting areas along the second direction Y. That is, FIG. 1 shows a light emitting display panel including a display area DA divided into 12 light emitting areas EA1 to EA12.

For example, when the first light emitting devices ED1 are driven in subpixels P of a first light emitting area EA1 illustrated in FIG. 1 and a light is output through the first lenses, the first light emitting area EA1 can operate in the wide viewing angle mode, and when the second light emitting device ED2 are driven in the subpixels P of the first light emitting area EA1 and a light is output through the second lenses, the first light emitting area EA1 can operate in the narrow viewing angle mode.

In this case, when the first light emitting device ED1 are driven in subpixels P of the second light emitting area EA2 and a light is output through the first lenses, the second light emitting area EA2 can operate in the wide viewing angle mode, and when the second light emitting device ED2 are driven in the subpixels P of the second light emitting area EA2 and a light is output through the second lenses, the second light emitting area EA2 can operate in the narrow viewing angle mode.

Each of a third to 12th light emitting areas EA3 to EA12 can also operate in the wide viewing angle mode or the narrow viewing angle mode.

For example, all of the first to 12th light emitting areas EA1 to EA12 can operate in the wide viewing angle mode or the narrow viewing angle mode. Alternatively, a first subset of the first to 12th light emitting areas EA1 to EA12 can operate in the wide viewing angle mode, and a second subset of the first to 12th light emitting areas EA1 to EA12 can operate in the narrow viewing angle mode.

Accordingly, positions of light emitting areas operating in the wide viewing angle mode and positions of light emitting areas operating in the narrow viewing angle mode can be variously changed. Particularly, the positions of the light emitting areas operating in the wide viewing angle mode and the positions of the light emitting areas operating in the narrow viewing angle mode can be variously changed along the first direction X and can be variously changed along the second direction Y.

The light emitting display apparatus according to an embodiment of the present disclosure can further include a touch screen disposed in the display area DA to sense the user's touch.

The touch screen can be bonded to the light emitting display panel 100 or can be embedded into the light emitting display panel 100.

For example, the light emitting display panel 100 can include a pixel driving circuit layer including transistors disposed on a substrate, a light emitting device layer including light emitting devices disposed on the pixel driving circuit layer, an encapsulation layer disposed to encapsulate the light emitting device layer, a touch sensor array including touch electrodes disposed on the encapsulation layer, and a lens array disposed on the touch sensor array. In this case, the light emitting display panel 100 can further include an optical film, an optical clear adhesive (OCA), a cover substrate, and a protection film which are sequentially disposed on the lens array. The light emitting display panel 100 can further include a color filter array including a color filter and a black matrix disposed between the touch sensor array and the lens array.

As described above, the gate driver 200 can generate gate signals GS and emission signals EM, and can also generate reference control signals RCS. In the following description, the gate signals GS, emission signals EM, and reference control signals RCS are referred to as scan signals.

That is, the gate driver 200 can supply at least one scan signal to each of the pixel row lines by using the gate control signal GCS supplied from the control driver 400. For example, a subpixel P to which three scan signals GS, EM, and RCS are supplied is illustrated in FIG. 2.

The transistors provided in the subpixels P and the transistors included in the gate driver 200 provided in the display area DA or the non-display area NDA can be formed by using at least one of an LTPS transistor using a low temperature poly silicon (LTPS) and an oxide transistor using a metal-oxide semiconductor. Particularly, in order to reduce power consumption, the LTPS transistor and the oxide transistor can coexist in the light emitting display panel 100.

The data driver 300 can include a data drive IC (Integrated Circuit) as illustrated in FIG. 1, and at least one data driver IC can be mounted on the light emitting display panel 100. FIG. 1 shows a light emitting display panel 100 on which four data drivers 300 consisting of four data driver ICs are mounted.

Each of the data driver ICs can be individually mounted on each circuit film. The circuit film on which the data drive IC is mounted can be bonded to the non-display area NDA in which a pad area of the display panel 100 is disposed through an anisotropic conductive film (ACF). The circuit film may be a chip on film (COF). Moreover, in addition to the COF, FPC (Flexible Printed Circuit) or FFC (Flexible Flat Cable) can be used as the circuit film.

The control driver 400 can control the gate driver 200 and the data driver 300 by using timing synchronization signals TSS supplied from the external system 600 and timing setting information stored therein.

To this end, the control driver 200 can generate gate control signal GCS which controls a driving timing of the gate driver 200 and supply them to the gate driver 200, and generate data control signal DCS which controls a driving timing of the data driver 300 and supply them to the data driver 300.

Moreover, the control driver 400 can perform various image processing which include image quality correction, deterioration correction, and luminance correction for the reduction of power consumption, for received input image data Ri, Gi, and Bi, and then can supply the image-processed data Data to the data driver 300.

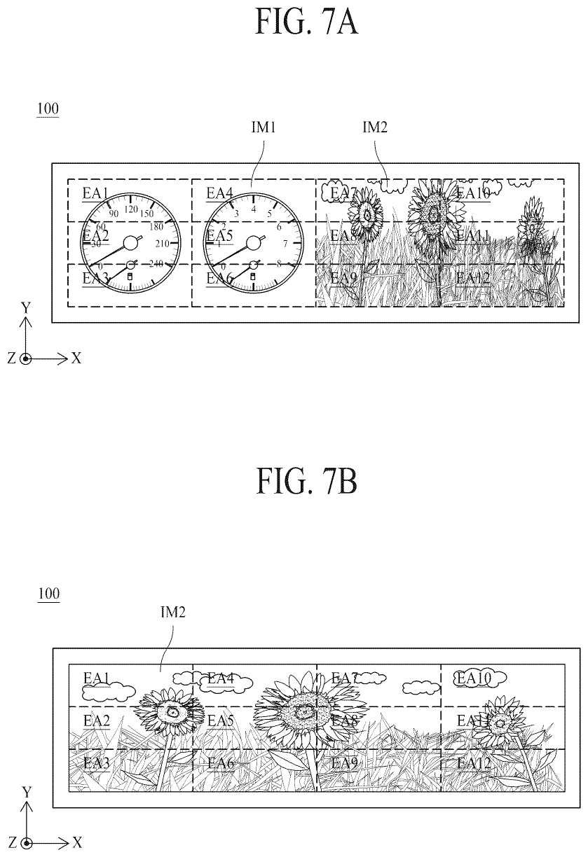

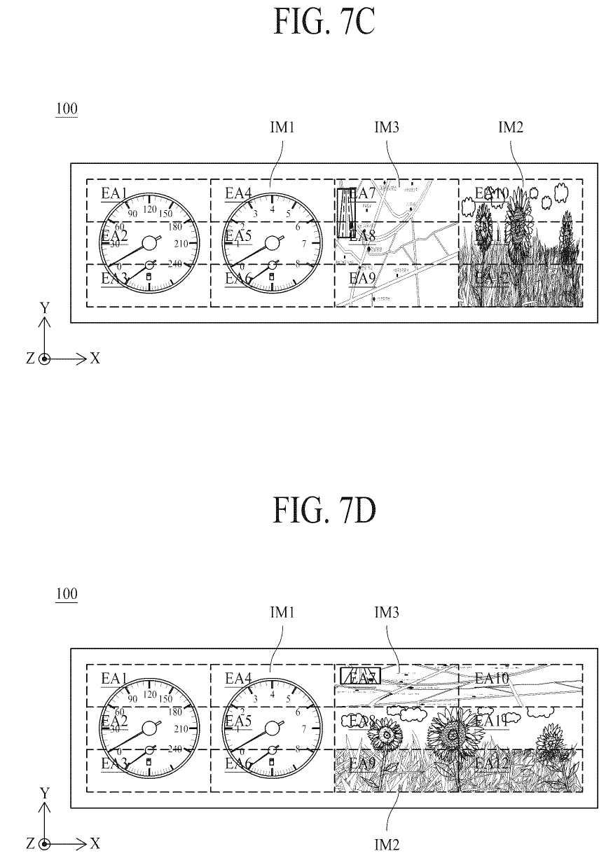

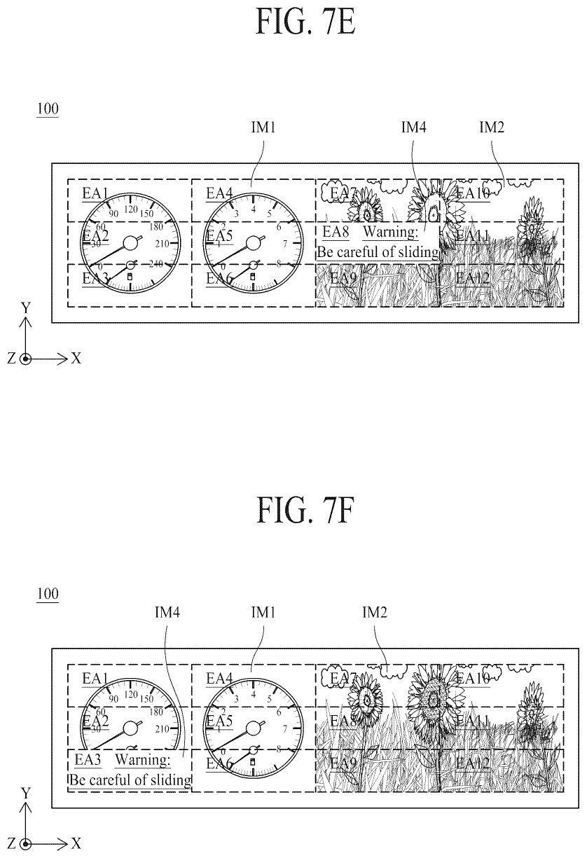

FIG. 6 is an exemplary diagram illustrating an internal structure of a vehicle to which a light emitting display apparatus according to an embodiment of the present disclosure is applied, and FIGS. 7A to 7F are exemplary diagrams illustrating how viewing angles of light emitting areas change in a light emitting display panel according to an embodiment of the present disclosure. Particularly, a light emitting display panel 100 divided into 12 light emitting areas EA1 to EA12 is illustrated in FIGS. 7A to 7F. Accordingly, hereinafter, a light emitting display apparatus according to an embodiment of the present disclosure will be described with reference to FIGS. 1 to 7F.

For example, as illustrated in FIG. 6, a light emitting display apparatus 10 according to an embodiment of the present disclosure can be placed in a center of a vehicle dashboard to display images to both a driver and a passenger in a passenger seat. For example, the light emitting display panel 100 of the light emitting display apparatus 10 can include first to 12th light emitting areas EA1 to EA12, and viewing angles of the first light emitting area EA1 to the 12th light emitting areas EA12 can be independently varied.

Here, the viewing angles mean the wide viewing angle and the narrow viewing angle. The wide viewing angle means a wider viewing angle than the narrow viewing angle. In the following description, a light emitting area where an image with the wide viewing angle is output is referred to as a wide viewing angle mode area or a share mode area, and a light emitting area where an image with the narrow viewing angle is output is referred to as a narrow viewing angle mode area or a privacy mode area.

First, referring to FIG. 7A, the first to 6th light emitting areas EA1 to EA6 of the light emitting display panel 100 (e.g., first light emitting areas) can provide a first image IM1 having the wide viewing angle in the left-right direction to a driver and a passenger of a passenger seat. As shown in FIG. 7A, each of the first to 6^{th} light emitting areas EA1 to EA6 emits light at the wide viewing angle where the emitted light corresponds to a portion of the first image IM1. The first to 6^{th} light emitting areas EA1 to EA6 collectively display the first image IM1 by having each light emitting area display a corresponding portion of the first image IM1. Thus, both a passenger and driver can view the first image IM1.

The first image IM1 can denote an image which provides information related to an operation of a vehicle (hereinafter simply referred to as a vehicle operation information image, and the vehicle operation information image can also be indicated by the reference numeral IM1). For example, as illustrated in FIG. 7A, the first image IM1 can provide a speed of a vehicle, a mileage of a vehicle, and an amount of fuel of a vehicle.

The vehicle operation information image needs to be seen not only by a driver but also to a passenger of the vehicle. Because the first image IM1 has a wide viewing angle, both a driver and a passenger can see the first image IM1. Accordingly, the first to 6th light emitting areas EA1 to EA6 can be the share mode areas.

Particularly, the vehicle operation information image should be displayed while the vehicle is operated, be displayed in a size which meets established standards, and be displayed in an area most visible to a driver. Therefore, while a vehicle (e.g., an object that includes the display device) is operated (e.g., moving) the display device is in an operation mode (e.g., a first mode) and the vehicle operation information image should be displayed unconditionally, regardless of a driver's choice, and the light emitting areas where the vehicle operation information image is output should also be fixed. For example, when the first image IM1 is the vehicle operation information image, the first image IM1 can be fixedly displayed in the first to 6th light emitting areas EA1 to EA6, as illustrated in FIG. 7A.

In this case, the 7th to 12th light emitting areas EA7 to EA12 of the light emitting display panel 100 can display a second image IM2 having the narrow viewing angle in the left-right direction to a passenger in a passenger seat but not the driver in the drive seat so as not to interfere with the driver's driving. As shown in FIG. 7A, each of the 7th to 12th light emitting areas EA7 to EA12 emits light at the narrow viewing angle where the emitted light corresponds to a portion of the second image IM2. The 7th to 12th light emitting areas EA7 to EA12 collectively display the second image IM2 by having each light emitting area display a corresponding portion of the first image IM2.

The second image IM2 is different from the first image IM1 during the operation mode. The second image IM2 can denote, for example, an image received through various communication networks (hereinafter simply referred to as a general image, and the general image can also be indicated by the reference numeral IM2). For example, the second image IM2 can be a television video, an internet video, or a playback file video.

Because the general image is not related to an operation of a vehicle, is provided by a passenger's choice, and attracts a driver's attention, the general image can be a distraction to the driver. Therefore, the second image IM2 does not need to be seen to the driver. Because the second image IM2 has the narrow viewing angle which is visible to a passenger but not the driver, a driver cannot see the second image IM2, and a passenger can see the second image IM2. Accordingly, the 7th to 12th light emitting areas EA7 to EA12 can be the privacy mode areas.

Referring to FIG. 7B, when a vehicle is parked or not operated the display device is in a non-operation mode (e.g., a second mode) and the first to 12th light emitting areas EA1 to EA12 can provide a driver and a passenger with the second image IM2 having the wide viewing angle in the left-right direction based on a user's choice. That is, the first to 6^{th} light emitting areas EA1 to EA6 display a first portion of the second image IM2 at the wide viewing angle and the 7^{th} to 12^{th} light emitting areas EA7 to EA12 display a second portion of the second image IM2 at the wide viewing angle to collectively display the second image IM2 during the non-operation mode. As shown in FIG. 7B, each of the Thus, both the driver and passenger can view the image IM2 while the vehicle is parked or not being operated and is thereby stationary.

Referring to FIG. 7C, the 7th to 12th light emitting areas EA7 to EA12 can be divided based on a user's choice. In this case, the 7th to 9th light emitting areas EA7 to EA9 can provide a third image IM3 having the wide viewing angle in the left-right direction to the driver and the passenger of a passenger seat, and the 10th to 12th light emitting areas EA10 to EA12 can provide the second image IM2.

The third image IM3 can denote an image which provides auxiliary information related to an operation of a vehicle (hereinafter simply referred to as a vehicle operation information auxiliary image, and the vehicle operation information auxiliary image can also be indicated by the reference numeral IM3). For example, as illustrated in FIG. 7C, the third image IM3 can provide location information (for example, navigation information).

The vehicle operation information auxiliary image IM3 needs to be seen by both the driver and the passenger. Because the third image IM3 has the wide viewing angle, both a driver and a passenger can see the third image IM3. Accordingly, the 7th to 9th light emitting areas EA7 to EA9 can be the share mode areas, and the 10th to 12th light emitting areas EA10 to EA12 can be the privacy mode areas.

Referring to FIG. 7D, the third image IM3 can be displayed through the 7th light emitting area EA7 and the 10th light emitting area EA10, and the second image IM2 can be displayed through the 8th light emitting area EA8, the 9th light emitting area EA9, the 11th light emitting area EA11, and the 12th light emitting area EA12.

That is, in a light emitting display apparatus according to an embodiment of the present disclosure, the share mode area and the privacy mode area can be changed along the first direction X of the light emitting display panel, as illustrated in FIGS. 7A to 7C, and can be changed along the second direction Y of the light emitting display panel, as illustrated in FIG. 7D.

Finally, at least one of the 7th to 12th light emitting areas EA7 to EA12, which were driven as privacy mode areas in FIG. 7A, can be changed to the share mode area to display the fourth image IM4. For example, as illustrated in FIG. 7E, the 8th light emitting area EA8 can be changed to the share mode area to display the fourth image IM4.

The fourth image IM4 can denote an image which provides emergency information related to an operation of a vehicle (hereinafter simply referred to as an emergency information image, and the emergency information image can also be indicated by the reference numeral IM4). For example, as illustrated in FIG. 7E, the fourth image IM4 can be an image indicating that there is a dangerous object in front of a vehicle. The emergency information images IM4 can be collected through various sensors mounted on a vehicle. Furthermore, the emergency information image IM4 may be a disaster message provided by the government or local governments to citizens across the country or in a specific region through various communication networks, or may be an image provided through a navigation system mounted in a vehicle.

However, as illustrated in FIGS. 7A and 7F, the fourth image IM4 can be displayed through at least one (e.g., the third light emitting area EA3) of the first to 6th light emitting areas EA1 to EA6 which are driven in the share mode area.

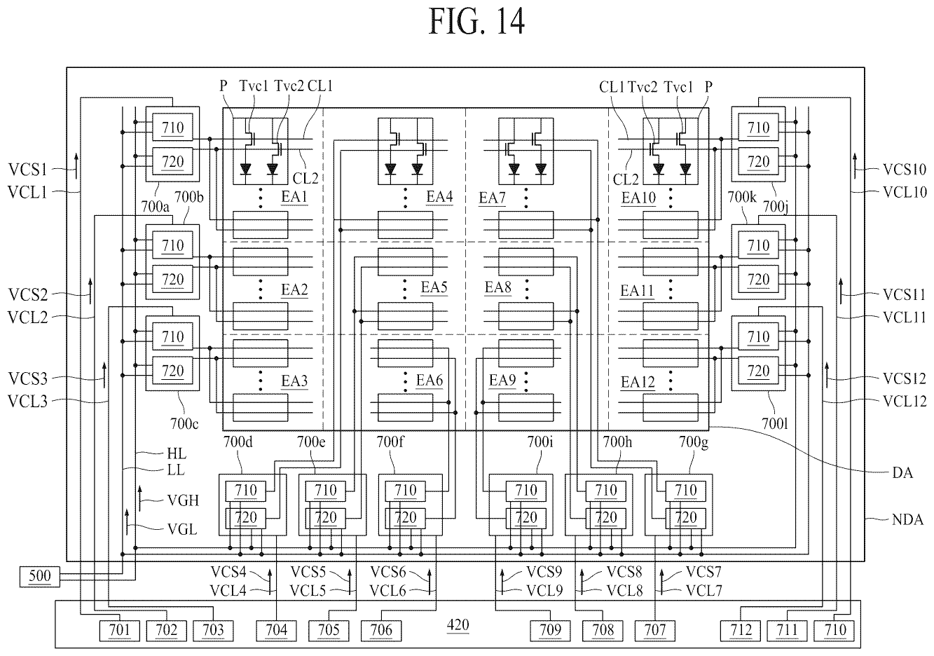

A specific method of changing the share mode area and the privacy mode area will be described below with reference to FIGS. 14 to 25.

A light emitting display apparatus 10 according to an embodiment of the present disclosure is not limited to the light emitting display apparatus for a vehicle as described above, and thus can be applied to various light emitting display apparatus such as a light emitting display apparatus for a mobile, a light emitting display apparatus for an IT device, and a light emitting display apparatus for TV.

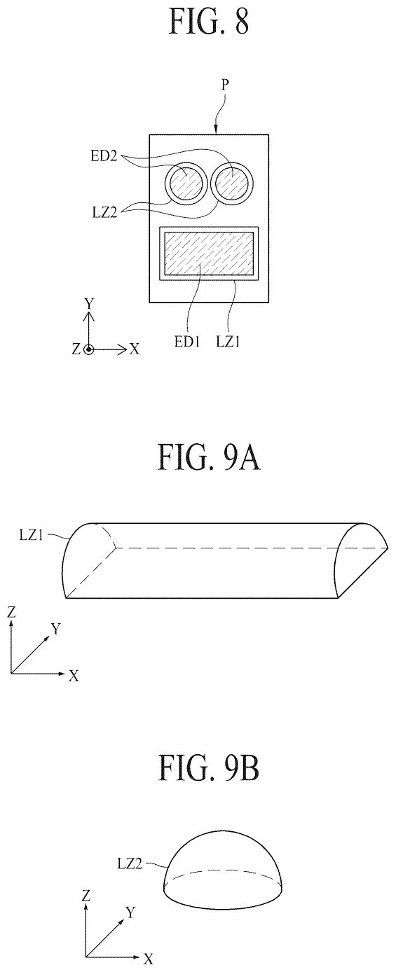

FIG. 8 is an exemplary plan view schematically illustrating a structure of a subpixel of a light emitting display panel according to an embodiment of the present disclosure, and FIGS. 9A and 9B are exemplary perspective views illustrating structures of a first lens and a second lens of a subpixel applied to a light emitting display panel according to an embodiment of the present disclosure.

As illustrated in FIG. 8, a subpixel P applied to a light emitting display panel according to an embodiment of the present disclosure can includes the first light emitting device ED1, the second light emitting device ED2, a first lens LZ1 disposed on the first light emitting device ED1, and a second lens LZ2 disposed on the second light emitting device ED2.

The first lens LZ1 can be disposed on a light traveling path of the first light emitting device ED1. The second lens LZ2 can be disposed on a light traveling path of the second light emitting device ED2. Here, the light traveling path may be, for example, a third direction Z vertical to the first direction X and the second direction Y. For example, the first lens LZ1 and the first light emitting device ED1 can be provided along the third direction Z, and the second lens LZ2 and the second light emitting device ED2 can be provided along the third direction Z.

The subpixel P can include at least two second light emitting devices ED2, and the second lens LZ2 can be provided on the light traveling path of each of the at least two second light emitting devices ED2. The at least two second light emitting devices ED2 can share one first electrode (for example, an anode) in the subpixel P.

In the subpixel P, an area where the first lens LZ1 is disposed can be referred to as a first lens area, and an area where the second lens LZ2 is disposed can be referred to as a second lens area.

As illustrated in FIG. 9A, the first lens LZ1 may be a half-cylindrical lens elongated in the first direction X. As illustrated FIG. 9B, the second lens LZ2 may be a half-spherical lens. However, the shape of the first lens LZ1 and the shape of the second lens LZ2 can be variously changed.

In the following description, the first direction X can be expressed in a left-right direction, a widthwise direction, a horizontal direction, or an X-axis direction. The second direction Y can be expressed in an up-down direction, a lengthwise direction, a vertical direction or a Y axis direction. The third direction Z can be expressed in a front-rear direction, a thickness direction of a light emitting display panel 100, or a Z-axis direction.

The first lens LZ1 and the second lens LZ2 can differently control (limit) a viewing angle in the left-right direction X and can equally control (limit) a viewing angle in the up-down direction Y.

For example, because the first lens LZ1 does not limit a traveling path of a light emitted from the first light emitting device ED1 within a specific angle in the left-right direction X, the first lens LZ1 can control the first viewing angle corresponding to the wide viewing angle. The second lens LZ2 cam control the second viewing angle to the narrow viewing angle by limiting a traveling path of a light emitted from the second light emitting device ED2 within a specific angle in the left-right direction X.

Both the first lens LZ1 and the second lens LZ2 can control a viewing angle to the narrow viewing angle by limiting a light traveling path within a specific angle in the up-down direction Y. Accordingly, in a case when, as illustrated in FIG. 6, a light emitting display apparatus 10 is applied to a vehicle, a driver's view is prevented from being disturbed by images which is displayed on the light emitting display panel 100 to be reflected by a front glass of a vehicle.

When the first light emitting device ED1 is driven in the subpixel P, the subpixel P can operate in the wide viewing angle mode which does not limit a viewing angle in the left-right direction X.

When the second light emitting device ED2 is driven in the subpixel P, the subpixel P can operate in the narrow viewing angle mode which limits a viewing angle in the left-right direction X. The wide viewing angle mode can be described as a first mode, and the narrow viewing angle mode can be described as a second mode.

By switching the driving of the first light emitting device ED1 and the second light emitting device ED2 of the subpixel P, the subpixel P can be switched between the wide viewing angle mode and the narrow viewing angle mode.

To provide an additional description, as described above, the first light emitting unit can include the first light emitting device ED1 driven by the first viewing angle control transistor Tvc1 and the first lens LZ1 disposed on the first light emitting device, and the second light emitting unit can include the second light emitting device ED2 driven by the second viewing angle control transistor Tvc2 and the second lens LZ2 disposed on the second light emitting device.

In this case, the first light emitting units or the second light emitting units can be driven in each of the light emitting areas EA1 to EA12. For example, in each of the light emitting areas, the first light emitting device ED1 provided in the first light emitting unit can be driven without the second light emitting device ED2 being driven, or the second light emitting device ED2 provided in the second light emitting unit can be driven without the first light emitting device ED1 being driven. Accordingly, in each of the light emitting areas EA, light having the wide viewing angle can be output through the first lens LZ1, or light having the narrow viewing angle can be output through the second lens LZ2.

Accordingly, each of the light emitting areas can be the wide viewing angle mode area or the narrow viewing angle mode area.

Moreover, because the viewing angles of the light emitting areas can be controlled independently, the light emitting area can be the wide viewing angle mode area or the narrow viewing angle mode area, regardless of the position of the light emitting area.

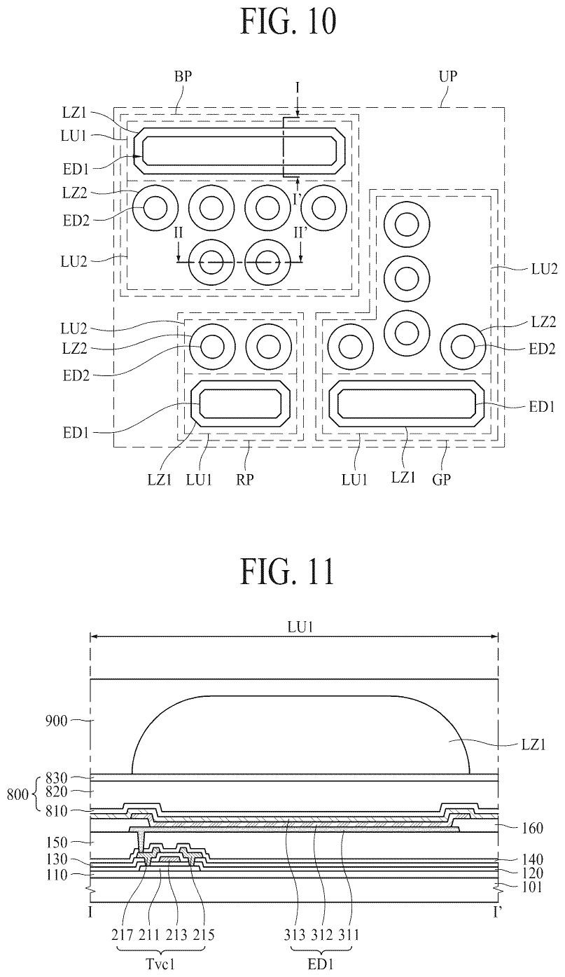

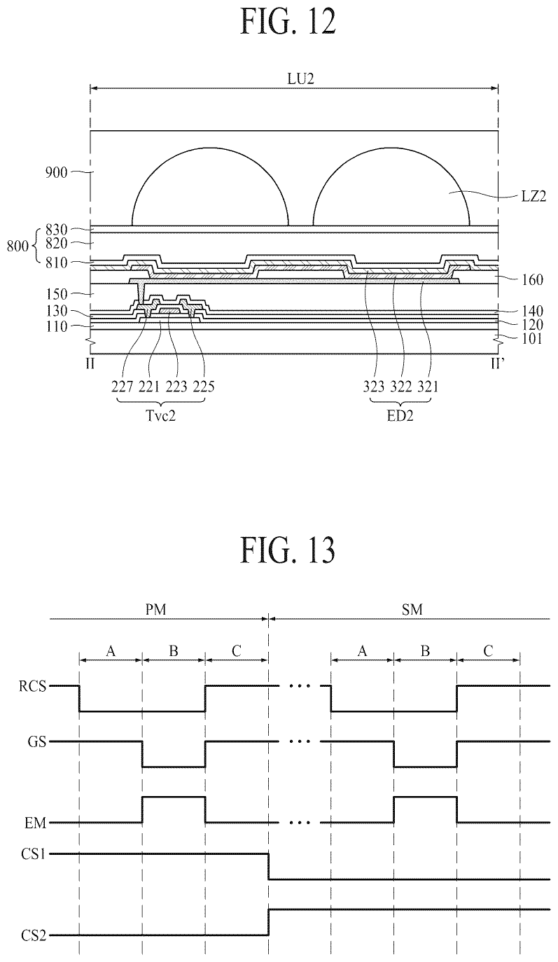

FIG. 10 is an exemplary plan view illustrating a structure of three subpixels applied to a light emitting display panel according to an embodiment of the present disclosure, FIG. 11 is an exemplary cross-sectional view taken along line I-I′ illustrated in FIG. 10 according to an embodiment of the present disclosure, and FIG. 12 is an exemplary cross-sectional view taken along line II-II′ illustrate in FIG. 10 according to an embodiment of the present disclosure. Particularly, FIG. 10 illustrates three subpixels BP, RP, and GP configuring a unit pixel UP, FIG. 11 illustrates a cross-sectional surface of the first light emitting unit LU1, and FIG. 12 illustrates a cross-sectional surface of the second light emitting unit. LU2.

For example, the unit pixel UP capable of outputting white light can include a blue subpixel BP which emits blue light, a red subpixel RP which emits red light, and a green subpixel GP which emits green light, as illustrated in FIG. 10.

The blue subpixel BP can include a first light emitting unit LU1 and a second light emitting unit LU2. The first light emitting unit LU1 can include a first light emitting device ED1 driven by a first viewing angle control transistor Tvc1 and a first lens LZ1 overlapping the first light emitting device ED1. The second light emitting unit LU2 can include a second light emitting device ED2 driven by a second viewing angle control transistor Tvc2 and a second lens LZ2 overlapping the second light emitting device.

The red subpixel RP can include a first light emitting unit LU1 and a second light emitting unit LU2. The first light emitting unit LU1 can include a first light emitting device ED1 driven by a first viewing angle control transistor Tvc1 and a first lens LZ1 overlapping the first light emitting device ED1. The second light emitting unit LU2 can include a second light emitting device ED2 driven by a second viewing angle control transistor Tvc2 and a second lens LZ2 overlapping the second light emitting device.

The green subpixel GP can include a first light emitting unit LU1 and a second light emitting unit LU2. The first light emitting unit LU1 can include a first light emitting device ED1 driven by a first viewing angle control transistor Tvc1 and a first lens LZ1 overlapping the first light emitting device ED1. The second light emitting unit LU2 can include a second light emitting device ED2 driven by a second viewing angle control transistor Tvc2 and a second lens LZ2 overlapping the second light emitting device.

In each of the blue subpixel BP, red subpixel RP, and green subpixel GP, as described with reference to FIGS. 9A and 9B, the first lens LZ1 and the second lens LZ2 can differently control a viewing angle in the left-right direction X and can equally control a viewing angle in the up-down direction Y.

Each of the first light emitting units LU1 of the unit pixel UP can include one first light emitting device ED1 and one first lens LZ1. Each of the second light emitting units LU2 of the unit pixel UP can include at least one second light emitting device ED2 and at least one second lens LZ2. In this case, the at least two second light emitting devices ED2 can share a first electrode (for example, an anode) 321, a light emitting layer 322, and a second electrode (for example, a cathode) 323, as illustrated in FIG. 12.

The first light emitting device ED1 included in the first light emitting unit LU1 can have the same shape as a lower surface of the first lens LZ1. The size of the first lens LZ1 can be set to be larger than the size of the first light emitting device ED1 to improve the emission efficiency of light generated from the first light emitting device ED1.

The second light emitting device ED2 included in the second light emitting unit LU2 can have the same shape as the lower surface of the second lens LZ2. The size of the second lens LZ2 can be set to be larger than the size of the second light emitting device ED2 to improve the emission efficiency of light generated from the second light emitting device ED2.

The areas of the second light emitting devices ED2 included in the second light emitting units LU2 can be the same.

However, the number of second light emitting devices ED2 included in the second light emitting unit LU2 can vary for each subpixel BP, RP, and GP. For example, as illustrated in FIG. 10, the number of second light emitting devices ED2 disposed in the second light emitting unit LU2 of the blue subpixel BP can be greater than the number of the second light emitting devices ED2 disposed in the second light emitting unit LU2 of the red subpixel RP. The number of second light emitting devices ED2 disposed in the second light emitting unit LU2 of the red subpixel RP can be less than the number of the second light emitting devices ED2 disposed in the second light emitting unit LU2 of the green subpixel GP. Accordingly, the efficiency deviation of the blue subpixel BP, red subpixel RP, and green subpixel GP in the unit pixel UP can be compensated by the number of the second light emitting device ED2 disposed in the second light emitting unit LU2.

The size of the first light emitting device ED1 can be different for each subpixel P. For example, as illustrated in FIG. 10, the size of the first light emitting device ED1 of the blue subpixel BP can be larger than the size of the first light emitting device ED1 of the red subpixel RP. Moreover, the size of the first light emitting device ED1 of the red subpixel RP can be smaller than the size of the first light emitting device ED1 of the green subpixel GP. Accordingly, the efficiency deviation of the blue subpixel BP, red subpixel RP, and green subpixel GP in the unit pixel UP can be compensated by the sizes of the first light emitting devices ED1 disposed in the first light emitting units LU1.

A light emitting display panel 100 according to an embodiment of the present disclosure, as illustrated in FIGS. 11 and 12, can include a pixel driving circuit layer which includes a substrate 101 and transistors Tvc1 and Tvc2 disposed on the substrate 101, a light emitting device layer which includes light emitting devices ED1 and ED2 disposed on the pixel driving circuit layer, an encapsulation layer 800 disposed on the light emitting device layer, and a lens layer which includes lenses LZ1 and LZ2 disposed on the encapsulation layer 800.

A light emitting display panel 100 according to an embodiment of the present disclosure can further include a touch sensor layer disposed between the encapsulation layer 800 and the lens layer. A light emitting display panel 100 according to an embodiment of the present disclosure can further include a color filter layer including a color filter and a black matrix which are disposed between the touch sensor layer and the lens layer.

Hereinafter, a cross-sectional structure of a subpixel is described with reference to FIGS. 10 to 12. FIGS. 11 and 12 illustrate cross-sectional surfaces of the blue subpixel BP illustrated in FIG. 10. However, each of the red subpixel RP and the green subpixel GP can also have the cross-sectional structures illustrated in FIGS. 11 and 12.

That is, each of the subpixels BP, RP, and GP of the light emitting display panel according to an embodiment of the present disclosure can include the first light emitting unit LU1 illustrated in FIG. 11 and the second light emitting unit LU2 illustrated in FIG. 12.

As illustrated in FIG. 11, the first light emitting unit LU1 of the subpixel P can include the first viewing angle control transistor Tvc1, the first light emitting device ED1 connected to the first viewing angle control transistor Tvc1, and the first lens LZ1 disposed on the first light emitting device ED1 to overlap the first light emitting device ED1.

As illustrated in FIG. 12, the second light emitting unit LU2 of the subpixel P can include the second viewing angle control transistor Tvc2, the second light emitting device ED2 connected to the second viewing angle control transistor Tvc2, and at least one second lens LZ2 disposed on the second light emitting device ED2 to overlap the second light emitting device ED2.

In the light emitting display panel 100 according to an embodiment of the present disclosure, the pixel driving circuit layer disposed on the substrate 101 can include insulation layers stacked on the substrate 101. For example, the insulation layers can include a buffer layer 110, a gate insulation layer 120, an interlayer insulation layer 130, a passivation layer 140, and a planarization layer 150.

The substrate 101 can include an insulation material such as glass or plastic. The plastic substrate can be formed of a flexible material. For example, the substrate 101 can include at least one of acrylic resin, epoxy resin, siloxane resin, polyimide resin, and polyamide resin. That is, the substrate 101 can include an organic insulation material.

The buffer layer 110 can include an inorganic insulation material such as silicon oxide (SiOx), silicon nitride (SiNx), and aluminum oxide (Al2O3), and can have a single-layer or multi-layer structure. The buffer layer 110 can prevent impurities such as hydrogen from flowing into semiconductor layers 211 and 221 through the substrate 101.

Various transistors configuring the subpixel P can be provided on the buffer layer 110. For example, the first viewing angle control transistor Tvc1 and the second viewing angle control transistor Tvc2 can be disposed.

Each of the transistors provided in the subpixel P can include a gate electrode, a source electrode, and a drain electrode. In this case, the source electrode and drain electrode are not fixed and can change depending on the voltage and current direction applied to the gate electrode. Accordingly, one of the source electrode and the drain electrode can be referred to as a first electrode, the other can be referred to as a second electrode. The transistors of the subpixel P can use at least one of polysilicon semiconductor, amorphous silicon semiconductor, and oxide semiconductor. The transistors of the subpixel P can be P-type transistors or N-type transistors, and the subpixel P can include both P-type transistors and N-type transistors.

The first viewing angle control transistor Tvc1 includes a semiconductor layer 211, a gate electrode 213, a source electrode 215, and a drain electrode 217 which are disposed on an upper end of the buffer layer 110. The second viewing angle control transistor Tvc2 includes a semiconductor layer 221, a gate electrode 223, a source electrode 225, and a drain electrode 227 which are disposed on the buffer layer 110.

A gate insulation layer 120 can be disposed between the semiconductor layers 211 and 221 and the gate electrodes 213 and 223. An interlayer insulation layer 130 can be disposed between the gate electrodes 213 and 223 and the source and drain electrodes 215, 217, 225, and 227. The source electrode 215 and drain electrode 217 of the first viewing angle control transistor Tvc1 can be connected to a source region and drain region of the semiconductor layer 211 through contact holes penetrating the interlayer insulation layer 130 and the gate insulation layer 120. The source electrode 225 and drain electrode 227 of the second viewing angle control transistor Tvc2 can be connected to a source region and drain region of the semiconductor layer 221 through contact holes penetrating the interlayer insulation layer 130 and the gate insulation layer 120.

The semiconductor layers 211 and 221 can include polycrystalline silicon, an oxide semiconductor material, or low temperature polysilicon (LPTS). The semiconductor layers 211 and 221 can include at least one selected from IZO (InZnO)-based, IGO (InGaO)-based, ITO (InSnO)-based, IGZO (InGaZnO)-based, IGZTO (InGaZnSnO)-based, GZTO (GaZnSnO)-based, and GZO (GaZnO)-based, and ITZO (InSnZnO)-based oxide semiconductor materials. A light blocking layer can be further disposed under the semiconductor layers 211 and 221.

The gate insulation layer 120 can include an inorganic insulation material such as silicon oxide (SiOx) and silicon nitride (SiNx). The gate insulation layer 120 can include a material with a high dielectric constant. For example, the gate insulation layer 120 can include a high-K material such as hafnium oxide (HfO). The gate insulation layer 120 can have a multi-layer structure.

Gate lines connected to the gate electrodes 213 and 223 can be disposed on the gate insulation layer 120.

The interlayer insulation layer 130 can include an inorganic insulation material such as silicon oxide (SiOx) and silicon nitride (SiNx). The interlayer insulation layer 130 can have a multi-layer structure.

Data lines connected to the source electrodes 215 and 225 or the drain electrodes 217 and 227 and power lines can be disposed on the interlayer insulation layer 130.

A passivation layer 140 and a planarization layer 150 can be stacked on the first and second viewing angle control transistors Tvc1 and Tvc2. The passivation layer 140 can include an inorganic insulation material such as silicon oxide (SiOx) and silicon nitride (SiNx). The planarization layer 150 can include an organic insulation material different from that of the passivation layer 140 and can provide a flat surface.

A light emitting device layer including the first light emitting device ED1 and the second light emitting device ED2 can be disposed on the planarization layer 150.

The first light emitting device ED1 includes a first electrode 311 disposed on the planarization layer 150, a light emitting layer 312 disposed on the first electrode 311, and a second electrode 313 disposed on the light emitting layer 312. The second light emitting device ED2 includes a first electrode 321 disposed on the planarization layer 150, a light emitting layer 322 disposed on the first electrode 321, and a second electrode 323 disposed on the light emitting layer 322. The first light emitting device ED1 and the second light emitting device ED2 disposed in the subpixel P can emit light of the same color.

The first electrode 311 of the first light emitting device ED1 can be connected to any one of the source electrode 215 and the drain electrode 217 of the first viewing angle control transistor Tvc1 through a contact hole penetrating the planarization layer 150 and the passivation layer 140. The first electrode 321 of the second light emitting device ED2 can be connected to any one of the source electrode 225 and the drain electrode 227 of the second viewing angle control transistor Tvc2 through a contact hole penetrating the planarization layer 150 and the passivation layer 140.

The first electrodes 311 and 321 can include a conductive material with high reflectivity. The first electrodes 311 and 321 can include metal such as aluminum (Al), silver (Ag), titanium (Ti), and silver-palladium-copper (APC) alloy. The first electrodes 311 and 321 can further include a transparent conductive material such as indium tin oxide (ITO) or indium zinc oxide (IZO). For example, the first electrodes 311 and 321 can have a multi-layer structure Ti/Al/Ti of titanium (Ti) and aluminum (Al), a multi-layer structure ITO/Al/ITO of ITO and aluminum (Al), or a multi-layer structure ITO/APC/ITO of ITO and APC.

The light emitting layers 312 and 322 can include an emission material layer (EML) including a light emitting material. The light emitting material can include an organic material, an inorganic material, or hybrid material. The light emitting layer 312 of the first light emitting device ED1 and the light emitting layer 322 of the second light emitting device ED2 can be spaced apart from each other. Accordingly, light emission due to leakage current can be prevented.

The light emitting layers 312 and 322 can have a multi-layer structure. For example, the light emitting layers 312 and 322 can further include at least one of a hole injection layer (HIL), a hole transport layer (HTL), an electron injection layer (EIL).

The second electrodes 313 and 323 can include a conductive material which can transmits light therethrough. The second electrodes 313 and 323 can include a transparent conductive material such as ITO or IZO. The second electrodes 313 and 323 can include aluminum (Al), magnesium (Mg), silver (Ag), or an alloy thereof, and can have a thin thickness capable of transmitting light. Accordingly, light generated in each of the light emitting layers 312 and 322 can be emitted through the second electrodes 313 and 323.

The first electrode 311 of the first light emitting device ED1 can be spaced apart from the first electrode 321 of the second light emitting device ED2, and a bank insulation layer 160 can be provided between the first electrodes 311 and 321. The bank insulation layer 160 can cover the edge of each of the first electrodes 311 and 321. The bank insulation layer 160 can include an organic insulation material. The bank insulation layer 160 can include an organic material different from that of the planarization layer 150 and can have a single-layer or double-layer structure.

The bank insulation layer 160 can include an opening portion through which the first electrode 311 of the first light emitting device ED1 is exposed, and light can be output through the opening portion. The light emitting layer 312 and the second electrode 313 of the first light emitting device ED1 can be stacked on the first electrode 311 exposed by the opening portion of the bank insulation layer 160.

The bank insulation layer 160 can include an opening portion through which the first electrode 321 of the second light emitting device ED2 is exposed, and light can be output through the opening portion. The bank insulation layer 160 can include at least two opening portions provided on the first electrode 321, and thus, at least two second light emitting devices ED2 can be formed.

The light emitting layer 322 and the second electrode 323 of the second light emitting device ED2 can be stacked on the first electrode 321 exposed by the opening portion of the bank insulation layer 160. The light emitting layer 322 and the second electrode 323 of the second light emitting device ED2 can overlap the first electrode 321. In the second light emitting unit LU2, at least two second light emitting devices ED2 are independently arranged and spaced apart from each other by the bank insulation layer 160, but the second light emitting devices ED2 can share the first electrode 321, the light emitting layer 322, and the second electrode 323. Accordingly, the luminous efficiency of the second light emitting devices ED2 can be improved. The size of the second light emitting device ED2 may be smaller than the size of the first light emitting device ED1.

The second electrode 313 of the first light emitting device ED1 can be a common electrode electrically connected to the second electrode 323 of the second light emitting device ED2.

An encapsulation layer 800 can be disposed on the light emitting device layer including the first light emitting device ED1 and the second light emitting device ED2. The encapsulation layer 800 can prevent the light emitting devices ED1 and ED2 from being damaged by moisture and impact from the outside. The encapsulation layer 800 can have a multi-layer structure. For example, the encapsulation layer 800 can include a first encapsulation layer 810, a second encapsulation layer 820, and a third encapsulation layer 830, but not limited thereto. The first encapsulation layer 810, the second encapsulation layer 820, and the third encapsulation layer 830 can include an insulating material. The second encapsulation layer 820 can include a material different from that of the first encapsulation layer 810 and the third encapsulation layer 830. For example, the first encapsulation layer 810 and the third encapsulation layer 830 can be inorganic encapsulation layers including an inorganic insulation material, and the second encapsulation layer 820 can include an organic encapsulation layer including an organic insulation material. Accordingly, it is possible to more effectively prevent the light emitting devices ED1 and ED2 from being damaged by moisture and impact from the outside.

A lens layer including the first lens LZ1 and the second lens LZ2 can be disposed on the encapsulation layer 800.

The first lens LZ1 can be disposed on an upper end of the first light emitting device ED1 in the first light emitting unit LU1. The first lens LZ1 does not limit the path of light generated in the first light emitting device ED1 to the left-right directions. Accordingly, the first lens LZ1 can output light having the wide viewing angle in the left-right direction. For example, the first lens LZ1 does not limit the path of light emitted from the first light emitting device ED1 to within a specific angle in the left-right direction. Accordingly, the first lens LZ1 can output light having the wide viewing angle in the left-right direction. Further, the first lens LZ1 can limit the path of light generated in the first light emitting device ED1 to within a certain angle in the up-down direction, and thus can output light having the narrow viewing angle in the up-down direction.

The second lens LZ2 can be disposed on an upper end of the second light emitting device ED2 in the second light emitting unit LU2. The second lens LZ2 limits the path of light generated in the second light emitting device ED2 to the left-right direction. Accordingly, the second lens LZ2 can output light having the narrow viewing angle in the left-right direction. For example, the second lens LZ2 limits the path of light emitted from the second light emitting device ED2 to the left-right direction. Accordingly, the second lens LZ2 can output light having the narrow viewing angle in the left-right direction. Further, the second lens LZ2 can limit the path of light generated in the second light emitting device ED2 to within a specific angle in the up-down direction, and thus can output light having the narrow viewing angle in the up-down direction.

A lens passivation layer 900 can be provided on the first lens LZ1 and the second lens LZ2 of each subpixel area. The lens passivation layer 900 can include an organic insulation material. The refractive index of the lens passivation layer 900 can be smaller than the refractive index of the first lens LZ1 and the refractive index of the second lens LZ2. Accordingly, light passing through the first lens LZ1 and the second lens LZ2 cannot be reflected toward the direction of the substrate 101.

FIG. 13 is an exemplary timing diagram for explaining a basic driving method of a light emitting display apparatus according to an embodiment of the present disclosure.

In a light emitting display apparatus according to the present disclosure, in a state where one of the first viewing angle control transistor Tvc1 and the second viewing angle control transistor Tvc2 provided in the subpixel P is turned on, the pixel driving circuit PDC can be driven. Accordingly, in each of the subpixels P, only the first light emitting device ED1 connected to the first viewing angle control transistor Tvc1 can output light, or only the second light emitting device ED2 connected to the second viewing angle control transistor Tvc2 can output light.

The light output from the first light emitting device ED1 can have the first viewing angle (wide viewing angle), and the light output from the second light emitting device ED2 can have the second viewing angle (narrow viewing angle).

Accordingly, an image having the first viewing angle (wide viewing angle) can be displayed in a light emitting area where light is output only from the first light emitting devices ED1, and an image having the second viewing angle (narrow viewing angle) can be displayed in a light emitting area where light is output only from the second light emitting devices ED2.

The pixel driving circuit PDC applied to a light emitting display apparatus according to the present disclosure can include the light emitting control unit ECU and the viewing angle control unit VCU, as described with reference to FIG. 2.

The viewing angle control unit VCU can include the first viewing angle control transistor Tvc1 connected to the first light emitting device ED1 and the second viewing angle control transistor Tvc2 connected to the second light emitting device ED2. A gate of the first viewing angle control transistor Tvc1 can be connected to a first control signal line CL1 and a gate of the second viewing angle control transistor Tvc2 can be connected to a second control signal line CL2.

In this case, the polarity type of the first viewing angle control transistor Tvc1 can be the same as the polarity type of the second viewing angle control transistor Tvc2. For example, when the first viewing angle control transistor Tvc1 is a P-type transistor, as illustrated in FIG. 2, the second viewing angle control transistor Tvc2 can also be a P-type transistor.

The light emitting control unit ECU can perform a function of supplying current to the first viewing angle control transistor Tvc1 or the second viewing angle control transistor Tvc2. To this end, the light emitting control unit ECU can be formed in the structure illustrated in FIG. 2, and can be changed to various structures other than the structure illustrated in FIG. 2.

Further, the driving method for turning on the driving transistor Tdr included in the light emitting control unit ECU to supply current to the first viewing angle control transistor Tvc1 or the second viewing angle control transistor Tvc2 can also be changed in various ways.

Therefore, hereinafter, the basic driving method of the light emitting display apparatus according to the present disclosure will be briefly described with reference to the pixel driving circuit PDC illustrated in FIG. 2 and the timing diagram illustrated in FIG. 13.

Particularly, hereinafter, the basic driving method of the light emitting display apparatus according to the present disclosure will be briefly described with reference to an 8th light emitting area EA8 which is converted to the share mode (SM), where the emergency information image IM4 with the first viewing angle (wide viewing angle) is output, from the privacy mode (PM) where the general image IM2 with the second viewing angle (narrow viewing angle) is output, as illustrated in FIG. 7E.

First, for example, when the 8th light emitting area EA8 is driven in the privacy mode (PM), a first control signal CS1 having a high level, as illustrated in FIG. 13, can be supplied to gates of the first viewing angle control transistors Tvc1 of the subpixels P provided in the 8th light emitting area EA8. In this case, a second control signal CS2 having a low level, as illustrated in FIG. 13, can be supplied to gates of the second viewing angle control transistors Tvc2 of the subpixels P provided in the 8th light emitting area EA8.

That is, the level of the first control signal CS1 supplied to the subpixels P provided in the 8th light emitting area EA8 is different from the level of the second control signal CS2 supplied to the subpixels P provided in the 8th light emitting area EA8. For example, when the first control signal CS1 has the high level, the second control signal CS2 has the low level.

In this case, as illustrated in FIG. 2, the first viewing angle control transistor Tvc1 and the second viewing angle control transistor Tvc2 which are provided in the subpixels P can be P-type transistors.

Accordingly, while the 8th light emitting area EA8 is driven in the privacy mode (PM), the first viewing angle control transistors Tvc1 provided in the subpixels P of the 8th light emitting area EA8 can be turned off by the first control signal CS1 having the high level, and the second viewing angle control transistors Tvc2 provided in the subpixels P of the 8th light emitting area EA8 can be turned on by the second control signal CS2 having the low level.

Next, as illustrated in FIG. 13, when a reference control signal RCS having a low level, a gate signal GS having a high level, and an emission signal EM having a low level are supplied to a kth pixel row line (k is a natural number less than or equal to g) provided in the 8th light emitting area EA8, the first emission transistor Tsw4a, the second emission transistor Tsw4b, the first reference transistor Tsw2a, the second reference transistor Tsw2b, and the connection transistor Tsw3 which are provided in the subpixel P of a kth pixel row line can be turned on, and the switching transistor Tsw1 can be turned off. Here, the kth pixel row line can denote a pixel row line provided in the 8th light emitting area EA8, and particularly, the kth pixel row line can denote the subpixels provided along the first direction X in the 8th light emitting area EA8.

Accordingly, through the first emission transistor Tsw4a, the second emission transistor Tsw4b, the first reference transistor Tsw2a, the second reference transistor Tsw2b, and the connection transistor Tsw3, a reference voltage VREF can be supplied to the gate of the driving transistor Tdr, the first electrode (anode) of the first light emitting device ED1, and the first electrode (anode) of the second light emitting device ED2.

Therefore, the gate of the driving transistor Tdr, the first electrode (anode) of the first light emitting device ED1, and the first electrode (anode) of the second light emitting device ED2 can be initialized by the reference voltage VREF.

If the second terminal of the first reference transistor Tsw2a is connected to the first terminal of the first viewing angle control transistor Tvc1 and the second terminal of the second reference transistor Tsw2b is connected to the first terminal of the second viewing angle control transistor Tvc2, because the first viewing angle control transistor Tvc1 is turned off, only the second light emitting device ED2 can be initialized by the reference voltage VREF transmitted through the second reference transistor Tsw2b and the second viewing angle control transistor Tvc2.

Hereinafter, a period during which the reference control signal RCS having the low level, the gate signal GS having the high level, and the emission signal EM having the low level are supplied to the kth pixel row line provided in the 8th light emitting area EA8 is referred to as an initialization period A.

Next, after the initialization period A, a sampling period B begins.

In the sampling period B, as illustrated in FIG. 13, when the reference control signal RCS having the low level, the gate signal GS having the low level, and the emission signal EM having the high level are supplied to the kth pixel row line provided in the 8th light emitting area EA8, the switching transistor Tsw1, the first reference transistor Tsw2a, the second reference transistor Tsw2b, and the connection transistor Tsw3 which are provided in the subpixel connected to the kth pixel row line can be turned on and the first emission transistor Tsw4a and the second emission transistor Tsw4b can be turned off. In this case, the driving transistor Tdr can also be turned on. Because the second emission transistor Tsw4b is turned off, even if the driving transistor Tdr is turned on, current is not supplied to the second light emitting device ED2 through the second viewing angle control transistor Tvc2.

Accordingly, the data voltage Vdata transmitted through the data line DL can be charged to the first terminal of the storage capacitor Cst through the switching transistor Tsw1.

In this case, the gate of the driving transistor Tdr, which is the second terminal of the storage capacitor Cst, can be charged with the first voltage VDD and the threshold voltage (Vth) of the driving transistor Tdr.

Next, after the sampling period B, an emission period C begins.

In the emission period C, as illustrated in FIG. 13, when the reference control signal RCS having the high level, the gate signal GS having the high level, and the emission signal EM having the low level are supplied to the kth pixel row line provided in the 8th light emitting area EA8, the switching transistor Tsw1, the first reference transistor Tsw2, the second reference transistor Tsw2b, and the connection transistor Tsw3 which are provided in the subpixel P connected to the kth pixel row line can be turned off, and the first emission transistor Tsw4a and the second emission transistor Tsw4b can be turned on.

Accordingly, the first terminal of the storage capacitor Cst can be charged with the reference voltage VREF.

In this case, a gate voltage (Vg) can be supplied to the gate of the driving transistor Tdr, which is the second terminal of the storage capacitor Cst (for example, Vg=VREF−Vdata+ELVDD+Vth). A source voltage (Vs) (for example, Vs=ELVDD) can be supplied to a source of the driving transistor Tdr.

A level of a current flowing through the driving transistor Tdr to the first light emitting device ED1 or the second light emitting device ED2 can be proportional to the square of a voltage obtained by subtracting the threshold voltage (Vth) of the driving transistor Tdr from a difference voltage (hereinafter simply referred to as a gate-source voltage (Vgs)) between the gate voltage Vg and the source voltage Vs of the driving transistor Tdr.

In the above example, a value (Vgs-Vth) obtained by subtracting the threshold voltage (Vth) of the driving transistor Tdr from the gate-source voltage (Vgs) does not include the threshold voltage (Vth) of the driving transistor Tdr, and can include the data voltage Vdata and the reference voltage VREF (for example, Vgs−Vth=[Vref−Vdata+ELVDD+Vth]−[ELVDD]−[Vth]=VREF−Vdata). Here, the reference voltage VREF is a constant voltage regardless of the threshold voltage (Vth) of the driving transistor Tdr.

Therefore, the threshold voltage (Vth) of the driving transistor Tdr does not affect the level of the current flowing through the driving transistor Tdr, and the data voltage Vdata and reference voltage VREF can affect the level of the current flowing through the driving transistor Tdr.

Accordingly, even when the driving transistor Tdr deteriorates and thus the threshold voltage (Vth) of the driving transistor Tdr changes, the first light emitting device ED1 or the second light emitting device ED2 can output light with a luminance corresponding to the data voltage Vdata.

In this case, because only the second viewing angle control transistor Tvc2 connected to the second light emitting device ED2 is turned on by the second control signal CS2 having the low level in the privacy mode (PM), only lights having the second viewing angle (narrow viewing angle) can be output from the subpixels P of the kth pixel row line provided in the 8th light emitting area EA8.

That is, lights having the second viewing angle can be output from the subpixels P provided in the 8th light emitting area EA8, and thus, as illustrated in FIG. 7A, the general image IM2 having the second viewing angle (narrow viewing angle) can be displayed in the 8th light emitting area EA8.

The general image IM2 having the second viewing angle (narrow viewing angle) can be visible only to a user at a specific location, for example, a passenger. Accordingly, this mode can be the privacy mode (PM), as described above.

The processes described above can be repeated in all pixel row lines provided in the 8th light emitting area EA8 while the first control signal CS1 having the high level and the second control signal CS2 having the low level are supplied to the 8th light emitting area EA8.

Next, if the emergency information image IM4 with the first viewing angle (wide viewing angle) is received in the privacy mode (PM) in which the general image IM2 with the second viewing angle (narrow viewing angle) is displayed, the control driver 400 can supply the first control signal having the low level and the second control signal having the high level, as illustrated in FIG. 13, to the subpixels P provided in the 8th light emitting area EA8.

In this case, as illustrated in FIG. 2, the first viewing angle control transistor Tvc1 and the second viewing angle control transistor Tvc2 which are provided in the subpixels P can be P-type transistors.

Accordingly, the first viewing angle control transistors Tvc1 provided in the subpixels P of the 8th light emitting area EA8 can be turned on by the first control signal CS1 having the low level, and the second viewing angle control transistors Tvc2 can be turned off by the second control signal CS2 having the high level.

Next, the initialization period A and the sampling period B can be performed for the kth pixel row line provided in the 8th light emitting area EA8.

That is, for the kth pixel row line, the same initialization period A and sampling period B as the initialization period A and sampling period B described in the privacy mode (PM) can proceed.

Accordingly, the driving transistor Tdr provided in the kth pixel row line can be initialized, and the data voltage Vdata can be supplied to the subpixel P.

Finally, after the sampling period B, the emission period C begins.

In the emission period C, as illustrated in FIG. 13, when the reference control signal RCS having the high level, the gate signal GS having the high level, and the emission signal EM having the low level are supplied to the kth pixel row line provided in the 8th light emitting area EA8, the switching transistor Tsw1, the first reference transistor Tsw2a, the second reference transistor Tsw2b, and the connection transistor Tsw3 which are provided in the subpixel P connected to the kth pixel row line can be turned off, and the first emission transistor Tsw4a and the second emission transistor Tsw4b can be turned on.

Accordingly, current flows through the driving transistor Tdr toward the first viewing angle control transistor Tvc1 and the second viewing angle control transistor Tvc2.

In this case, in the share mode (SM), because only the first viewing angle control transistor Tvc1 connected to the first light emitting device ED1 is turned on by the first control signal CS1 having the low level, only lights having the first viewing angle (wide viewing angle) can be output from the subpixels P connected to the kth pixel row line provided in the 8th light emitting area EA8.

That is, lights having the first viewing angle can be output from the subpixels P provided in the 8th light emitting area EA8, and thus, the emergency information image IM4 having the first viewing angle (wide viewing angle) can be displayed in the 8th light emitting area EA8, as illustrated in FIG. 7E.

The emergency information image IM4 having the first viewing angle (wide viewing angle) can be seen by users at any location, for example, a driver and a passenger. Accordingly, this mode can be the share mode (SM), as described above.

That is, the mode of the 8th light emitting area EA8 can be changed from the privacy mode (PM) to the share mode (SM) through the method described above.

The mode of each of the remaining light emitting areas can also be changed from the privacy mode (PM) to the share mode (SM), or changed from the share mode (SM) to the privacy mode (PM) through the same method as described above.

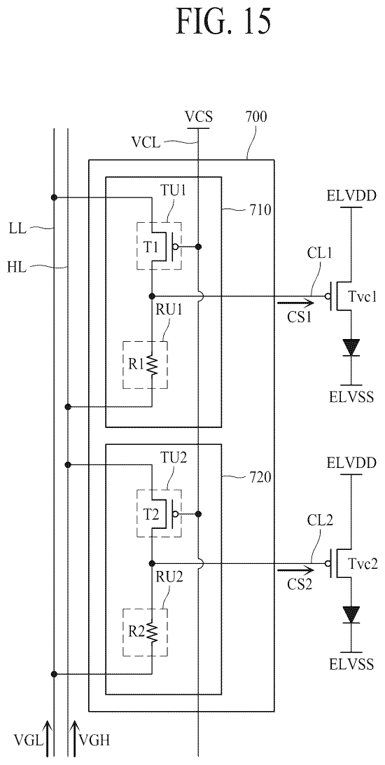

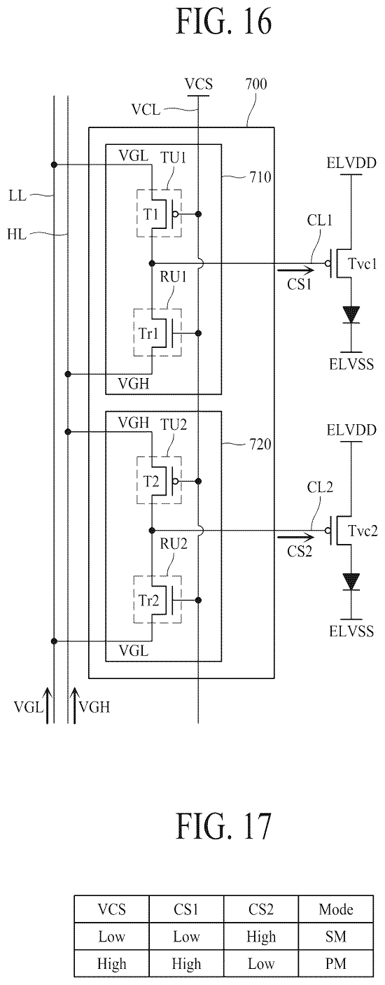

FIG. 14 is an exemplary diagram illustrating a connection structure of viewing angle switching units and viewing angle control lines in a light emitting display apparatus according to an embodiment of the present disclosure, FIG. 15 is an exemplary diagram illustrating a structure of a viewing angle switching unit illustrated in FIG. 14, FIG. 16 is another exemplary diagram illustrating a structure of a viewing angle switching unit illustrated in FIG. 14, and FIG. 17 is an exemplary diagram illustrating a viewing angle control signal, a first control signal, and a second control signal applied to a light emitting display apparatus illustrated in FIG. 14. In particular, FIG. 14 specifically illustrates a structure of the light emitting display panel 100 illustrated in FIG. 1, and FIGS. 15 and 16 specifically illustrate a detailed structure of the viewing angle switching unit illustrated in FIG. 14.

Moreover, in FIG. 14, different reference numerals are assigned to the 12 viewing angle switching units 700 to distinguish the 12 viewing angle switching units 700. For example, a first viewing angle switching unit corresponding to the first light emitting area EA1 is indicated by a reference numerals 700a, and a 12th viewing angle switching unit corresponding to the 12th light emitting area EA12 is indicated by a reference numerals 700l.

In the following description, details which are the same as or similar to details described with reference to FIGS. 1 to 13 are omitted or will be briefly described. Hereinafter, a method in which only the first light emitting units LU1 or only the second light emitting units LU2 are driven in each of the light emitting areas will be described with reference to FIGS. 1 to 17.

As described above, the first viewing angle control transistor Tvc1 can be connected between the driving transistor Tdr which controls the level of the current supplied to the first light emitting unit LU1 (or the second light emitting unit LU2) and the first light emitting unit LU1, and the second viewing angle control transistor Tvc2 can be connected between the driving transistor Tdr and the second light emitting unit LU2.

In this case, as illustrated in FIG. 2, the second emission transistor Tsw4b for controlling the light emitting timing of the first light emitting device ED1 (or the second light emitting device ED2) can be further provided between the driving transistor Tdr and the first viewing angle control transistor Tvc1 (or the second viewing angle control transistor Tvc2).

The first light emitting unit LU1 can include the first light emitting device ED1 driven by the first viewing angle control transistor Tdr and the first lens LZ1 disposed on the first light emitting device ED1. Also, the second light emitting unit LU2 can include the second light emitting device ED2 driven by the second viewing angle control transistor Tvc2 and the second lens LZ2 disposed on the second light emitting device ED2.

The display area DA of the light emitting display panel 100 can be divided into at least two light emitting areas along the first direction X, and the display area DA can be divided into at least two light emitting areas along the second direction Y different from the first direction X. For example, a light emitting display panel 100 which is divided into four light emitting areas along the first direction X and divided into three light emitting areas along the second direction Y is illustrated in FIGS. 1 and 14. That is, a light emitting display panel 100 divided into 12 light emitting areas EA1 to EA12 is illustrated in FIGS. 1 and 14.

In this case, an s−1th viewing angle switching unit connected to first viewing angle control transistors Tvc1 and second viewing angle control transistors Tvc2 provided in an s-1th light emitting area among the light emitting areas can be connected to an s−1th viewing angle control line to which an s−1th viewing angle control signal is supplied, and an sth viewing angle switching unit connected to first viewing angle control transistors Tvc1 and second viewing angle control transistors Tvc2 provided in an sth light emitting area among the light emitting areas can be connected to an sth viewing angle control line to which an sth viewing angle control signal is supplied.

That is, the s−1th viewing angle switching unit among the viewing angle switching units 700 can be connected to the first viewing angle control transistors Tvc1 and the second viewing angle control transistors Tvc2 provided in the s−1th light emitting area among the light emitting areas, and the sth viewing angle switching unit among the viewing angle switching units 700 can be connected to the first viewing angle control transistors Tvc1 and the second viewing angle control transistors Tvc2 provided in the sth light emitting area among the light emitting areas.

Here, s is a natural number smaller than or equal to the number of the light emitting areas provided in the light emitting display panel 100. For example, in the light emitting display panel 100 illustrated in FIG. 14, m is 12, and the s can be any natural number from 1 to 12.

Moreover, the first viewing angle switching unit 700a to the 12th viewing angle switching unit 700l is connected to a first viewing angle control line VCL1 to a 12th viewing angle control line VCL12, and the first viewing angle control line VCL1 to the 12th viewing angle control line VCL12 can be connected to the control driver 400 which generates the first viewing angle control signal VCS1 to the 12th viewing angle control signal VCS12. That is, each of the viewing angle switching units 700 can be connected to the control driver 400 which controls the viewing angle switching units 700.

For example, gates of the first viewing angle control transistors Tvc1 and gates of the second viewing angle control transistors Tvc2 provided in a first light emitting area EA1 among the light emitting areas illustrated in FIG. 14 can be connected to a first viewing angle switching unit 700a to which the first viewing angle control signal VCS1 is supplied. Also, gates of the first viewing angle control transistors Tvc1 and gates of the second viewing angle control transistors Tvc2 provided in a second light emitting area EA2 among the light emitting areas can be connected to a second viewing angle switching unit 700b to which a second viewing angle control signal VCS2 is supplied. Moreover, gates of the first viewing angle control transistors Tvc1 and gates of the second viewing angle control transistors Tvc2 provided in a 12th light emitting area EA12 among the light emitting areas can be connected to a 12th viewing angle switching unit 700l to which a 12th viewing angle control signal VCS12 is supplied. Further, the first viewing angle control line VCL1 to the 12th viewing angle control line VCL12 can be connected to the control driver 400 which generates the first viewing angle control signal VCS1 to the 12th viewing angle control signal VCS12.

Particularly, the first viewing angle control line VCL1 to the 12th viewing angle control line VCL12 can be connected to a first viewing angle control signal generator 701 to a 12th viewing angle control signal generator 712 provided in the control signal generator 420 of the control driver 400, as illustrated in FIG. 14. That is, the first viewing angle control signal generator 701 to the 12th viewing angle control signal generator 712 can generate the first viewing angle control signal VCS1 to the 12th viewing angle control signal VCS12.

Accordingly, each of the light emitting areas EA1 to EDA12 can be driven independently. For example, the subpixels P provided in the first light emitting area EA1 can be driven by the first viewing angle control signal VCS1, the subpixels P provided in the second light emitting area EA2 can be driven by the second viewing angle control signal VCS2, and the subpixels P provided in the 12th light emitting area EA12 can be driven by the 12th viewing angle control signal VSC12.

The first viewing angle switching unit 700a to the 12th viewing angle switching unit 700l can be provided in the non-display area NDA, as illustrated in FIG. 14.

For example, when the first light emitting area EA1 to the third light emitting area EA3 are provided on the left side of the display area DA, as illustrated in FIG. 14, the first viewing angle switching unit 700a to a third viewing angle switching unit 700c can be provided in the non-display area NDA provided on the left side of the display area DA.

Moreover, as illustrated in FIG. 14, when a 10th to 12th light emitting areas EA10 to EA12 are provided on the right side of the display area DA, the 10th to 12th viewing angle switching units 700j to 700l can be provided in the non-display area NDA provided on the right side of the display area DA.

Further, when a 4th light emitting area EA4 to a 9th light emitting area EA9 are provided in the center area with respect to the left and right sides of the display area DA, as illustrated in FIGS. 14, a 4th to 9th viewing angle switching units 700d to 700i can be provided in the non-display area NDA provided in an upper or lower side of the display area DA. Particularly, in the light emitting display apparatus illustrated in FIG. 14, the control signal generator 420 included in the control driver 400 is provided in the lower side of the light emitting display panel. Therefore, in order to minimize the lengths of the viewing angle control lines VCL, the 4th to 9th viewing angle switching units 700d to 700i can be provided in the lower side of the display area DA.

In this case, the first viewing angle switching unit 700a to the 12th viewing angle switching unit 700l is connected to the first viewing angle control line VCL1 to the 12th viewing angle control line VCL12, and the first viewing angle control line VCL1 to the 12th viewing angle control line VCL12 can be connected to the control driver 400 which generates the first viewing angle control signal VCS1 to the 12th viewing angle control signal VCS12. That is, one viewing angle control line VCL is connected to each of the viewing angle switching units 700.

Also, a high voltage line HL and a low voltage line LL can be connected to the first viewing angle switching unit 700a to the 12th viewing angle switching unit 700l, respectively. A high voltage VGH can be supplied to the high voltage line HL through the power supply unit 500, and a low voltage VGL lower than the high voltage VGH can be supplied to the low voltage line LL through the power supply unit 500.

The high voltage VGH may be a voltage capable of turning off (or turning on) the first viewing angle control transistor Tvc1 and the second viewing angle control transistor Tvc2, and the low voltage VGL may be a voltage capable of turning on (or turning off) the first viewing angle control transistor Tvc1 and the second viewing angle control transistor Tvc2.

For example, as illustrated in FIG. 2, when the first viewing angle control transistor Tvc1 and the second viewing angle control transistor Tvc2 are formed of P-type transistors, the first viewing angle control transistor Tvc1 and the second viewing angle control transistor Tvc2 can be turned off by the high voltage VGH and can be turned on by the low voltage VGL.

That is, a voltage for turning on the first viewing angle control transistor Tvc1 and the second viewing angle control transistor Tvc2 and a voltage for turning off the first viewing angle control transistor Tvc1 and the second viewing angle control transistor Tvc2 can be changed based on polarity types of the first viewing angle control transistor Tvc1 and the second viewing angle control transistor Tvc2.

Hereinafter, as illustrated in FIG. 2, a light emitting display apparatus including the first viewing angle control transistor Tvc1 and the second viewing angle control transistor Tvc2 formed of P-type transistors will be described as an example of a light emitting display apparatus according to an embodiment of the present disclosure. Therefore, the high voltage VGH can be a voltage capable of turning off the first viewing angle control transistor Tvc1 and the second viewing angle control transistor Tvc2, and the low voltage VGL can be a voltage capable of turning on the first viewing angle control transistor Tvc1 and the second viewing angle control transistor Tvc2.

In this case, each of the viewing angle switching units 700 can include a first switching unit 710 and a second switching unit 720.

For example, among the viewing angle switching units 700, the sth viewing angle switching unit (s is a natural number less than or equal to the number of light emitting areas) can include a first switching unit 710 which is connected to gates of the first viewing angle control transistors Tvc1 in the sth light emitting area among the light emitting areas EA and a second switching unit 720 which is connected to gates of the second viewing angle control transistors Tvc2 in the sth light emitting area.

To provide an additional description, the first viewing angle switching unit 700a can include a first switching unit 710 connected to gates of the first viewing angle control transistors Tvc1 provided in the first light emitting area EA1 among the light emitting areas EA and a second switching unit 720 connected to gates of the second viewing angle control transistors Tvc2 provided in the first light emitting area EA1.

Moreover, the second viewing angle switching unit 700b can include a first switching unit 710 connected to gates of the first viewing angle control transistors Tvc1 provided in the second light emitting area EA2 among the light emitting areas EA and a second switching unit 720 connected to gates of the second viewing angle control transistors Tvc2 provided in the second light emitting area EA2.

Therefore, the 12th viewing angle switching unit 700l can include a first switching unit 710 connected to gates of the first viewing angle control transistors Tvc1 provided in the 12th light emitting area EA12 among the light emitting areas EA and a second switching unit 720 connected to gates of the second viewing angle control transistors Tvc2 provided in the 12th light emitting area EA12.

The first switching unit 710 can include a first transistor unit TU1 connected between a first control signal line CL1 connected to gates of the first viewing angle control transistors Tvc1 provided in the sth light emitting area and a low voltage line LL to which a low voltage is supplied, and a first resistance unit RU1 connected between the first control signal line CL1 and a high voltage line HL to which a high voltage VGH higher than the low voltage VGL is supplied.

The second switching unit 720 can include a second transistor unit TU2 connected between a second control signal line CL2 connected to gates of the second viewing angle control transistors Tvc2 provided in the sth light emitting area and the high voltage line HL, and a second resistance unit RU2 connected between the second control signal line CL2 and the low voltage line LL.

For example, the first switching units 710 provided in the first viewing angle switching unit 700a to the 12th viewing angle switching unit 700l can have the same structure, and the second switching units 720 provided in the first viewing angle switching unit 700a to the 12th viewing angle switching unit 700l can have the same structure.

In this case, the structure of the first switching unit 710 and the structure of the second switching unit 720 can be formed differently from each other.

For example, as illustrated in FIG. 15, the first transistor unit TU1 of the first switching unit 710 can include a first control transistor T1. In this case, a gate of the first control transistor T1 can be connected to the viewing angle control line VCL to which the viewing angle control signal VCS is supplied, a first terminal of the first control transistor T1 can be connected to the low voltage line LL, and a second terminal of the first control transistor T1 can be connected to the first resistance unit RU1.

The second transistor unit TU2 of the second switching unit 720 can include a second control transistor T2. In this case, a gate of the second control transistor T2 can be connected to the viewing angle control line VCL, a first terminal of the second control transistor T2 can be connected to the high voltage line HL, and a second terminal of the second control transistor T2 can be connected to the second resistance unit RU2.

In this case, each of the first resistance unit RU1 and the second resistance unit RU2 provided in the viewing angle switching unit 700 can be formed of resistors. For example, as illustrated in FIG. 15, the first resistance unit RU1 can include a first resistor R1 provided between the high voltage line HL and the first control signal line CL1, and the second resistance unit RU2 can include a second resistor R2 provided between the low voltage line LL and the second control signal line CL2.

The first resistor R1 and the second resistor R2 can be replaced with a first resistance transistor Tr1 and a second resistance transistor Tr2, as illustrated in FIG. 16. That is, each of the first resistance transistor Tr1 and the second resistance transistor Tr2 can function as a resistor.

Hereinafter, a method of operating the viewing angle switching unit 700 and a method of driving a light emitting area EA corresponding to the viewing angle switching unit 700 will be described with reference to FIGS. 14 to 17. Particularly, hereinafter, as illustrated in FIG. 15, the viewing angle switching unit 700 including the first control transistor T1 and the second control transistor T2 formed in a P-type will be described as an example of the present disclosure.

First, as illustrated in FIG. 17, when the viewing angle control signal VCS having a low level is supplied through the viewing angle control line VCL, the first control transistor T1 and the second control transistor T2 illustrated in FIG. 15 are turned on.

Therefore, the low voltage VGL supplied through the first terminal of the first control transistor T1 is supplied to the first control signal line CL1 through the first control transistor T1. That is, the first control signal CS1 having the low level is supplied to the first control signal line CL1.

Also, the high voltage VGH supplied through the first terminal of the second control transistor T2 is supplied to the second control signal line CL2 through the second control transistor T2. That is, the second control signal CS2 having the high level is supplied to the second control signal line CL2.

In this case, when the viewing angle switching unit 700 illustrated in FIG. 15 is the first viewing angle switching unit 700a, the first control signal line CL1 connected to the first viewing angle switching unit 700a is connected to gates of the first viewing angle control transistors Tvc1 provided in the first light emitting area EA1, and the second control signal line CL2 connected to the first viewing angle switching unit 700a is connected to gates of the second viewing angle control transistors Tvc2 provided in the first light emitting area EA1.

Therefore, the first control signal CS1 having the low level is supplied to gates of the first viewing angle control transistors Tvc1 provided in the first light emitting area EA1, and the second control signal CS2 having the high level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the low level is supplied to the first viewing angle control transistors Tvc1, the first viewing angle control transistors Tvc1 are turned on. Also, when the second control signal CS2 having the high level is supplied to the second viewing angle control transistors Tvc2, the second viewing angle control transistors Tvc2 are turned off.

Accordingly, in the first light emitting area EA1, an image having the wide viewing angle in the left-right direction can be output through the first light emitting units LU1 connected to the first viewing angle control transistors Tvc1. That is, in the first light emitting area EA1, only the first light emitting units LU1 can be driven to output an image having the wide viewing angle.

Therefore, a mode of the first light emitting area EA1 can be the share mode (SM).

In this case, as illustrated in FIG. 16, when the first resistance unit RU1 is formed of the first resistance transistor Tr1 and the second resistance unit RU2 is formed of the second resistance transistor Tr2, a gate of the first resistance transistor Tr1 and a gate of the second resistance transistor Tr2 can be connected to the viewing angle control line VCL. The first resistance transistor Tr1 and the second resistance transistor Tr2 can be formed of N-type transistors.

Therefore, the first resistance transistor Tr1 and the second resistance transistor Tr2 are turned off by the viewing angle control signal VCS having the low level.

Accordingly, as described above, a first control signal CS1 having the low level can be supplied to the first control signal line CL1 through the first control transistor T1, and a second control signal CS2 having the high level can be supplied to the second control signal line CL2 through the second control transistor T2.

Therefore, in the first light emitting area EA1, an image having the wide viewing angle in the left-right direction can be output through the first light emitting units LU1 connected to the first viewing angle control transistors Tvc1.

That is, a mode of the first light emitting area EA1 can be the share mode (SM).

Second, as illustrated in FIG. 17, when the viewing angle control signal VCS having the high level is supplied through the viewing angle control line VCL, the first control transistor T1 and the second control transistor T2 illustrated in FIG. 15 are turned off.

Accordingly, the high voltage VGH supplied through the first resistance unit RU1 is supplied to the first control signal line CL1 through the first resistance unit RU1. That is, the first control signal CS1 having the high level is supplied to the first control signal line CL1.

Also, the low voltage VGL supplied through the second resistance unit RU2 is supplied to the second control signal line CL2 through the second resistance unit RU2. That is, the second control signal CS2 having the low level is supplied to the second control signal line CL2.

In this case, when the viewing angle switching unit 700 illustrated in FIG. 15 is the first viewing angle switching unit 700a, the first control signal line CL1 connected to the first viewing angle switching unit 700a is connected to gates of the first viewing angle control transistors Tvc1 provided in the first light emitting area EA1, and the second control signal line CL2 connected to the first viewing angle switching unit 700a is connected to gates of the second viewing angle control transistors Tvc2 provided in the first light emitting area EA1.

Therefore, the first control signal CS1 having the high level is supplied to gates of the first viewing angle control transistors Tvc1 provided in the first light emitting area EA1, and the second control signal CS2 having the low level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the high level is supplied to the first viewing angle control transistors Tvc1, the first viewing angle control transistors Tvc1 are turned off. Also, when the second control signal CS2 having the low level is supplied to the second viewing angle control transistors Tvc2, the second viewing angle control transistors Tvc2 are turned on.

Accordingly, in the first light emitting area EA1, an image having the narrow viewing angle in the left-right direction can be output through the second light emitting units LU2 connected to the second viewing angle control transistors Tvc2. That is, in the first light emitting area EA1, only the second light emitting units LU2 can be driven to output an image having the narrow viewing angle.

Therefore, a mode of the first light emitting area EA1 can be the privacy mode (PM).

In this case, as illustrated in FIG. 16, when the first resistance unit RU1 is formed of the first resistance transistor Tr1 and the second resistance unit RU2 is formed of the second resistance transistor Tr2, a gate of the first resistance transistor Tr1 and a gate of the second resistance transistor Tr2 are connected to the viewing angle control line VCL. The first resistance transistor Tr1 and the second resistance transistor Tr2 can be formed of N-type transistors.

Therefore, the first resistance transistor Tr1 and the second resistance transistor Tr2 are turned on by the viewing angle control signal VCS having the high level.

Accordingly, as described above, a first control signal CS1 having the high level can be supplied to the first control signal line CL1 through the first resistance transistor Tr1, and a second control signal CS2 having the low level can be supplied to the second control signal line CL2 through the second resistance transistor Tr2.

Therefore, in the first light emitting area EA1, an image having the narrow viewing angle in the right-left direction can be output through the second light emitting units LU2 connected to the second viewing angle control transistors Tvc2.

That is, a mode of the first light emitting area EA1 can be the privacy mode (PM).

The operation method described above can also be independently performed in the second viewing angle switching unit 700b to the 12th viewing angle switching unit 700l. Accordingly, an image having the wide viewing angle or an image having the narrow viewing angle can be output in each of the second to 12th light emitting areas EA2 to EA12.

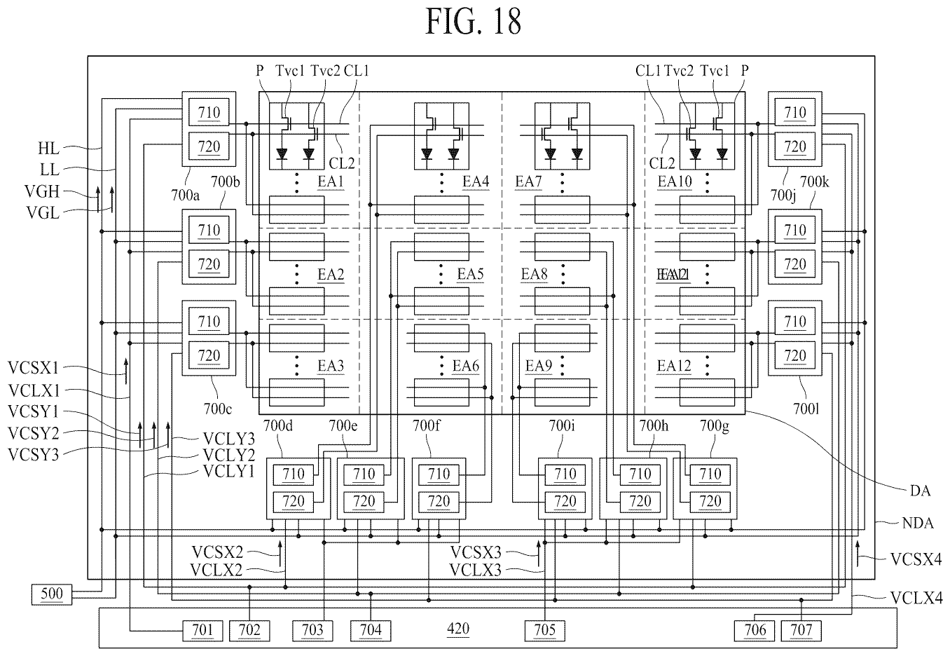

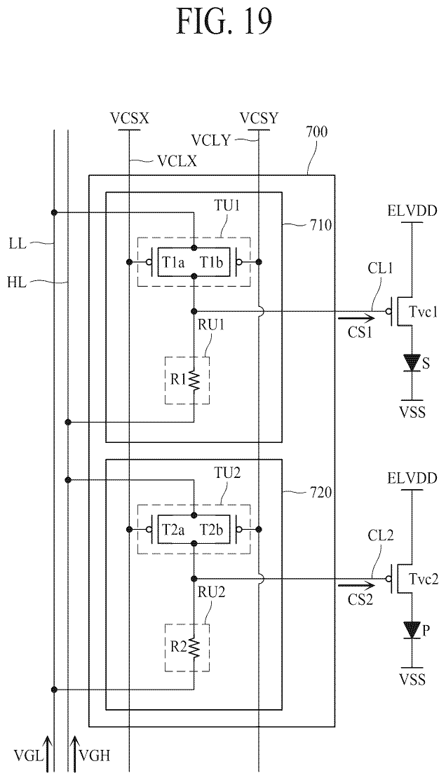

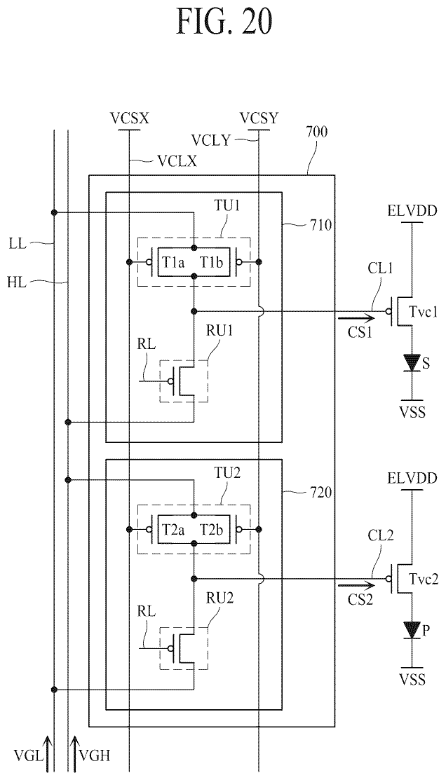

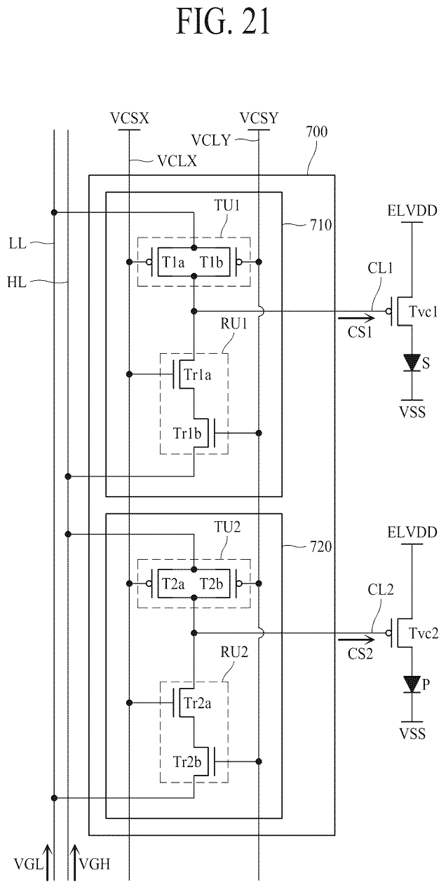

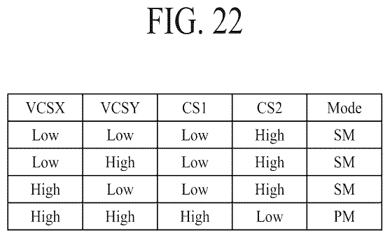

FIG. 18 is another exemplary diagram illustrating a connection structure of viewing angle switching units and viewing angle control lines in a light emitting display apparatus according to an embodiment of the present disclosure, FIG. 19 is an exemplary diagram illustrating a structure of a viewing angle switching unit illustrated in FIG. 18, FIG. 20 is another exemplary diagram illustrating a structure of a viewing angle switching unit illustrated in FIG. 18, FIG. 21 is another exemplary diagram illustrating a structure of a viewing angle switching unit illustrated in FIG. 18, and FIG. 22 is an exemplary diagram illustrating a viewing angle control signal, a first control signal, and a second control signal applied to a light emitting display apparatus illustrated in FIG. 18. Particularly, FIG. 18 specifically illustrates a structure of the light emitting display panel 100 illustrated in FIG. 1, and FIGS. 19 to 21 specifically illustrates a detailed structure of the viewing angle switching unit illustrated in FIG. 18.

Moreover, in FIG. 18, different reference numerals are assigned to the 12 viewing angle switching units 700 to distinguish the 12 viewing angle switching units 700. For example, a first viewing angle switching unit corresponding to the first light emitting area EA1 is indicated by a reference numerals 700a, and a 12th viewing angle switching unit corresponding to the 12th light emitting area EA12 is indicated by a reference numerals 700l.

In the following description, details which are the same as or similar to details described with reference to FIGS. 1 to 17 are omitted or will be briefly described. Hereinafter, a method in which only the first light emitting units LU1 or only the second light emitting units LU2 are driven in each of the light emitting areas will be described with reference to FIGS. 1 to 22. As described above, the first viewing angle control transistor Tvc1 can be connected between the driving transistor Tdr which controls the level of the current supplied to the first light emitting unit LU1 (or the second light emitting unit LU2) and the first light emitting unit LU1, and the second viewing angle control transistor Tvc2 can be connected between the driving transistor Tdr and the second light emitting unit LU2.

In this case, as illustrated in FIG. 2, the second emission transistor Tsw4b for controlling the light emitting timing of the first light emitting device ED1 (or the second light emitting device ED2) can be further provided between the driving transistor Tdr and the first viewing angle control transistor Tvc1 (or the second viewing angle control transistor Tvc2).

The first light emitting unit LU1 can include the first light emitting device ED1 driven by the first viewing angle control transistor Tdr and the first lens LZ1 disposed on the first light emitting device ED1. Also, the second light emitting unit LU2 can include the second light emitting device ED2 driven by the second viewing angle control transistor Tvc2 and the second lens LZ2 disposed on the second light emitting device ED2.

The display area DA of the light emitting display panel 100 can be divided into at least two light emitting areas along the first direction X, and the display area DA can be divided into at least two light emitting areas along the second direction Y different from the first direction X. For example, a light emitting display panel 100 which is divided into four light emitting areas along the first direction X and divided into three light emitting areas along the second direction Y is illustrated in FIGS. 1 and 18. That is, a light emitting display panel 100 divided into 12 light emitting areas EA1 to EA12 is illustrated in FIGS. 1 and 18.

In this case, an s−1th viewing angle switching unit connected to first viewing angle control transistors Tvc1 and second viewing angle control transistors Tvc2 provided in an s−1th light emitting area among the light emitting areas can be connected to an s−1th viewing angle control line to which an s−1th viewing angle control signal is supplied, and an sth viewing angle switching unit connected to first viewing angle control transistors Tvc1 and second viewing angle control transistors Tvc2 provided in an sth light emitting area among the light emitting areas can be connected to an sth viewing angle control line to which an sth viewing angle control signal is supplied.

That is, the s−1th viewing angle switching unit among the viewing angle switching units 700 can be connected to the first viewing angle control transistors Tvc1 and the second viewing angle control transistors Tvc2 provided in the s−1th light emitting area among the light emitting areas, and the sth viewing angle switching unit among the viewing angle switching units 700 can be connected to the first viewing angle control transistors Tvc1 and the second viewing angle control transistors Tvc2 provided in the sth light emitting area among the light emitting areas.

Here, s is a natural number smaller than or equal to the number of the light emitting areas provided in the light emitting display panel 100. For example, in the light emitting display panel 100 illustrated in FIG. 18, m is 12, and the s can be any natural number from 1 to 12.

Moreover, each of the first to 12th viewing angle switching units 700a to 700l is connected to two viewing angle control lines VCLX and VCLY, and the viewing angle control lines VCLX1, VCLX2, VCLX3, VCLX4, VCLY1, VCLY2, and VCLY3 can be connected to the control driver 400 which generates viewing angle control signals VCSX1, VCSX2, VCSX3, VCSX4, VCSY1, VCSY2, and VCSY3. That is, each of the viewing angle switching units 700 can be connected to the control driver 400 which controls the viewing angle switching units 700.

For example, gates of the first viewing angle control transistors Tvc1 and gates of the second viewing angle control transistors Tvc2 provided in the first light emitting area EA1 among the light emitting areas illustrated in FIG. 18 can be connected to a first viewing angle switching unit 700a to which first viewing angle control signals VCSX1 and VCSY1 are supplied. Also, gates of the first viewing angle control transistors Tvc1 and the second viewing angle control transistors Tvc2 provided in the second light emitting area EA2 among the light emitting areas illustrated in FIG. 18 can be connected to a second viewing angle switching unit 700b to which second viewing angle control signals VCSX1 and VCSY2 are supplied. Further, gates of the first viewing angle control transistors Tvc1 and gates of the second viewing angle control transistors Tvc2 provided in the 12th light emitting area EA12 can be connected to a 12th viewing angle switching unit 700l to which 12th viewing angle control signals VCSX4 and VCSY3 are supplied.

Moreover, the viewing angle control lines VCLX1, VCLX2, VCLX3, VCLX4, VCLY1, VCLY2, and VCLY3 can be connected to the control driver 400 which generates the viewing angle control signals VCSX1, VCSX2, VCSX3, VCSX4, VCSY1, VCSY2, and VCSY3.

Particularly, the viewing angle control lines VCLX1, VCLX2, VCLX3, VCLX4, VCLY1, VCLY2, and VCLY3 can be connected to the viewing angle control signal generator 701 to 707 provided in the control signal generator 420 of the control driver 400, as illustrated in FIG. 18. That is, the first viewing angle control signal generator 701 to the 7th viewing angle control signal generator 707 can generate the viewing angle control signals VCSX1, VCSY1, VCSX2, VCSY2, VCSX3, VCSX4, and VCSY3.

In this case, a viewing angle control signal generated by each of the viewing angle control signal generator 701 to 707 is not transmitted to one viewing angle switching unit 700, but can be transmitted to at least one viewing angle switching unit based on the number of light emitting areas provided along the X-axis and Y-axis.

For example, when 12 light emitting areas EA1 to EA12 are provided in the light emitting display panel 100, as illustrated in FIG. 18, the coordinates (X,Y) of the 12 light emitting areas EA1 to EA12 can be (1,1), (1,2), (1,3), (2,1), (2,2), (2,3), (3,1), (3,2), (3,3), (4,1), (4,2), and (4,3).

In this case, four X coordinates and three Y coordinates can be generated.

To this end, four X-coordinate viewing angle control signals VCSX1, VCSX2, VCSX3, and VCSX4 and three Y-coordinate viewing angle control signals VCSY1, VCSY2, and VCSY3 can be generated.

For example, a first X-coordinate viewing angle control signal VCSX1 generated by the first viewing angle control signal generator 701 can be transmitted to the first viewing angle switching unit 700a, the second viewing angle switching unit 700b, and the third viewing angle switching unit 700c through a first X-coordinate viewing angle control line VCLX1. The first viewing angle switching unit 700a, the second viewing angle switching unit 700b, and the third viewing angle switching unit 700c can be connected to the first light emitting area EA1, the second light emitting area EA2, and the third light emitting area EA3. Also, each of the first light emitting area EA1, the second light emitting area EA2, and the third light emitting area EA3 has an X-coordinate of 1.

Further, a first Y-coordinate viewing angle control signal VCSY1 generated by the second viewing angle control signal generator 702 can be transmitted to the first viewing angle switching unit 700a, the 4th viewing angle switching unit 700d, the 7th viewing angle switching unit 700g, and the 10th viewing angle switching unit 700j through a first Y-coordinate viewing angle control line VCLY1. The first viewing angle switching unit 700a, the 4th viewing angle switching unit 700d, the 7th viewing angle switching unit 700g, and the 10th viewing angle switching unit 700j can be connected to the first light emitting area EA1, the 4th light emitting area EA4, the 7th light emitting area EA7, and the 10th light emitting area EA10. Also, each of the first light emitting area EA1, the 4th light emitting area EA4, the 7th light emitting area EA7, and the 10th light emitting area EA10 has a Y-coordinate of 1.

Further, a third X-coordinate viewing angle control signal VCSX3 generated by the 5th viewing angle control signal generator 705 can be transmitted to the 7th viewing angle switching unit 700g, the 8th viewing angle switching unit 700h, and the 9th viewing angle switching unit 700i through a third X-coordinate viewing angle control line VCLX3. The 7th viewing angle switching unit 700g, the 8th viewing angle switching unit 700h, and the 9th viewing angle switching unit 700i can be connected to the 7th light emitting area EA7, the 8th light emitting area EA8, and the 9th light emitting area EA9. Also, each of the 7th light emitting area EA7, the 8th light emitting area EA8, and the 9th light emitting area EA9 has an X-coordinate of 3.

Further, a third Y-coordinate viewing angle control signal VCSY3 generated by the 7th viewing angle control signal generator 707 can be transmitted to the third viewing angle switching unit 700c, the 6th viewing angle switching unit 700f, the 9th viewing angle switching unit 700i, and the 12th viewing angle switching unit 700l through a third Y-coordinate viewing angle control line VCLY3. The third viewing angle switching unit 700c, the 6th viewing angle switching unit 700f, the 9th viewing angle switching unit 700i, and the 12th viewing angle switching unit 700l can be connected to the third light emitting area EA3, the 6th light emitting area EA6, the 9th light emitting area EA9, and the 12th light emitting area EA12. Also, each of the third light emitting area EA3, the 6th light emitting area EA6, the 9th light emitting area EA9, and the 12th light emitting area EA12 has a Y-coordinate of 3.

That is, each of the viewing angle switching units can be connected to one X-coordinate viewing angle control line VCLX and one Y-coordinate viewing angle control line VCLY, and can be driven by one X-coordinate viewing angle control signal VCSX and one Y-coordinate viewing angle control signal VCSY.

Therefore, each of the light emitting areas EA1 to EA12 can be independently driven. For example, subpixels P provided in the first light emitting area EA1 can be driven by the first X-coordinate viewing angle control signal VCSX1 and the first Y-coordinate viewing angle control signal VCSY1, subpixels P provided in the second light emitting area EA2 can be driven by the first X-coordinate viewing angle control signal VCSX1 and the second Y-coordinate viewing angle control signal VCSY2, and subpixels P provided in the 12th light emitting area EA12 can be driven by a fourth X-coordinate viewing angle control signal VCSX4 and the third Y-coordinate viewing angle control signal VCSY3.

The first viewing angle switching unit 700a to the 12th viewing angle switching unit 700l can be provided in the non-display area NDA, as illustrated in FIG. 18.

For example, when the first light emitting area EA1 to the third light emitting area EA3 are provided on the left side of the display area DA, as illustrated in FIG. 18, the first viewing angle switching unit 700a to the third viewing angle switching unit 700c can be provided in the non-display area NDA provided on the left side of the display area DA.

Moreover, as illustrated in FIG. 18, when the 10th to 12th light emitting areas EA10 to EA12 are provided on the right side of the display area DA, the 10th to 12th viewing angle switching units 700j to 700l can be provided in the non-display area NDA provided on the right side of the display area DA.

Moreover, when the 4th to 9th light emitting areas EA4 to EA9 are provided in the center area with respect to the left and right sides of the display area DA, as illustrated in FIG. 18, the 4th to 9th viewing angle switching units 700d to 700i can be provided in the non-display area NDA provided in an upper or lower side of the display area DA. Particularly, in the light emitting display apparatus illustrated in FIG. 18, the control signal generator 420 included in the control driver 400 is provided in the lower side of the light emitting display panel. Therefore, in order to minimize the lengths of the viewing angle control lines VCLX and VCLY, in the light emitting display panel 100 illustrated in FIG. 14, the 4th to 9th viewing angle switching units 700d to 700i can be provided in the lower side of the display area DA.

In this case, each of the first to 12th viewing angle switching units 700a to 700l is connected to one X-coordinate viewing angle control line VCLX and one Y-coordinate viewing angle control line VCLY, and X-coordinate viewing angle control lines VCLX1, VCLX2, VCLX3, and VCLX4 and the Y-coordinate viewing angle control lines VCLY1, VCLY2, and VCLY3 can be connected to the control driver 400. That is, one X-coordinate viewing angle control line VCLX and one Y-coordinate viewing angle control line VCLY are connected to each of the viewing angle switching units 700.

Also, a high voltage line HL and a low voltage line LL can be connected to each of the first viewing angle switching unit 700a to the 12th viewing angle switching unit 700l. A high voltage VGH can be supplied to a high voltage line HL through the power supply unit 500, and a low voltage VGL lower than the high voltage VGH can be supplied to a low voltage line LL through the power supply unit 500.

The high voltage VGH may be a voltage capable of turning off (or turning on) the first viewing angle control transistor Tvc1 and the second viewing angle control transistor Tvc2, and the low voltage VGL may be a voltage capable of turning on (or turning off) the first viewing angle control transistor Tvc1 and the second viewing angle control transistor Tvc2.

For example, as illustrated in FIG. 2, when the first viewing angle control transistor Tvc1 and the second viewing angle control transistor Tvc2 are formed of P-type transistors, the first viewing angle control transistor Tvc1 and the second viewing angle control transistor Tvc2 can be turned off by the high voltage VGH and can be turned on by the low voltage VGL.

That is, a voltage for turning on the first viewing angle control transistor Tvc1 and the second viewing angle control transistor Tvc2 and a voltage for turning off the first viewing angle control transistor Tvc1 and the second viewing angle control transistor Tvc2 can be changed based on the polarity types of the first viewing angle control transistor Tvc1 and the second viewing angle control transistor Tvc2.

Hereinafter, as illustrated in FIG. 2, a light emitting display apparatus including the first viewing angle control transistor Tvc1 and the second viewing angle control transistor Tvc2 formed of P-type transistors will be described as an example of a light emitting display apparatus according to the present disclosure. Therefore, the high voltage VGH can be a voltage capable of turning off the first viewing angle control transistor Tvc1 and the second viewing angle control transistor Tvc2, and the low voltage VGL can be a voltage capable of turning on the first viewing angle control transistor Tvc1 and the second viewing angle control transistor Tvc2.

In this case, each of the viewing angle switching units 700 can include the first switching unit 710 and the second switching unit 720.

For example, among the viewing angle switching units 700, an sth viewing angle switching unit (s is a natural number less than or equal to the number of light emitting areas) can include a first switching unit 710 connected to gates of the first viewing angle control transistors Tvc1 provided in an sth light emitting area among the light emitting areas EA, and a second switching unit 720 connected to gates of the second viewing angle control transistors Tvc2 provided in the sth light emitting area.

To provide an additional description, the first viewing angle switching unit 700a can include a first switching unit 710 connected to gates of the first viewing angle control transistors Tvc1 provided in the first light emitting area EA1 among the light emitting areas EA and a second switching unit 720 connected to gates of the second viewing angle control transistors Tvc2 provided in the first light emitting area EA1.

Moreover, the second viewing angle switching unit 700b can include a first switching unit 710 connected to gates of the first viewing angle control transistors Tvc1 provided in the second light emitting area EA2 among the light emitting areas EA and a second switching unit 720 connected to gates of the second viewing angle control transistors Tvc2 provided in the second light emitting area EA2.

Therefore, the 12th viewing angle switching unit 700l can include a first switching unit 710 connected to gates of the first viewing angle control transistors Tvc1 provided in the 12th light emitting area EA12 among the light emitting areas EA and a second switching unit 720 connected to gates of the second viewing angle control transistors Tvc2 provided in the 12th light emitting area EA12.

The first switching unit 710 can include a first transistor unit TU1 connected between a first control signal line CL1 connected to gates of the first viewing angle control transistors Tvc1 provided in the sth light emitting area and a low voltage line LL to which a low voltage is supplied, and a first resistance unit RU1 connected between the first control signal line CL1 and a high voltage line HL to which a high voltage VGH higher than the low voltage VGL is supplied.

The second switching unit 720 can include a second transistor unit TU2 connected between a second control signal line CL2 connected to gates of the second viewing angle control transistors Tvc2 provided in the sth light emitting area and the high voltage line HL, and second resistance unit RU2 connected between the second control signal line CL2 and the low voltage line LL.

For example, the first switching units 710 provided in the first viewing angle switching unit 700a to the 12th viewing angle switching unit 700l can have the same structure, and the second switching units 720 provided in the first viewing angle switching unit 700a to the 12th viewing angle switching unit 700l can have the same structure.

In this case, the structure of the first switching unit 710 and the structure of the second switching unit 720 can be formed differently from each other.

For example, as illustrated in FIG. 19, the first transistor unit TU1 of the first switching unit 710 can include a lath control transistor T1a and a 1bth control transistor T1b.

In this case, a gate of the lath control transistor T1a is connected to the X-coordinate viewing angle control line VCLX to which the X-coordinate viewing angle control signal VCSX is supplied, a first terminal of the lath control transistor T1a is connected to the low voltage line LL, and a second terminal of the lath control transistor T1a is connected to the first resistance unit RU1.

A gate of the 1bth control transistor T1b is connected to the Y-coordinate viewing angle control line VCLY to which the Y-coordinate viewing angle control signal VCSY is supplied, a first terminal of the 1bth control transistor T1b is connected to the low voltage line LL, and a second terminal of the 1bth control transistor T1b is connected to the first resistance unit RU1.

The second transistor unit TU2 of the second switching unit 720 can include a 2ath control transistor T2a and a 2bth control transistor T2b.

In this case, a gate of the 2ath control transistor T2a is connected to the X-coordinate viewing angle control line VCLX, a first terminal of the 2ath control transistor T2a is connected to the high voltage line HL, and a second terminal of the 2ath control transistor T2a is connected to the second resistance unit RU2.

A gate of the 2bth control transistor T2b is connected to the Y-coordinate viewing angle control line VCLY, a first terminal of the 2bth control transistor T2b is connected to the high voltage line HL, and a second terminal of the 2bth control transistor T2b is connected to the second resistance unit RU2.

In this case, each of the first resistance unit RU1 and the second resistance unit RU2 provided in the viewing angle switching unit 700 can be formed of resistors. For example, as illustrated in FIG. 19, the first resistance unit RU1 can include a first resistor R1 provided between the high voltage line HL and the first control signal line CL1, and the second resistance unit RU2 can include a second resistor R2 provided between the low voltage line LL and the second control signal line CL2.

The first resistor R1 and the second resistor R2 can be replaced with a first resistance transistor Tr1 and a second resistance transistor Tr2, as illustrated in FIG. 20. That is, each of the first resistance transistor Tr1 and the second resistance transistor Tr2 can function as a resistor.

Also, as illustrated in FIG. 21, the first resistor R1 can be replaced with a lath resistance transistor Tr1a and a 1bth resistance transistor Tr1b, and the second resistor R2 can be replaced with a 2ath resistance transistor Tr2a and the 2bth resistance transistor Tr2b.

In this case, a gate of the lath resistance transistor Tr1a and a gate of the 2ath resistance transistor Tr2a can be connected to the X-coordinate viewing angle control line VCLX, and a gate of the 1bth resistance transistor Tr1b and a gate of the 2bth resistance transistor Tr2b can be connected to the Y-coordinate viewing angle control line VCLY.

Hereinafter, a method of operating the viewing angle switching unit 700 and a method of driving a light emitting area EA corresponding to the viewing angle switching unit 700 will be described with reference to FIGS. 18 to 22. Particularly, hereinafter, as illustrated in FIG. 19, the viewing angle switching unit 700 including the lath control transistor T1a, the 1bth control transistor T1b, the 2ath control transistor T2a, and the 2bth control transistor T2b formed in P-type will be described as an example of the present disclosure. As described above, because the viewing angle switching units 700 have the same structure, the details described below can be applied to each of the viewing angle switching units 700.

First, as illustrated in FIG. 22, when the X-coordinate viewing angle control signal VCSX having a low level is supplied through the X-coordinate viewing angle control line VCLX and the Y-coordinate viewing angle control signal VCSY having a low level is supplied through the Y-coordinate viewing angle control line VCLY, the lath control transistor T1a, the 1bth control transistor T1b, the 2ath control transistor T2a, and the 2bth control transistor T2b illustrated in FIG. 19 are turned on.

Therefore, the low voltage VGL supplied through the first terminal of the lath control transistor T1a and the first terminal of the 1bth control transistor T1b is supplied to the first control signal line CL1 through the lath control transistor T1a and the 1bth control transistor T1b. That is, the first control signal CS1 having the low level is supplied to the first control signal line CL1.

Also, the high voltage VGH supplied through the first terminal of the 2ath control transistor T2a and the first terminal of the 2bth control transistor T2b is supplied to the second control signal line CL2 through the 2ath control transistor T2a and the 2bth control transistor T2b. That is, the second control signal CS2 having the high level is supplied to the second control signal line CL2.

In this case, when the viewing angle switching unit 700 illustrated in FIG. 19 is the first viewing angle switching unit 700a, the first control signal line CL1 connected to the first viewing angle switching unit 700a is connected to gates of the first viewing angle control transistors Tvc1 provided in the first light emitting area EA1, and the second control signal line CL2 connected to the first viewing angle switching unit 700a is connected to gates of the second viewing angle control transistors Tvc2 provided in the first light emitting area EA1.

Therefore, the first control signal CS1 having the low level is supplied to gates of the first viewing angle control transistors Tvc1 provided in the first light emitting area EA1, and the second control signal CS2 having the high level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the low level is supplied to the first viewing angle control transistors Tvc1, the first viewing angle control transistors Tvc1 are turned on, and when the second control signal CS2 having the high level is supplied to the second viewing angle control transistors Tvc2, the second viewing angle control transistors Tvc2 are turned off.

Accordingly, in the first light emitting area EA1, an image having the wide viewing angle in the left-right direction can be output through the first light emitting units LU1 connected to the first viewing angle control transistors Tvc1. That is, in the first light emitting area EA1, only the first light emitting units LU1 can be driven to output an image having the wide viewing angle.

Therefore, a mode of the first light emitting area EA1 can be the share mode (SM).

In this case, as illustrated in FIG. 20, when the first resistance unit RU1 is formed of the first resistance transistor Tr1 and the second resistance unit RU2 is formed of the second resistance transistor Tr2, the gate of the first resistance transistor Tr1 and the gate of the second resistance transistor Tr2 are connected to the resistance control line RL. The first resistance transistor Tr1 and the second resistance transistor Tr2 can be formed of P-type transistors, and a resistance control signal having the high level can be input to the resistance control line RL. Accordingly, the first resistance transistor Tr1 and the second resistance transistor Tr2 are turned off by the resistance control signal having the high level.

Also, as illustrated in FIG. 21, when the first resistance unit RU1 includes the lath resistance transistor Tr1a and the 1bth resistance transistor Tr1b, and the second resistance unit RU2 includes the 2ath resistance transistor Tr2a and the 2bth resistance transistor Tr2b, the gate of the lath resistance transistor Tr1a and the gate of the 2ath resistance transistor Tr2a can be connected to the X-coordinate viewing angle control line VCLX, and the gate of the 1bth resistance transistor Tr1b and the gate of the 2bth resistance transistor Tr2b can be connected to the Y-coordinate viewing angle control line VCLY.

The lath resistance transistor Tr1a, the 1bth resistance transistor Tr1b, the 2ath resistance transistor Tr2a, and the 2bth resistance transistor Tr2b can be formed of N-type transistors, the X-coordinate viewing angle control signal VCSX having the low level can be input to the X-coordinate viewing angle control line VCLX, and the Y-coordinate viewing angle control signal VCSY having the low level can be input to the Y-coordinate viewing angle control line VCLY.

Therefore, the lath resistance transistor Tr1a, the 1bth resistance transistor Tr1b, the 2ath resistance transistor Tr2a, and the 2bth resistance transistor Tr2b are turned off by the X-coordinate viewing angle control signal VCSX and the Y-coordinate viewing angle control signal VCSY having low levels.

Accordingly, as described above, the first control signal CS1 having the low level can be supplied to the first control signal line CL1 through the lath control transistor T1a and the 1bth control transistor T1b, and the second control signal CS2 having the high level can be supplied to the second control signal line CL2 through the 2ath control transistor T2a and the 2bth control transistor T2b.

Therefore, in the first light emitting area EA1, an image having the wide viewing angle in the left-right direction can be output through the first light emitting units LU1 connected to the first viewing angle control transistors Tvc1.

That is, a mode of the first light emitting area EA1 can be the share mode (SM).

Second, as illustrated in FIG. 22, when the X-coordinate viewing angle control signal VCSX having the low level is supplied through the X-coordinate viewing angle control line VCLX and the Y-coordinate viewing angle control signal VCSY having the high level is supplied through the Y-coordinate viewing angle control line VCLY, the lath control transistor T1a and the 2ath control transistor T2a illustrated in FIG. 19 are turned on, and the 1bth control transistor T1b and the 2bth control transistor T2b are turned off.

Therefore, the low voltage VGL supplied through the first terminal of the lath control transistor T1a is supplied to the first control signal line CL1 through the lath control transistor T1a. That is, the first control signal CS1 having the low level is supplied to the first control signal line CL1.

Also, the high voltage VGH supplied through the first terminal of the 2ath control transistor T2a is supplied to the second control signal line CL2 through the 2ath control transistor T2a. That is, the second control signal CS2 having the high level is supplied to the second control signal line CL2.

Therefore, the first control signal CS1 having the low level is supplied to gates of the first viewing angle control transistors Tvc1 provided in the first light emitting area EA1, and the second control signal CS2 having the high level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the low level is supplied to the first viewing angle control transistors Tvc1, the first viewing angle control transistors Tvc1 are turned on, and when the second control signal CS2 having the high level is supplied to the second viewing angle control transistors Tvc2, the second viewing angle control transistors Tvc2 are turned off.

Accordingly, in the first light emitting area EA1, an image having the wide viewing angle in the left-right direction can be output through the first light emitting units LU1 connected to the first viewing angle control transistors Tvc1. That is, in the first light emitting area EA1, only the first light emitting units LU1 can be driven to output an image having the wide viewing angle.

Therefore, a mode of the first light emitting area EA1 can be the share mode (SM).

In this case, as illustrated in FIG. 20, when the first resistance unit RU1 is formed of the first resistance transistor Tr1 and the second resistance unit RU2 is formed of the second resistance transistor Tr2, the gate of the first resistance transistor Tr1 and the gate of the second resistance transistor Tr2 are connected to the resistance control line RL. The first resistance transistor Tr1 and the second resistance transistor Tr2 can be formed of P-type transistors, and a resistance control signal having the high level can be input to the resistance control line RL. Accordingly, the first resistance transistor Tr1 and the second resistance transistor Tr2 are turned off by the resistance control signal having the high level.

Also, as illustrated in FIG. 21, when the first resistance unit RU1 includes the lath resistance transistor Tr1a and the 1bth resistance transistor Tr1b, and the second resistance unit RU2 includes the 2ath resistance transistor Tr2a and the 2bth resistance transistor Tr2b, the gate of the lath resistance transistor Tr1a and the gate of the 2ath resistance transistor Tr2a can be connected to the X-coordinate viewing angle control line VCLX, and the gate of the 1bth resistance transistor Tr1b and the gate of the 2bth resistance transistor Tr2b can be connected to the Y-coordinate viewing angle control line VCLY.

The lath resistance transistor Tr1a, the 1bth resistance transistor Tr1b, the 2ath resistance transistor Tr2a, and the 2bth resistance transistor Tr2b can be formed of N-type transistors, the X coordinate viewing angle control signal VCSX having the low level can be input to the X-coordinate viewing angle control line VCLX, and the Y-coordinate viewing angle control signal VCSY having the high level can be input to the Y-coordinate viewing angle control line VCLY.

Therefore, the lath resistance transistor Tr1a and the 2ath resistance transistor Tr2a are turned off by the X-coordinate viewing angle control signal VCSX having the low level, and the 1bth resistance transistor Tr1b and the 2bth resistance transistor Tr2b are turned on by the Y-coordinate viewing angle control signal VCSY having the high level.

Because the lath resistance transistor Tr1a is turned off, the high voltage VGH cannot be supplied to the first control signal line CL1, and because the 2ath resistance transistor Tr2a is turned off, the low voltage VGL cannot be supplied to the second control signal line CL2.

Accordingly, as described above, the first control signal CS1 having the low level can be supplied to the first control signal line CL1 through the lath control transistor T1a, and the second control signal CS2 having the high level can be supplied to the second control signal line CL2 through the 2ath control transistor T2a.

Therefore, in the first light emitting area EA1, an image having the wide viewing angle in the left-right direction can be output through the first light emitting units LU1 connected to the first viewing angle control transistors Tvc1.

That is, a mode of the first light emitting area EA1 can be the share mode (SM).

Third, as illustrated in FIG. 22, when the X-coordinate viewing angle control signal VCSX having the high level is supplied through the X-coordinate viewing angle control line VCLX and the Y-coordinate viewing angle control signal VCSY having the low level is supplied through the Y-coordinate viewing angle control line VCLY, the lath control transistor T1a and the 2ath control transistor T2a illustrated in FIG. 19 are turned off, and the 1bth control transistor T1b and the 2bth control transistor T2b are turned on.

Accordingly, the low voltage VGL supplied through the first terminal of the 1bth control transistor T1b is supplied to the first control signal line CL1 through the 1bth control transistor T1b. That is, the first control signal CS1 having the low level is supplied to the first control signal line CL1.

Also, the high voltage VGH supplied through the first terminal of the 2bth control transistor T2b is supplied to the second control signal line CL2 through the 2bth control transistor T2b. That is, the second control signal CS2 having the high level is supplied to the second control signal line CL2.

Therefore, the first control signal CS1 having the low level is supplied to gates of the first viewing angle control transistors Tvc1 provided in the first light emitting area EA1, and the second control signal CS2 having the high level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the low level is supplied to the first viewing angle control transistors Tvc1, the first viewing angle control transistors Tvc1 are turned on, and when the second control signal CS2 having the high level is supplied to the second viewing angle control transistors Tvc2, the second viewing angle control transistors Tvc2 are turned off.

Accordingly, in the first light emitting area EA1, an image having the wide viewing angle in the left-right direction can be output through the first light emitting units LU1 connected to the first viewing angle control transistors Tvc1. That is, in the first light emitting area EA1, only the first light emitting units LU1 can be driven to output an image having the wide viewing angle.

Therefore, a mode of the first light emitting area EA1 can be the share mode (SM).

In this case, as illustrated in FIG. 20, when the first resistance unit RU1 is formed of the first resistance transistor Tr1 and the second resistance unit RU2 is formed of the second resistance transistor Tr2, the gate of the first resistance transistor Tr1 and the gate of the second resistance transistor Tr2 are connected to the resistance control line RL. The first resistance transistor Tr1 and the second resistance transistor Tr2 can be formed of P-type transistors, and a resistance control signal having the high level can be input to the resistance control line RL. Accordingly, the first resistance transistor Tr1 and the second resistance transistor Tr2 are turned off by the resistance control signal having the high level.

Also, as illustrated in FIG. 21, when the first resistance unit RU1 includes the lath resistance transistor Tr1a and the 1bth resistance transistor Tr1b, and the second resistance unit RU2 includes the 2ath resistance transistor Tr2a and the 2bth resistance transistor Tr2b, the gate of the lath resistance transistor Tr1a and the gate of the 2ath resistance transistor Tr2a can be connected to the X-coordinate viewing angle control line VCLX, and the gate of the 1bth resistance transistor Tr1b and the gate of the 2bth resistance transistor Tr2b can be connected to the Y-coordinate viewing angle control line VCLY.

The lath resistance transistor Tr1a, the 1bth resistance transistor Tr1b, the 2ath resistance transistor Tr2a, and the 2bth resistance transistor Tr2b can be formed of N-type transistors, the X-coordinate viewing angle control signal VCSX having the high level can be input to the X-coordinate viewing angle control line VCLX, and the Y-coordinate viewing angle control signal VCSY having the low level can be input to the Y-coordinate viewing angle control line VCLY.

Therefore, the lath resistance transistor Tr1a and the 2ath resistance transistor Tr2a are turned on by the X-coordinate viewing angle control signal VCSX having the high level, and the 1bth resistance transistor Tr1b and the 2bth resistance transistor Tr2b are turned off by the Y-coordinate viewing angle control signal VCSY having the low level.

Because the 1bth resistance transistor Tr1b is turned off, the high voltage VGH cannot be supplied to the first control signal line CL1, and because the 2bth resistance transistor Tr2b is turned off, the low voltage VGL cannot be supplied to the second control signal line CL2.

Accordingly, as described above, the first control signal CS1 having the low level can be supplied to the first control signal line CL1 through the 1bth control transistor T1b, and the second control signal CS2 having the high level can be supplied to the second control signal line CL2 through the 2bth control transistor T2b.

Therefore, in the first light emitting area EA1, an image having the wide viewing angle in the left-right direction can be output through the first light emitting units LU1 connected to the first viewing angle control transistors Tvc1.

That is, a mode of the first light emitting area EA1 can be the share mode (SM).

Fourth, as illustrated in FIG. 22, when the X-coordinate viewing angle control signal VCSX having the high level is supplied through the X-coordinate viewing angle control line VCLX and the Y-coordinate viewing angle control signal VCSY having the high level is supplied through the Y-coordinate viewing angle control line VCLY, the lath control transistor T1a, the 2ath control transistor T2a, the 1bth control transistor T1b, and the 2bth control transistor T2b illustrated in FIG. 19 are turned off.

Accordingly, the high voltage VGH supplied through the first resistance unit RU1 is supplied to the first control signal line CL1 through the first resistance unit RU1. That is, the first control signal CS1 having the high level is supplied to the first control signal line CL1.

Also, the low voltage VGL supplied through the second resistance unit RU2 is supplied to the second control signal line CL2 through the second resistance unit RU2. That is, the second control signal CS2 having the low level is supplied to the second control signal line CL2.

In this case, when the viewing angle switching unit 700 illustrated in FIG. 19 is the first viewing angle switching unit 700a, the first control signal line CL1 connected to the first viewing angle switching unit 700a is connected to gates of the first viewing angle control transistors Tvc1 provided in the first light emitting area EA1, and the second control signal line CL2 connected to the first viewing angle switching unit 700a is connected to gates of the second viewing angle control transistors Tvc2 provided in the first light emitting area EA1.

Therefore, the first control signal CS1 having the high level is supplied to gates of the first viewing angle control transistors Tvc1 provided in the first light emitting area EA1, and the second control signal CS2 having the low level is supplied to gates of the second viewing angle control transistors Tvc2 provided in the first light emitting area EA1.

The first viewing angle control transistors Tvc1 and the second viewing angle control transistors Tvc2 can be formed of P-type transistors, as illustrated in FIG. 2. Therefore, when the first control signal CS1 having the high level is supplied to the first viewing angle control transistors Tvc1, the first viewing angle control transistors Tvc1 are turned off, and when the second control signal CS2 having the low level is supplied to the second viewing angle control transistors Tvc2, the second viewing angle control transistors Tvc2 are turned on.

Accordingly, in the first light emitting area EA1, an image having the narrow viewing angle in the left-right direction can be output through the second light emitting units LU2 connected to the second viewing angle control transistors Tvc2. That is, in the first light emitting area EA1, only the second light emitting units LU2 can be driven to output an image having the narrow viewing angle.

Therefore, a mode of the first light emitting area EA1 can be the privacy mode (PM).

In this case, as illustrated in FIG. 20, when the first resistance unit RU1 is formed of the first resistance transistor Tr1 and the second resistance unit RU2 is formed of the second resistance transistor Tr2, the gate of the first resistance transistor Tr1 and the gate of the second resistance transistor Tr2 are connected to the resistance control line RL. The first resistance transistor Tr1 and the second resistance transistor Tr2 can be formed of P-type transistors, and a resistance control signal having the low level can be input to the resistance control line RL. Accordingly, the first resistance transistor Tr1 and the second resistance transistor Tr2 are turned on by the resistance control signal having the low level.

Also, as illustrated in FIG. 21, when the first resistance unit RU1 includes the lath resistance transistor Tr1a and the 1bth resistance transistor Tr1b, and the second resistance unit RU2 includes the 2ath resistance transistor Tr2a and the 2bth resistance transistor Tr2b, the gate of the lath resistance transistor Tr1a and the gate of the 2ath resistance transistor Tr2a can be connected to the X-coordinate viewing angle control line VCLX, and the gate of the 1bth resistance transistor Tr1b and the gate of the 2bth resistance transistor Tr2b can be connected to the Y-coordinate viewing angle control line VCLY.

The lath resistance transistor Tr1a, the 1bth resistance transistor Tr1b, the 2ath resistance transistor Tr2a, and the 2bth resistance transistor Tr2b can be formed of N-type transistors, the X-coordinate viewing angle control signal VCSX having the high level can be supplied to the X-coordinate viewing angle control line VCLX, and the Y-coordinate viewing angle control signal VCSY having the high level can be input to the Y-coordinate viewing angle control line VCLY.

Therefore, the lath resistance transistor Tr1a, the 1bth resistance transistor Tr1b, the 2ath resistance transistor Tr2a, and the 2bth resistance transistor Tr2b are turned on by the X-coordinate viewing angle control signal VCSX and the Y-coordinate viewing angle control signal VCSY having high levels. Accordingly, as described above, the first control signal CS1 having the high level can be supplied to the first control signal line CL1 through the lath resistance transistor Tr1a and the 1bth resistance transistor Tr1b, and the second control signal CS2 having the low level can be supplied to the second control signal line CL2 through the 2ath resistance transistor Tr2a and the 2bth resistance transistor Tr2b. Therefore, in the first light emitting area EA1, an image having the narrow viewing angle in the left-right direction can be output through the second light emitting units LU2 connected to the second viewing angle control transistors Tvc2.

That is, a mode of the first light emitting area EA1 can be the privacy mode (PM).

The operation method described above can also be independently performed in the second viewing angle switching unit 700b to the 12th viewing angle switching unit 700l. Accordingly, in each of the second to 12th light emitting areas EA2 to EA12, an image having the wide viewing angle can be output or an image having the narrow viewing angle can be output.

Hereinafter, an operation method of a light emitting display apparatus according to the present disclosure will be described with reference to the viewing angle switching units 700 illustrated in FIGS. 14 to 17. In this case, a detailed operation method of each of the viewing angle switching units 700 described with reference to FIGS. 14 to 17 is omitted.

The operation method described below can be equally applied to a light emitting display apparatus including the viewing angle switching units 700 described with reference to FIGS. 18 to 22.

As described above, the viewing angle control signals VCSX1, VCSX2, VCSX3, VCSX4, VCSY1, VCSY2, and VCSY3 transmitted to the viewing angle switching units 700 described with reference to FIGS. 18 to 22 are different from the viewing angle control signals VCS1 to VCS12 transmitted to the viewing angle switching units 700 described with reference to FIGS. 14 to 17. However, the first control signals CS1 and the second control signals CS2 generated by the viewing angle switching units 700 described with reference to FIGS. 18 to 22 are the same as the first control signals CS1 and the second control signals CS2 generated by the viewing angle switching units 700 described with reference to FIGS. 14 to 17.

Therefore, the method of operating the viewing angle switching units 700 and the method of driving the subpixels described below can be applied equally or similarly to the method of operating the viewing angle switching units 700 and the method of driving the subpixels which are described with reference to FIGS. 18 to 22.

First, after a vehicle is started and the vehicle is driven by a driver, a vehicle operation information signal can be transmitted from the external system 600 to the control driver 400.

In this case, a first viewing angle control signal generator 701 to a 6th viewing angle control signal generator 706 can generate a first viewing angle control signal VCS1 to a 6th viewing angle control signal VCS6 having the low levels. The first to 6th viewing angle control signals VCS1 to VCS6 can be transmitted to the first to 6th viewing angle switching units 700a to 700f through the first to 6th viewing angle control lines VCL1 to VCL6.

In this case, each of the first viewing angle switching unit 700a to the 6th viewing angle switching unit 700f can transmit a first control signal CS1 having the low level to the first control signal line CL1 and can transmit a second control signal CS2 having the high level to the second control signal line CL2.

In the subpixels P provided in the first to 6th light emitting areas EA1 to EA6 corresponding to the first to 6th viewing angle switching units 700a to 700f, the first viewing angle control transistors Tvc1 connected to the first control signal lines CL1 and the second viewing angle control transistors Tvc2 connected to the second control signal lines CL2 can be provided. In this case, as illustrated in FIG. 2, the first and second viewing angle control transistors Tvc1 and Tvc2 can be P-type transistors.

Therefore, in the subpixels P provided in the first to 6th light emitting areas EA1 to EA6, only the first viewing angle control transistors Tvc1 can be turned on by the first control signals CS1 having the low level, and the second viewing angle control transistors Tvc2 can be turned off by the second control signals CS2 having the high level.

Accordingly, in the first to 6th light emitting areas EA1 to EA6, as illustrated in FIG. 7A, the first image having the wide viewing angle in the left-right direction, for example, the vehicle operation information image, can be displayed through the first light emitting units LU1. Accordingly, both a driver and a passenger can see the vehicle operation information image.

In other words, while a vehicle is operated, the vehicle operation information image IM1 should be necessarily displayed, and particularly, the vehicle operation information image

IM1 can have the first viewing angle, for example, the wide viewing angle, so that it can be seen by both a driver and a passenger.

Therefore, modes of the first to 6th light emitting areas EA1 to EA6 can be share modes (SM).

Next, while a vehicle is operated by a driver, if a television, radio, internet, or file playback program is selected by a driver or a passenger, a general image signal can be transmitted from the external system 600 to the control driver 400.

In this case, a 7th viewing angle control signal generator 707 to a 12th viewing angle control signal generator 712 can generate a 7th viewing angle control signal VCS7 to a 12th viewing angle control signal VCS12 having the high levels. The 7th viewing angle control signal VCS7 to the 12th viewing angle control signal VCS12 can be transmitted to a 7th to 12th switching units 700g to 700l through a 7th viewing angle control line VCL7 to a 12th viewing angle control line VCL12.

In this case, each of a 7th viewing angle switching unit 700g to a 12th viewing angle switching unit 700l can transmit a first control signal CS1 having the high level to the first control signal line CL1, and can transmit a second control signal CS2 having the low level to the second control signal line CL2.

Subpixels P provided in the 7th to 12th light emitting areas EA7 to EA12 corresponding to the 7th viewing angle switching unit 700g to the 12th viewing angle switching unit 700l can be provided with first viewing angle control transistors Tvc1 connected to the first control signal lines CL1 and the second viewing angle control transistors Tvc2 connected to the second control signal lines CL2. In this case, as illustrated in FIG. 2, the first viewing angle control transistors Tvc1 and the second viewing angle control transistors Tvc2 can be P-type transistors.

Therefore, in the subpixels P provided in the 7th to 12th light emitting areas EA7 to EA12, only the second viewing angle control transistors Tvc2 can be turned on by the second control signals CS2 having the low level, and the first viewing angle control transistors Tvc1 can be turned off by the first control signals CS1 having the high level.

Accordingly, in the 7th to 12th light emitting areas EA7 to EA12, as illustrated in FIG. 7A, the second image having the narrow viewing angle in the left-right direction, for example, the general image, can be displayed through the second light emitting units LU2. Accordingly, only a passenger can see the general image.

In other words, while a vehicle is operated, the general image IM2 which disturbs a driver can have the second viewing angle, for example, the narrow viewing angle, so that it can be seen by only a passenger.

Therefore, modes of the 7th to 12th light emitting areas EA7 to EA12 can be privacy modes (PM).

Next, if a vehicle is not operated or is stopped in a parking mode, an operation stop signal can be transmitted from the external system 600 to the control driver 400.

In this case, if the entire screen of a light emitting display panel 100 is converted to a screen for viewing the general image IM2 by a user's selection or by an automatic function of the control driver 400, the first viewing angle control signal generator 701 to the 12th viewing angle control signal generator 712 can generate the first viewing angle control signal VCS1 to the 12th viewing angle control signal VCS12 having the low level. The first viewing angle control signal VCS1 to the 12th viewing angle control signal VCS12 can be transmitted through the first viewing angle control line VCL1 to the 12th viewing angle control line VCL12 to the first to 12th viewing angle switching units 700a to 700l.

In this case, each of the first viewing angle switching unit 700a to the 12th viewing angle switching unit 700l can transmit a first control signal CS1 having the low level to the first control signal line CL1 and can transmit a second control signal CS2 having the high level to the second control signal line CL2.

Accordingly, in the subpixels P provided in the first to 12th light emitting areas EA1 to EA12, only the first viewing angle control transistors Tvc1 can be turned on by the first control signals CS1 having the low level, and the second viewing angle control transistors Tvc2 can be turned off by the second control signals CS2 having the high level.

Therefore, in the first to 12th light emitting areas EA1 to EA12, as illustrated in FIG. 7B, the second image IM2 having the wide viewing angle in the left-right direction, for example, the general image, can be displayed through the first light emitting units LU1. Accordingly, both a driver and a passenger can see the general image.

In other words, while a vehicle is operated, the general image IM2 may disturb a driver. However, while a vehicle is not operated or is stopped in a parking mode, there is little chance of an accident occurring due to the general image IM2. Therefore, when a vehicle is not operated or is stopped in a parking mode, as illustrated in FIG. 7B, the general image IM2 having the first viewing angle, for example, the wide viewing angle, can be displayed through the entire light emitting display panel 100.

Therefore, modes of the first to 12th light emitting areas EA1 to EA12 can be share modes (SM).

To provide an additional description, in a light emitting display apparatus according to the present disclosure, each of the light emitting areas EA1 to EA12 can output an image having the wide viewing angle, or can output an image having the narrow viewing angle.

Further, in a light emitting display apparatus according to the present disclosure, the same type of image (e.g., the general image IM2) can have the narrow viewing angle or the wide viewing angle depending on a driving mode of a vehicle, etc.

Next, while a vehicle is operated by a driver, if the third image IM3, for example, the vehicle operation information auxiliary image such as navigation, is selected by a driver or a passenger, a vehicle operation information auxiliary signal can be transmitted to the control driver 400 from the external system 600.

If the vehicle operation information auxiliary signal is transmitted from the external system 600 to the control driver 400 and the vehicle operation information auxiliary image IM3 is set to be displayed in 7th to 9th light emitting areas EA7 to EA9, as illustrated in FIG. 7C, 7th to 9th viewing angle control signal generator 707 to 709 can transmit 7th to 9th viewing angle control signals VCS7 to VCS9 having the low levels to 7th to 9th viewing angle switching units 700g to 700i through 7th to 9th viewing angle control lines VCL7 to VCL9.

In this case, each of the 7th viewing angle switching unit 700g to the 9th viewing angle switching unit 700i can transmit a first control signal CS1 having the low level to the first control signal line CL1 and can transmit a second control signal CS2 having the high level to the second control signal line CL2.

Therefore, in the subpixels P provided in the 7th to 9th light emitting areas EA7 to EA9, only the first viewing angle control transistors Tvc1 can be turned on by the first control signals CS1 having the low level, and the second viewing angle control transistors Tvc2 can be turned off by the second control signals CS2 having the high level.

Accordingly, in the 7th to 9th light emitting areas EA7 to EA9, the third image IM3 having the wide viewing angle in the left-right direction, for example, the vehicle operation information auxiliary image, can be displayed through the first light emitting units LU1, as illustrated in FIG. 7C. Therefore, both a driver and a passenger can see the vehicle operation information auxiliary image.

Therefore, modes of the 7th to 9th light emitting areas EA7 to EA9 can be share modes (SM).

In other words, while a vehicle is operated, the vehicle operation information auxiliary image IM3 is an image beneficial to a driver and a passenger, and thus, the vehicle operation information auxiliary image IM3 can have the first viewing angle, for example, the wide viewing angle, so that it can be seen by both a driver and a passenger.

Further, If the vehicle operation information auxiliary signal is transmitted from the external system 600 to the control driver 400 and the vehicle operation information auxiliary image IM3 is set to be displayed in a 7th light emitting area EA7 and a 10th light emitting areas EA10, as illustrated in FIG. 7D, a 7th viewing angle control signal generator 707 and a 10th viewing angle control signal generator can transmit a 7th viewing angle control signals VCS7 and a 10th viewing angle control signals VCS10 having low levels to a 7th viewing angle switching units 700g and a 10th viewing angle switching units 700j.

In this case, each of the 7th viewing angle switching unit 700g and the 10th viewing angle switching unit 700j can transmit a first control signal CS1 having the low level to the first control signal line CL1, and can transmit a second control signal CS2 having the high level to the second control signal line CL2.

Therefore, in the subpixels P provided in the 7th light emitting area EA7 and the 10th light emitting area EA10, only the first viewing angle control transistors Tvc1 can be turned on by the first control signals CS1 having the low level, and the second viewing angle control transistors Tvc2 can be turned off by the second control signals CS2 having the high level.

Accordingly, in the 7th light emitting area EA7 and the 10th light emitting areas EA10, the third image IM3 having the wide viewing angle in the left-right direction, for example, the vehicle operation information auxiliary image, can be displayed through the first light emitting units LU1, as illustrated in FIG. 7D. Therefore, both a driver and a passenger can see the vehicle operation information auxiliary image.

Therefore, modes of the 7th light emitting area EA7 and the 10th light emitting area EA10 can be share modes (SM).

In other words, while a vehicle is operated, the vehicle operation information auxiliary image IM3 is an image beneficial to a driver and a passenger, and thus, the vehicle operation information auxiliary image IM3 can have the first viewing angle, for example, the wide viewing angle, so that it can be seen by both a driver and a passenger.

Particularly, in a light emitting display apparatus according to the present disclosure, as illustrated in FIGS. 7C and 7D, a position where the image with the first viewing angle is output and a position where the image with the second viewing angle is output can be changed not only along the first direction X but also along the second direction Y.

That is, according to a light emitting display apparatus according to the present disclosure, the position where the image with the first viewing angle is output and the position where the image with the second viewing angle is output can be freely changed. Therefore, a driver or a passenger can freely change the position where the image with the first viewing angle is output and the position where the image with the second viewing angle is output.

For example, a driver or a passenger can set the area illustrated in FIG. 7C (for example, the 7th light emitting area EA7 to the 9th light emitting area EA9) or the area illustrated in FIG. 7D (for example, the 7th light emitting area EA7 and the 10th light emitting area EA10) to the position where the vehicle operation information auxiliary image IM3 such as navigation is output, by using the external system 60.

However, a position where an image affecting the safe driving, like the vehicle operation information image IM1, is output can be fixed at a specific area (for example, the first to 6th light emitting areas EA1 to EA6) by the external system 600 or the control driver 400.

Finally, while a vehicle is operated by a driver or a vehicle is not operated or stopped in a parking mode, if the emergency information image IM4 is received, an emergency information signal can be transmitted to the control driver 400 from the external system 600.

For example, when the emergency information signal is received, an 8th viewing angle control signal generator 708 can generate an 8th viewing angle control signal VCS8 having the low level. The 8th viewing angle control signal VCS8 can be transmitted to an 8th viewing angle switching unit 700h through an 8th viewing angle control line VCL8.

In this case, the 8th viewing angle switching unit 700h can transmit a first control signal CS1 having the low level to the first control signal line CL1, and can transmit a second control signal CS2 having the high level to the second control signal line CL2.

Accordingly, in the subpixels P provided in the 8th light emitting area EA8, only the first viewing angle control transistors Tvc1 can be turned on by the first control signal CS1 having the low level and the second viewing angle control transistors Tvc2 can be turned off by the second control signal CS2 having the high level.

Accordingly, in the 8th light emitting area EA8, as illustrated in FIG. 7E, the fourth image IM4 having the wide viewing angle in the left-right direction, for example, the emergency information image, can be displayed through the first light emitting units LU1.

Therefore, a mode of the 8th light emitting area EA8 can be the share mode (SM).

In other words, while a vehicle is operated, the emergency information image IM4 is an image which needs to be viewed by not only a driver but also a passenger, and thus, the emergency information image IM4 can have the first viewing angle, for example, the wide viewing angle, so that it can be seen by both a driver and a passenger.

In this case, the emergency information image IM4 can be displayed through any one of the light emitting areas where the general image IM2 having the second viewing angle (narrow viewing angle) is displayed, as illustrated in FIG. 7E.

However, as illustrated in FIGS. 7A and 7F, the emergency information image IM4 can be displayed through any one of the light emitting areas where the vehicle operation information image IM1 having the first viewing angle (wide viewing angle) is displayed.

That is, in a light emitting display apparatus according to the present disclosure, each of the light emitting areas EA1 to EA12 can be driven independently, and thus, each of the light emitting areas EA1 to EA12 can independently display an image having the first viewing angle (wide viewing angle) or an image having the second viewing angle (narrow viewing angle).

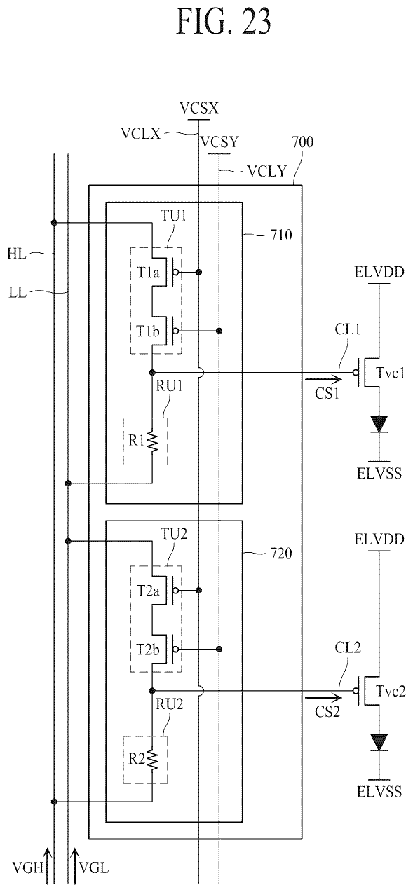

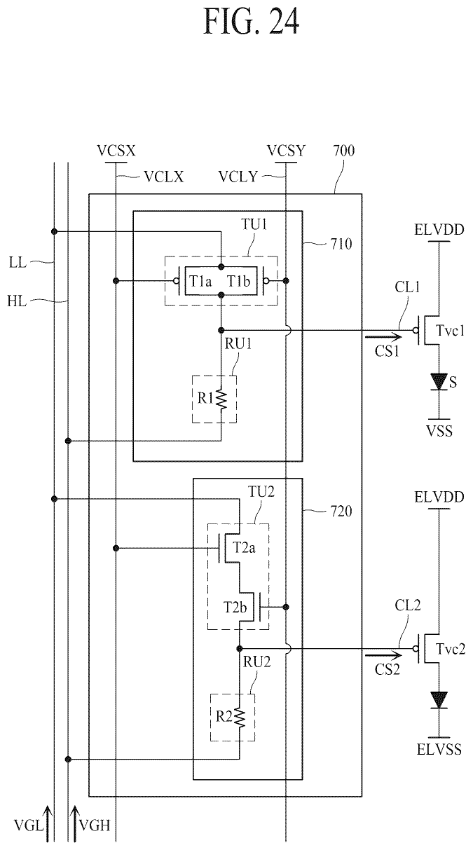

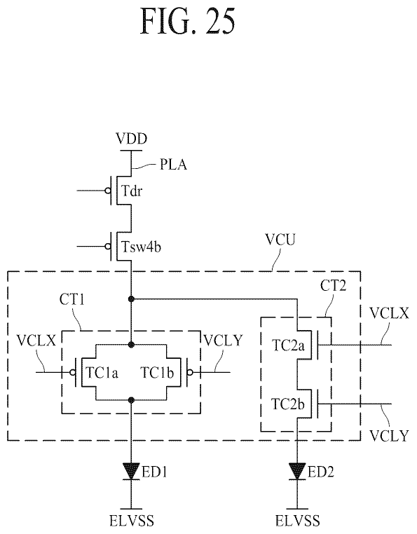

FIGS. 23 and 24 are other exemplary diagrams illustrating a structure of a viewing angle switching unit applied to a light emitting display apparatus according to the present disclosure, and FIG. 25 is another exemplary diagram illustrating a structure of a viewing angle control unit applied to a light emitting display apparatus according to the present disclosure.

In this case, functions of viewing angle switching units illustrated in FIGS. 23 and 24 are the same as or similar to the functions of the viewing angle switching units described above. Also, a function of a viewing angle control unit VCU illustrated in FIG. 25 is the same as or similar to the function of the viewing angle control unit VCU described with reference to FIG. 2. Therefore, in the following descriptions, details which are the same as or similar to details described with reference to FIGS. 1 to 22 are omitted or will be briefly described.

First, a viewing angle switching unit 700 illustrated in FIG. 23 includes a first switching unit 710 and a second switching unit 720. The first switching unit 710 includes a first transistor unit TU1 and a first resistance unit RU1, and the second switching unit 720 includes a second transistor unit TU2 and a second resistance unit RU2.

The first switching unit 710 includes a lath control transistor T1a and a 1bth control transistor T1b. The lath control transistor T1a and the 1bth control transistor T1b can be formed of P-type transistors.

A gate of the lath control transistor T1a is connected to the X-coordinate viewing angle control line VCLX to which the X-coordinate viewing angle control signal VCSX is supplied, a first terminal of the lath control transistor T1a is connected to the high voltage line HL, and a second terminal of the lath control transistor T1a is connected to a first terminal of the 1bth control transistor T1b.

A gate of the 1bth control transistor T1b is connected to the Y-coordinate viewing angle control line VCLY to which the Y-coordinate viewing angle control signal VCSY is supplied, a first terminal of the 1bth control transistor T1b is connected to the second terminal of the lath control transistor T1a, and a second terminal of the 1bth control transistor T1b is connected to the first resistance unit RU1.

The second switching unit 720 includes a 2ath control transistor T2a and a 2bth control transistor T2b. The 2ath control transistor T2a and the 2bth control transistor T2b can be formed of P-type transistors.

A gate of the 2ath control transistor T2a is connected to the X-coordinate viewing angle control line VCLX to which the X-coordinate viewing angle control signal VCSX is supplied, a first terminal of the 2ath control transistor T2a is connected to the low voltage line LL, and a second terminal of the 2ath control transistor T2a is connected to a first terminal of the 2bth control transistor T2b.

A gate of the 2bth control transistor T2b is connected to the Y-coordinate viewing angle control line VCLY to which the Y-coordinate viewing angle control signal VCSY is supplied, a first terminal of the 2bth control transistor T2b is connected to the second terminal of the 2ath control transistor T2a, and a second terminal of the 2bth control transistor T2b is connected to the second resistance unit RU2.

In this case, if at least one of the X-coordinate viewing angle control signal VCSX and the Y-coordinate viewing angle control signal VCSY has the high level, the first switching unit 710 outputs the low voltage VGL, and the second switching unit 720 outputs the high voltage VGH.

The low voltage VGL output from the first switching unit 710 is supplied to the first viewing angle control transistor Tvc1 through the first control signal line CL1, and the high voltage VGH output from the second switching unit 720 is supplied to the second viewing angle control transistor Tvc2 through the second control signal line CL2.

Accordingly, in the first light emitting area EA1, an image having the wide viewing angle in the left-right direction can be output through the first light emitting units LU1 connected to the first viewing angle control transistors Tvc1.

However, if the X-coordinate viewing angle control signal VCSX and the Y-coordinate viewing angle control signal VCSY have the low level, the first switching unit 710 outputs the high voltage VGH, and the second switching unit 720 outputs the low voltage VGL.

Accordingly, in the first light emitting area EA1, an image having the narrow viewing angle in the left-right direction can be output through the second light emitting units LU2 connected to the second viewing angle control transistors Tvc2.

That is, the viewing angle control signals VCSX and VCSY supplied to the viewing angle switching unit 700 illustrated in FIG. 23 in order to output an image having the wide viewing angle (or the narrow viewing angle) are different from the viewing angle control signals VCSX and VCSY supplied to the viewing angle switching unit 700 illustrated in FIG. 19 in order to output an image having the wide viewing angle (or the narrow viewing angle).

However, functions as described with reference to FIGS. 1 to 22 can also be performed by the viewing angle switching unit 700 illustrated in FIG. 23.

Next, a viewing angle switching unit 700 illustrated in FIG. 24 includes a first switching unit 710 and a second switching unit 720. The first switching unit 710 includes a first transistor unit TU1 and a first resistance unit RU1, and the second switching unit 720 includes a second transistor unit TU2 and a second resistance unit RU2.

The first switching unit 710 includes a lath control transistor T1a and a 1bth control transistor T1b. The lath control transistor T1a and the 1bth control transistor T1b can be formed of P-type transistors.

A gate of the lath control transistor T1a is connected to the X-coordinate viewing angle control line VCLX to which the X-coordinate viewing angle control signal VCSX is supplied, a first terminal of the lath control transistor T1a is connected to the low voltage line LL, and a second terminal of the lath control transistor T1a is connected to the first resistance unit RU1.

A gate of the 1bth control transistor T1b is connected to the Y-coordinate viewing angle control line VCLY to which the Y-coordinate viewing angle control signal VCSY is supplied, a first terminal of the 1bth control transistor T1b is connected to the low voltage line LL, and a second terminal of the 1bth control transistor T1b is connected to the first resistance unit RU1.

The second switching unit 720 includes a 2ath control transistor T2a and a 2bth control transistor T2b. The 2ath control transistor T2a and the 2bth control transistor T2b can be formed of N-type transistors.

A gate of the 2ath control transistor T2a is connected to the X-coordinate viewing angle control line VCLX to which the X-coordinate viewing angle control signal VCSX is supplied, a first terminal of the 2ath control transistor T2a is connected to the low voltage line LL, and a second terminal of the 2ath control transistor T2a is connected to a first terminal of the 2bth control transistor T2b.

A gate of the 2bth control transistor T2b is connected to the Y-coordinate viewing angle control line VCLY to which the Y-coordinate viewing angle control signal VCSY is supplied, the first terminal of the 2bth control transistor T2b is connected to the second terminal of the 2ath control transistor T2a, and a second terminal of the 2bth control transistor T2b is connected to the second resistance unit RU2.

In this case, if at least one of the X-coordinate viewing angle control signal VCSX and the Y-coordinate viewing angle control signal VCSY has the low level, the first switching unit 710 outputs the low voltage VGL, and the second switching unit 720 outputs the high voltage VGH.

The low voltage VGL output from the first switching unit 710 is supplied to the first viewing angle control transistor Tvc1 through the first control signal line CL1, and the high voltage VGH output from the second switching unit 720 is supplied to the second viewing angle control transistor Tvc2 through the second control signal line CL2.

Accordingly, in the first light emitting area EA1, an image having the wide viewing angle in the left-right direction can be output through the first light emitting units LU1 connected to the first viewing angle control transistors Tvc1.

However, if the X-coordinate viewing angle control signal VCSX and the Y-coordinate viewing angle control signal VCSY have the high levels, the first switching unit 710 outputs the high voltage VGH, and the second switching unit 720 outputs the low voltage VGL.

Accordingly, in the first light emitting area EA1, an image having the narrow viewing angle in the left-right direction can be output through the second light emitting units LU2 connected to the second viewing angle control transistors Tvc2.

That is, the viewing angle control signals VCSX and VCSY supplied to the viewing angle switching unit 700 illustrated in FIG. 24 in order to output an image having the wide viewing angle (or the narrow viewing angle) are the same as the viewing angle control signals

VCSX and VCSY supplied to the viewing angle switching unit 700 illustrated in FIG. 19 in order to output an image having the wide viewing angle (or the narrow viewing angle).

Therefore, functions as described with reference to FIGS. 1 to 22 can also be performed by the viewing angle switching unit 700 illustrated in FIG. 24.

Finally, in FIG. 25, a viewing angle control unit VCU having a structure different from that of the viewing angle control unit VCU described with reference to FIG. 2 is illustrated.

For example, in the light emitting display apparatus described with reference to FIGS. 1 to 22, viewing angle control signals VCSX and VCSY are supplied to the viewing angle switching units 700 provided in the non-display area NDA. In this case, one of the first viewing angle control transistor Tvc1 and the second viewing angle control transistor Tvc2 of the viewing angle control unit VCU is turned on by the first control signal CS1 and the second control signal CS2 supplied from the viewing angle switching unit 700, and thus, an image having the wide viewing angle or an image having the narrow viewing angle can be output in the light emitting area EA.

However, in a light emitting display apparatus including the viewing angle control unit VCU illustrated in FIG. 25, the viewing angle control signals VCSX and VCSY can be directly supplied to the viewing angle control unit VCU, and thus, an image having the wide viewing angle or an image having the narrow viewing angle can be output in the light emitting area EA.

To this end, the viewing angle control unit VCU illustrated in FIG. 25 includes a first viewing angle control transistor unit CT1 and a second viewing angle control transistor unit CT2.

The first viewing angle control transistor unit CT1 includes a lath viewing angle transistor TC1a and a 1bth viewing angle transistor TC1b. The lath viewing angle transistor TC1a and the 1bth viewing angle transistor TC1b can be formed of P-type transistors.

A gate of the lath viewing angle transistor TC1a is connected to the X-coordinate viewing angle control line VCLX to which the X-coordinate viewing angle control signal VCSX is supplied, a first terminal of the lath viewing angle transistor TC1a is connected to the second terminal of the second emission transistor Tsw4b, and a second terminal of the lath viewing angle transistor TC1a is connected to the first terminal of the first light emitting device ED1.

A gate of the 1bth viewing angle transistor TC1b is connected to the Y-coordinate viewing angle control line VCLY to which the Y-coordinate viewing angle control signal VCSY is supplied, a first terminal of the 1bth viewing angle transistor TC1b is connected to the second terminal of the second emission transistor Tsw4b, and a second terminal of the 1bth viewing angle transistor TC1b is connected to the first terminal of the first light emitting device ED1.

The second viewing angle control transistor unit CT2 includes a 2ath viewing angle transistor TC2a and a 2bth viewing angle transistor TC2b. The 2ath viewing angle transistor TC2a and the 2bth viewing angle transistor TC2b can be formed of N-type transistors.

A gate of the 2ath viewing angle transistor TC2a is connected to the X-coordinate viewing angle control line VCLX to which the X-coordinate viewing angle control signal VCSX is supplied, a first terminal of the 2ath viewing angle transistor TC2a is connected to the second terminal of the second emission transistor Tsw4b, and a second terminal of the 2ath viewing angle transistor TC2a is connected to a first terminal of the 2bth viewing angle transistor TC2b.

A gate of the 2bth viewing angle transistor TC2b is connected to the Y-coordinate viewing angle control line VCLY to which the Y-coordinate viewing angle control signal VCSY is supplied, a first terminal of the 2bth viewing angle transistor TC2b is connected to the second terminal of the 2ath viewing angle transistor TC2a, and a second terminal of the 2bth viewing angle transistor TC2b is connected to the first terminal of the second light emitting device ED2.

In this case, if at least one of the X-coordinate viewing angle control signal VCSX and the Y-coordinate viewing angle control signal VCSY has the low level, the first viewing angle control transistor unit CT1 is turned on, and current can be supplied to the first light emitting device ED1.

If at least one of the X-coordinate viewing angle control signal VCSX and the Y-coordinate viewing angle control signal VCSY has the low level, the second viewing angle control transistor unit CT2 is turned off, and thus, current cannot be supplied to the second light emitting device ED2.

Accordingly, in the first light emitting area EA1, an image having the wide viewing angle in the left-right direction can be output through the first light emitting units LU1 connected to the first viewing angle control transistor units CT1.

However, if the X-coordinate viewing angle control signal VCSX and the Y-coordinate viewing angle control signal VCSY have the high levels, the second viewing angle control transistor unit CT2 is turned on, and current can be supplied to the second light emitting device ED2.

If the X-coordinate viewing angle control signal VCSX and the Y-coordinate viewing angle control signal VCSY have the high levels, the first viewing angle control transistor unit CT1 is turned off, and thus, current cannot be supplied to the first light emitting device ED1.

Accordingly, in the first light emitting area EA1, an image having the narrow viewing angle in the left-right direction can be output through the second light emitting units LU2 connected to the second viewing angle control transistor units CT2.

That is, the viewing angle control signals VCSX and VCSY supplied to the viewing angle control unit VCU illustrated in FIG. 25 in order to output an image having the wide viewing angle (or the narrow viewing angle) are the same as the viewing angle control signals VCSX and VCSY supplied to the viewing angle switching unit 700 illustrated in FIG. 19 in order to output an image having the wide viewing angle (or the narrow viewing angle).

Therefore, an image having the wide viewing angle or an image having the narrow viewing angle as described with reference to FIGS. 1 to 22 can also be output by the viewing angle control unit VCU illustrated in FIG. 25.

According to the present disclosure as described above, the modes of the light emitting areas EA can be controlled by the viewing angle switching units 700 provided in the non-display area NDA of the light emitting display panel, and particularly, the modes of the light emitting areas EA can be independently controlled.

Also, according to the present disclosure as described above, the modes of the light emitting areas EA can be controlled by the viewing angle control signals VCS. In this case, the viewing angle control signals VCS can be supplied to the viewing angle switching units 700 provided in the non-display area NDA, or can be directly transmitted to the viewing angle control units VCU provided in the pixel driving units PDC.

The features of the light emitting display apparatus according to an embodiment of the present disclosure are briefly summarized as follows.

A light emitting display panel according to an embodiment of the present disclosure comprises a display area configured to be provided with subpixels and a non-display area configured to be provided outside the display area, wherein each of the subpixels includes a first light emitting unit driven by a first viewing angle control transistor and a second light emitting unit driven by a second viewing angle control transistor, a first lens provided in the first light emitting unit and a second lens provided in the second light emitting unit have different shapes, the display area is divided into at least two light emitting areas along a first direction, the display area is divided into at least two light emitting areas along a second direction different from the first direction, and viewing angle switching units corresponding to the light emitting areas are provided in the non-display area.

A polarity type of the first viewing angle control transistor is the same as that of the second viewing angle control transistor.

The first viewing angle control transistor is connected between the first light emitting unit and a driving transistor which controls a level of current supplied to the first light emitting unit or the second light emitting unit, and the second viewing angle control transistor is connected between the second light emitting unit and the driving transistor.

The first light emitting unit includes a first light emitting device driven by the first viewing angle control transistor and a first lens disposed on the first light emitting device, and the second light emitting unit includes a second light emitting device driven by the second viewing angle control transistor and a second lens disposed on the second light emitting device.

An s−1th viewing angle switching unit among the viewing angle switching units is connected to first viewing angle control transistors and second viewing angle control transistors which are provided in an s−1th light emitting area among the light emitting areas (s is a natural number less than or equal to the number of light emitting areas), and an sth viewing angle switching unit among the viewing angle switching units is connected to first viewing angle control transistors and second viewing angle control transistors which are provided in an sth light emitting area among the light emitting areas.

Each of the viewing angle switching units is connected to a control driver controlling the viewing angle switching units.

Among the viewing angle switching units, an sth viewing angle switching unit (s is a natural number less than or equal to the number of light emitting areas) includes a first switching unit connected to gates of first viewing angle control transistors provided in an sth light emitting area among the light emitting areas and a second switching unit connected to gates of second viewing angle control transistors provided in the sth light emitting area.

The first switching unit includes a first transistor unit connected between a first control signal line connected to gates of the first viewing angle control transistors provided in the sth light emitting area and a low voltage line to which a low voltage is supplied and a first resistance unit connected between the first control signal line and a high voltage line to which a high voltage higher than the low voltage is supplied, and the second switching unit includes a second transistor unit connected between the high voltage line and a second control signal line connected to gates of the second viewing angle control transistors provided in the sth light emitting area and a second resistance unit connected between the second control signal line and the low voltage line.

The first transistor unit includes a first control transistor, a gate of the first control transistor is connected to a viewing angle control line to which a viewing angle control signal is supplied, a first terminal of the first control transistor is connected to the low voltage line, and a second terminal of the first control transistor is connected to the first resistance unit, the second transistor unit includes a second control transistor, and a gate of the second control transistor is connected to the viewing angle control line, a first terminal of the second control transistor is connected to the high voltage line, and a second terminal of the second control transistor is connected to the second resistance unit.

The first transistor unit includes a lath control transistor and a 1bth control transistor, a gate of the lath control transistor is connected to a X-coordinate viewing angle control line to which a X-coordinate viewing angle control signal is supplied, a first terminal of the lath control transistor is connected to the low voltage line, and a second terminal of the lath control transistor is connected to the first resistance unit, a gate of the 1bth control transistor is connected to a Y-coordinate viewing angle control line to which a Y-coordinate viewing angle control signal is supplied, a first terminal of the 1bth control transistor is connected to the low voltage line, and a second terminal of the 1bth control transistor is connected to the first resistance unit, the second transistor unit includes a 2ath control transistor and a 2bth control transistor, a gate of the 2ath control transistor is connected to the X-coordinate viewing angle control line, a first terminal of the 2ath control transistor is connected to the high voltage line, and a second terminal of the 2ath control transistor is connected to the second resistance unit RU2, and a gate of the 2bth control transistor is connected to the Y-coordinate viewing angle control line, a first terminal of the 2bth control transistor is connected to the high voltage line, and a second terminal of the 2bth control transistor is connected to the second resistance unit.

A light emitting display apparatus according to an embodiment of the present disclosure comprises a display area provided with subpixels and a non-display area provided outside the display area, wherein each of the subpixels includes a first light emitting unit driven by a first viewing angle control transistor and a second light emitting unit driven by a second viewing angle control transistor, a first viewing angle of a light output from the first light emitting unit is different from a second viewing angle of a light output from the second light emitting unit, the display area is divided into at least two light emitting areas along a first direction, the display area is divided into at least two light emitting areas along a second direction different from the first direction, and in each of the subpixels of the light emitting areas, only light having the first viewing angle is output, or only light having the second viewing angle is output.

Viewing angle switching units corresponding to the light emitting areas are provided in the non-display area.

A polarity type of the first viewing angle control transistor is the same as that of the second viewing angle control transistor.

The first viewing angle control transistor is connected between the first light emitting unit and a driving transistor which controls a level of current supplied to the first light emitting unit or the second light emitting unit, and the second viewing angle control transistor is connected between the second light emitting unit and the driving transistor.

Each of the light emitting areas is independently driven.

The first light emitting unit includes a first light emitting device driven by the first viewing angle control transistor and a first lens disposed on the first light emitting device, and the second light emitting unit includes a second light emitting device driven by the second viewing angle control transistor and a second lens disposed on the second light emitting device. A shape of the first lens is different from that of the second lens.

Among the viewing angle switching units, an sth viewing angle switching unit (s is a natural number less than or equal to the number of light emitting areas) includes a first switching unit connected to gates of first viewing angle control transistors provided in an sth light emitting area among the light emitting areas and a second switching unit connected to gates of second viewing angle control transistors provided in the sth light emitting area.

The first switching unit includes a first transistor unit connected between a first control signal line connected to gates of the first viewing angle control transistors provided in the sth light emitting area and a low voltage line to which a low voltage is supplied and a first resistance unit connected between the first control signal line and a high voltage line to which a high voltage higher than the low voltage is supplied, and the second switching unit includes a second transistor unit connected between the high voltage line and a second control signal line connected to gates of the second viewing angle control transistors provided in the sth light emitting area and a second resistance unit connected between the second control signal line and the low voltage line.

The first transistor unit includes a first control transistor, a gate of the first control transistor is connected to a viewing angle control line to which a viewing angle control signal is supplied, a first terminal of the first control transistor is connected to the low voltage line, and a second terminal of the first control transistor is connected to the first resistance unit, the second transistor unit includes a second control transistor, and a gate of the second control transistor is connected to the viewing angle control line, a first terminal of the second control transistor is connected to the high voltage line, and a second terminal of the second control transistor is connected to the second resistance unit.

The light emitting display apparatus according to the present disclosure can be applied to all electronic devices including a light emitting display panel. For example, the light emitting display apparatus according to the present disclosure can be applied to a virtual reality (VR) device, an augmented reality (AR) device, a mobile device, a video phone, a smart watch, a watch phone, or a wearable device, foldable device, rollable device, bendable device, flexible device, curved device, electronic notebook, e-book, PMP (portable multimedia player), PDA (personal digital assistant), MP3 player, mobile medical device, desktop PC, laptop PC, netbook computer, workstation, navigation, car navigation, vehicle display devices, televisions, wall paper display devices, signage devices, game devices, laptops, monitors, cameras, camcorders, and home appliances.

According to a light emitting display apparatus according to an embodiment of the present disclosure, in each of the light emitting areas provided along the first direction of the light emitting display panel and the light emitting areas provided along the second direction different from the first direction, only the first light emitting units can be driven or only the second light emitting units can be driven. Therefore, only the light having the first viewing angle can be output or only the light having the second viewing angle can be output.

Particularly, the viewing angle of light output from each of the light emitting areas can be changed to the first viewing angle or the second viewing angle based on the type of image output from each of the light emitting areas.

Moreover, the viewing angle of light output from each of the light emitting areas can be changed to the first viewing angle or the second viewing angle based on the user's request.

Therefore, according to a light emitting display apparatus according to an embodiment of the present disclosure, a viewing angle of each of the light emitting areas provided along the first direction and the second direction of the light emitting display panel can be changed, and accordingly, the type of an image output from each of the light emitting areas can be freely changed. Therefore, the user can simply and quickly recognize an image necessary for him/her through the light emitting display apparatus.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A light emitting display panel comprising:
a display area that is divided into a plurality of light emitting areas along a first direction and along a second direction that is different from the first direction and a non-display area that is outside the display area, each of the plurality of light emitting areas including a plurality of subpixels in the light emitting area; and
a plurality of viewing angle switching units in the non-display area, each viewing angle switching unit connected to the plurality of subpixels included in a corresponding light emitting area from the plurality of light emitting areas,
wherein each of the plurality of subpixels includes:
a first light emitting unit driven by a first viewing angle control transistor that is controlled by a viewing angle switching unit from the plurality of viewing angle switching units that is connected to the subpixel, the first light emitting unit including a first lens having a first shape; and
a second light emitting unit driven by a second viewing angle control transistor that is controlled by the viewing angle switching unit that is connected to the subpixel, the second light emitting unit including a second lens having a second shape that is different from the first shape of the first lens.

2. The light emitting display panel of claim 1, wherein a polarity type of the first viewing angle control transistor is a same as a polarity type of the second viewing angle control transistor.

3. The light emitting display panel of claim 1, wherein the first viewing angle control transistor is connected to the first light emitting unit and a driving transistor that controls a level of current supplied to the first light emitting unit or the second light emitting unit, and the second viewing angle control transistor is connected to the second light emitting unit and the driving transistor.

4. The light emitting display panel of claim 1, wherein each first light emitting unit further includes a first light emitting device driven by the first viewing angle control transistor and the first lens is on the first light emitting device,
wherein each second light emitting unit includes a second light emitting device driven by the second viewing angle control transistor and the second lens is on the second light emitting device.

5. The light emitting display panel of claim 1, wherein a first viewing angle switching unit from the plurality of viewing angle switching units is connected to first viewing angle control transistors and second viewing angle control transistors that are in a first light emitting area among the plurality of light emitting areas, and a second viewing angle switching unit among the plurality of viewing angle switching units is connected to first viewing angle control transistors and second viewing angle control transistors that are in a second light emitting area from the plurality of light emitting areas.

6. The light emitting display panel of claim 1, wherein each of the plurality of viewing angle switching units is connected to a control driver that controls the plurality of viewing angle switching units.

7. The light emitting display panel of claim 1, wherein a viewing angle switching unit from the plurality of viewing angle switching units includes:
a first switching unit connected to gates of first viewing angle control transistors that are included in a corresponding light emitting area from the plurality of light emitting areas; and
a second switching unit connected to gates of second viewing angle control transistors that are included in the corresponding light emitting area.

8. The light emitting display panel of claim 7, wherein the first switching unit includes:
a first transistor unit connected to a first control signal line that is connected to the gates of the first viewing angle control transistors included in the corresponding light emitting area and a low voltage line that supplies a low voltage; and
a first resistance unit connected to the first control signal line and a high voltage line that supplies a high voltage that is greater than the low voltage, and
the second switching unit includes:
a second transistor unit connected to the high voltage line and a second control signal line that is connected to the gates of the second viewing angle control transistors included in the corresponding light emitting area; and
a second resistance unit connected to the second control signal line and the low voltage line.

9. The light emitting display panel of claim 8, wherein the first transistor unit includes a first control transistor comprising a gate of the first control transistor that is connected to a viewing angle control line that applies a viewing angle control signal to the gate of the first control transistor, a first terminal of the first control transistor that is connected to the low voltage line, and a second terminal of the first control transistor that is connected to the first resistance unit,
wherein the second transistor unit includes a second control transistor that comprises a gate of the second control transistor that is connected to the viewing angle control line, a first terminal of the second control transistor that is connected to the high voltage line, and a second terminal of the second control transistor that is connected to the second resistance unit.

10. The light emitting display panel of claim 8, wherein the first transistor unit includes a first control transistor and a second control transistor,
wherein a gate of the first control transistor of the first transistor unit is connected to a X-coordinate viewing angle control line that supplies a X-coordinate viewing angle control signal to the gate of the first control transistor, a first terminal of the first control transistor of the first transistor unit is connected to the low voltage line, and a second terminal of the first control transistor of the first transistor unit is connected to the first resistance unit,
wherein a gate of the second control transistor of the first transistor unit is connected to a Y-coordinate viewing angle control line that applies a Y-coordinate viewing angle control signal to the gate of the second control transistor, a first terminal of the second control transistor of the first transistor unit is connected to the low voltage line, and a second terminal of the second control transistor of the first transistor unit is connected to the first resistance unit,
wherein the second transistor unit includes a first control transistor and a second control transistor,
wherein a gate of the first control transistor of the second transistor unit is connected to the X-coordinate viewing angle control line, a first terminal of the second control transistor of the second transistor unit is connected to the high voltage line, and a second terminal of the second control transistor of the second transistor unit is connected to the second resistance unit, and
wherein a gate of the second control transistor of the second transistor unit is connected to the Y-coordinate viewing angle control line, a first terminal of the second control transistor of the second transistor unit is connected to the high voltage line, and a second terminal of the second control transistor of the second transistor unit is connected to the second resistance unit.

11. A light emitting display apparatus comprising:
a display area that is divided into a plurality of light emitting areas along a first direction and along a second direction that is different from the first direction and a non-display area that is outside the display area, each of the plurality of light emitting areas including a plurality of subpixels in the light emitting area,
wherein each of the plurality of subpixels includes:
a first light emitting unit driven by a first viewing angle control transistor, the first light emitting unit emitting light at a first viewing angle; and
a second light emitting unit driven by a second viewing angle control transistor, the second light emitting unit emitting light at a second viewing angle that is different from the first viewing angle,
wherein in each of the plurality of subpixels of the plurality of light emitting areas, the first light emitting unit emits light having the first viewing angle without the second light emitting unit emitting the light having the second viewing angle, and the second light emitting unit emits light having the second viewing angle without the first light emitting unit emitting the light having the first viewing angle.

12. The light emitting display apparatus of claim 11, further comprising:
a plurality of viewing angle switching units in the non-display area, each viewing angle switching unit connected to the plurality of subpixels included in a corresponding light emitting area from the plurality of light emitting areas.

13. The light emitting display apparatus of claim 11, wherein a polarity type of the first viewing angle control transistor is a same as a polarity type of the second viewing angle control transistor.

14. The light emitting display apparatus of claim 11, wherein the first viewing angle control transistor is connected to the first light emitting unit and a driving transistor that controls a level of current supplied to the first light emitting unit or the second light emitting unit, and the second viewing angle control transistor is connected between the second light emitting unit and the driving transistor.

15. The light emitting display apparatus of claim 11, wherein each of the plurality of light emitting areas is independently driven.

16. The light emitting display apparatus of claim 11, wherein the first light emitting unit includes:
a first light emitting device driven by the first viewing angle control transistor; and
a first lens on the first light emitting device,
wherein the second light emitting unit includes:
a second light emitting device driven by the second viewing angle control transistor; and
a second lens on the second light emitting device.

17. The light emitting display apparatus of claim 16, wherein a shape of the first lens is different from a shape of the second lens.

18. The light emitting display apparatus of claim 12, wherein a viewing angle switching unit from the plurality of viewing angle switching units comprises:
a first switching unit connected to gates of first viewing angle control transistors that are included in a corresponding light emitting area from the plurality of light emitting areas; and
a second switching unit connected to gates of second viewing angle control transistors that are included in the corresponding light emitting area.

19. The light emitting display apparatus of claim 18, wherein the first switching unit includes:
a first transistor unit connected to a first control signal line that is connected to the gates of the first viewing angle control transistors included in the corresponding light emitting area and a low voltage line that supplies a low voltage; and
a first resistance unit connected to the first control signal line and a high voltage line that supplies a high voltage that is greater than the low voltage, and
the second switching unit includes:
a second transistor unit connected to the high voltage line and a second control signal line that is connected to the gates of the second viewing angle control transistors included in the corresponding light emitting area; and
a second resistance unit connected to the second control signal line and the low voltage line.

20. The light emitting display apparatus of claim 19, wherein the first transistor unit includes a first control transistor that comprises a gate of the first control transistor that is connected to a viewing angle control line that applies a viewing angle control signal to the gate of the first control transistor, a first terminal of the first control transistor that is connected to the low voltage line, and a second terminal of the first control transistor that is connected to the first resistance unit,
wherein the second transistor unit includes a second control transistor that comprises a gate of the second control transistor that is connected to the viewing angle control line, a first terminal of the second control transistor that is connected to the high voltage line, and a second terminal of the second control transistor that is connected to the second resistance unit.

21. A light emitting display device comprising:
a display panel including a plurality of light emitting areas that each include a plurality of subpixels in the light emitting area and a non-display area around the plurality of light emitting areas, each of the plurality of subpixels including a first light emitting unit that emits light at a first viewing angle and a second light emitting unit that emits light at a second viewing angle that is different from the first viewing angle; and
a plurality of viewing angle switching units in the non-display area, each viewing angle switching unit connected to the plurality of subpixels included in a corresponding light emitting area from the plurality of light emitting areas and is configured to control the plurality of subpixels in the corresponding light emitting area to emit light at the first viewing angle or the second viewing angle,
wherein the plurality of subpixels of one light emitting area from the plurality of light emitting areas emit light at the first viewing angle that corresponds to a portion of a first image while the plurality of subpixels of another light emitting area from the plurality of light emitting areas emits light at the second viewing angle that corresponds to a portion of a second image that is different from the first image during a first mode of the light emitting display device.

22. The light emitting display device of claim 21, wherein first light emitting areas from the plurality of light emitting areas that include the one light emitting area collectively display the first image having the first viewing angle and second light emitting areas from the plurality of light emitting areas that include the other light emitting area collectively display the second image having the second viewing angle during the first mode,
wherein the first viewing angle is less than the second viewing angle.

23. The light emitting display device of claim 22, wherein an object that includes the light emitting display device is moving during the first mode.

24. The light emitting display device of claim 23, wherein the first light emitting areas from the plurality of light emitting areas display a first portion of a third image having the second viewing angle and the second light emitting areas display a second portion of the third image having the second viewing angle during a second mode that is different from the first mode,
wherein the object that includes the light emitting display device is stationary during the second mode.

25. The light emitting display device of claim 21, wherein each of the plurality of subpixels includes:
a first light emitting device driven by a first viewing angle control transistor that is controlled by a viewing angle switching unit from the plurality of viewing angle switching units that is connected to the subpixel;
a first lens on the first light emitting device, the first lens having a first shape;
a second light emitting device driven by a second viewing angle control transistor that is controlled by the viewing angle switching unit that is connected to the subpixel; and
a second lens on the second light emitting device, the second lens having a second shape that is different from the first shape of the first lens,
wherein the first light emitting unit emits light having the first viewing angle without the second light emitting unit emitting the light having the second viewing angle, and the second light emitting unit emits light having the second viewing angle without the first light emitting unit emitting the light having the first viewing angle.

26. The light emitting display device of claim 25, wherein the first viewing angle control transistor is connected to the first light emitting device and a driving transistor that controls a level of current supplied to the first light emitting unit or the second light emitting unit, and the second viewing angle control transistor is connected to the second light emitting unit and the driving transistor.

27. The light emitting display device of claim 26, wherein a viewing angle switching unit from the plurality of viewing angle switching units includes:
a first transistor unit connected to a first control signal line that is connected to gates of first viewing angle control transistors included in the corresponding light emitting area and a low voltage line that supplies a low voltage;
a first resistance unit connected to the first control signal line and a high voltage line that supplies a high voltage that is greater than the low voltage;
a second transistor unit connected to the high voltage line and a second control signal line that is connected to gates of second viewing angle control transistors included in the corresponding light emitting area; and
a second resistance unit connected to the second control signal line and the low voltage line.
